(19) United States
(12) Patent Application Publication
(10) Pub. No.: US 2010/0227059 A1
(43) Pub. Date: Sep. 9, 2010

(54) FILM DEPOSITION APPARATUS, FILM DEPOSITION METHOD, AND COMPUTER READABLE STORAGE MEDIUM

(75) Inventors: Hitoshi Kato, Oshu-Shi (JP); Manabu Honma, Oshu-Shi (JP); Hiroyuki Kikuchi, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/713,225

(22) Filed: Feb. 26, 2010

(30) Foreign Application Priority Data
Mar. 4, 2009 (JP) 2009-051256
Mar. 12, 2009 (JP) 2009-059971

(51) Int. Cl. C23C 16/458; C23C 16/00; C23C 16/52

(52) U.S. Cl. 427/255.28; 118/730; 118/696

(57) ABSTRACT

A film is deposited to a predetermined thickness on a wafer by allowing the wafer placed on a susceptor to alternately move through plural process areas where corresponding plural reaction gases are supplied from corresponding plural reaction gas supplying portions and a separation area where a separation gas is supplied from a separation gas supplying portion in order to separate the plural reaction gases. Such movement is achieved by rotating the susceptor relative to the plural reaction gas supplying portions and the separation gas supplying portion, or rotating the plural reaction gas supplying portions and the separation gas supplying portion relative to the susceptor. Then, when the film is deposited in the above manner to a predetermined thickness, the film deposition is temporarily stopped; the wafer is rotated around its center; and the film is deposited to another predetermined thickness in the same manner.

### CROSS-REFERENCE TO RELATED APPLICATION

This application claims the benefit of priority of Japanese Patent Applications No. 2009-051256 and 2009-059971, filed on Mar. 4, 2009 and Mar. 12, 2009, respectively, with the Japanese Patent Office, the entire contents of which are hereby incorporated by reference.

### BACKGROUND OF THE INVENTION

1. Field of the Invention

The present invention relates to a film deposition apparatus and a film deposition method that deposit a film on a substrate in a chamber by carrying out a cycle of alternately supplying at least two kinds of reaction gases that react with each other on the substrate to produce a layer of a reaction product, and a computer readable storage medium storing a computer program for causing the film deposition apparatus to execute the film deposition method.

2. Description of the Related Art

As a film deposition method in a semiconductor fabrication process, there has been known a method where at least two reaction gases are alternately supplied to a semiconductor wafer (referred to as a “wafer” below) or the like as a substrate under vacuum, thereby depositing a film. Specifically, in this method, after a first reaction gas is adsorbed on an upper surface of the wafer, a second reaction gas is adsorbed on the upper surface, so that one or more atomic (or molecular) layers are produced through chemical reaction of the first and the second reaction gases on the surface of the wafer. In addition, such a cycle is repeated, for example, several hundreds times, thereby depositing a thin film on the wafer. This process may be called an atomic layer deposition (ALD) method (also referred to as a molecular layer deposition (MLD) method). Because a thickness of the thin film can be controlled at higher accuracy by the number of the cycles and the deposited film can have excellent uniformity across the wafer, this deposition method is thought to be promising as a film deposition technique that can address further miniaturization of semiconductor devices.

Such a film deposition method may be preferably used, for example, for depositing a dielectric material to be used as a gate insulator. When a silicon oxide film is deposited as the gate insulator, a bis (tertiary-butylamino) silane (BTBAS) gas or the like is used as a first reaction gas (source gas) and ozone gas or the like is used as a second gas (oxidation gas).

Film deposition apparatuses suitable for ALD (or MLD) deposition have been disclosed, for example, in Patent Documents 1 through 8 listed below. Such film deposition apparatuses include a vacuum chamber, a susceptor that is provided in the vacuum chamber and on which plural wafers are placed in a circumferential direction of the susceptor, and plural gas supplying portions for supplying corresponding process gases (reaction gases) to the wafers.

When depositing a thin film using the above film deposition apparatus, first, the wafers are placed on the susceptor; an inside of the vacuum chamber is evacuated to a predetermined reduced pressure; the wafers are heated; and the gas supplying portions and the susceptor are rotated relative to each other. Then, the first and the second reaction gases are supplied to the upper surfaces of the wafers from the corresponding gas supplying portions. At this time, an inert gas is also supplied as a gas curtain in order to separate a first process area where the first reaction gases is supplied and a second process area where the second reaction gases is supplied, in the vacuum chamber. Alternatively, partition walls are provided between the first and the second process areas in the vacuum chamber in order to separate the process areas.

As stated, while the plural reaction gases are simultaneously supplied to the vacuum chamber, the process areas are separated so that the reaction gases are not intermixed, and thus the first reaction gas and the second reaction gas are alternately supplied to each of the wafers rotated by the susceptor, with the gas curtains (or the partition walls) intervening between the first and the second reaction gases. Because of such alternate supplying of the reaction gases, the reaction gases need not be alternately supplied to the vacuum chamber by operating valves and the like, and the vacuum chamber is not purged at the time when the reaction gases are switched over. In addition, the reaction gases are substantially switched over at higher speed by rotating the susceptor. Therefore, the ALD (or MLD) deposition can be realized at higher throughput.

Incidentally, along with further reduced circuit patterns and further increased numbers of layers in recent semiconductor device integration, there is a demand for further improvement in a thickness uniformity of a thin film across the wafer even when the ALD (or MLD) apparatus is used. In order to improve the thickness uniformity, the reaction gases need to be distributed over the wafer by controlling reaction gas flow patterns. However, concave portions in which the wafers are placed may be made in the susceptor in the vacuum chamber; the gas supplying portions are provided inside the vacuum chamber; and concave/convex portions are made in the vacuum chamber because of, for example, a wafer transfer opening. Therefore, the gas flow patterns may be disturbed by such structures, and thus it is difficult to control the reaction gas flow patterns. In addition, there may be a problem in that the reaction gases are not adsorbed uniformly on the upper surface of the wafer when there are variations in temperature across the wafer, specifically across a large diameter wafer, which leads to a degraded thickness uniformity.

Patent Document 9 discloses an ion implantation method where ions are implanted into a wafer, while rotating the wafer by a predetermined angle in a step-by-step manner. Specifically, in this method, plural wafers are placed along a circumferential direction of a wafer disk; the wafers are exposed to an ion beam so that one-fourth of a total dose of ions are implanted into the wafers; the wafers are rotated around their respective centers by 90°; and then the wafers are exposed again to the ion beam so that another one-fourth of the total dose is implanted into the wafers. Subsequently, the 90° rotation of the wafers and the ion implantation of another one-fourth of the total dose are repeated twice until the total dose of ions are implanted into the wafers. According to this method, the ions are uniformly implanted, so that field effect transistors (FETs) without large variations in their properties are obtained in the wafers, even if the FETs are variously oriented in the wafers in relation to a reciprocal movement of the wafer disk. This method is disclosed in order to form source and drain regions of the FETs as a fabrication method of the same, and is not applicable to the ALD (or MLD) process.

Patent Document 1: United States Patent Publication No. 6,634,314

Patent Document 2: Japanese Patent Application Laid-Open Publication No. 2001-254181 (FIGS. 1, 2)

Patent Document 3: Japanese Patent Publication No. 3,144,664 (FIGS. 1, 2, claim 1)

Patent Document 4: Japanese Patent Application Laid-Open Publication No. H4-287912

Patent Document 5: United States Patent Publication No. 7,153,542

Patent Document 6: Japanese Patent Application Laid-Open Publication No. 2007-247066 (paragraphs 0023 through 0025, 0058, FIGS. 12 and 13)

Patent Document 7: United States Patent Publication No. 2007-218701

Patent Document 8: United States Patent Publication No. 2007-218702

Patent Document 9: Japanese Patent Application Laid-Open Publication No. H05-152238

### SUMMARY OF THE INVENTION

The present invention has been made in view of the above, and provides a film deposition apparatus and a film deposition method that are capable of improving uniformity of a film, and a computer readable medium storing a computer program for causing the film deposition apparatus to carry out the film deposition method.

A first aspect of the present invention provides a film deposition apparatus for depositing a film on a substrate by carrying out a cycle of alternately supplying at least two kinds of reaction gases that react with each other on the substrate to produce a layer of a reaction product in a chamber. The film deposition apparatus includes a susceptor provided in the chamber; plural reaction gas supplying portions that are provided opposing an upper surface of the susceptor and apart from one another in a circumferential direction of the susceptor, and supply corresponding reaction gases to an upper surface of the substrate; a separation area including a separation gas supplying portion that supplies a separation gas, in order to separate atmospheres of plural process areas where the corresponding reaction gases are supplied from the corresponding reaction gas supplying portions, the separation area being provided between the plural process areas; a first rotation mechanism that carries out relative rotation of the susceptor with respect to the reaction gas supplying portions and the separation gas supplying portion around a vertical axis; substrate receiving portions formed in the susceptor along a rotation direction of the relative rotation by the first rotation mechanism so that the substrate may be positioned in the plural process areas and the separation areas in turn due to the relative rotation by the first rotation mechanism; a second rotation mechanism that rotates the substrate around a vertical axis by a predetermined rotation angle; and an evacuation portion that evacuates the chamber.

A second aspect of the present invention provides a film deposition apparatus for depositing a film on a substrate in a chamber by carrying out a cycle of alternately supplying at least two kinds of reaction gases that react with each other on the substrate to produce a layer of a reaction product. The film deposition apparatus includes a susceptor that is rotatably provided in the chamber and includes in one surface of the susceptor a substrate receiving portion in which the substrate is placed; a first reaction gas supplying portion configured to supply a first reaction gas to the one surface; a second reaction gas supplying portion configured to supply a second reaction gas to the one surface, the second reaction gas supplying portion being separated from the first reaction gas supplying portion along a rotation direction of the susceptor; a separation area positioned along the rotation direction between a first process area where the first reaction gas is supplied and a second process area where the second reaction gas is supplied; a center area that is positioned in a center portion of the chamber in order to separate the first process area and the second process area and includes a gas ejection hole through which a first separation gas is ejected along the one surface; an evacuation hole configured to evacuate the chamber; and a unit into which the substrate may be transferred from the chamber, wherein a rotational stage on which the substrate is placed inside the unit. The separation area includes a separation gas supplying portion that supplies a second separation gas, and a ceiling surface that creates in relation to the one surface of the susceptor a thin space where the second separation gas may flow from the separation area to the process area side in relation to the rotation direction.

A third aspect of the present invention provides a film deposition method for depositing a film on a substrate in a chamber by carrying out a cycle of alternately supplying at least two kinds of reaction gases that react with each other on the substrate to produce a layer of a reaction product. The film deposition method includes steps of placing the substrate in a substrate receiving portion of a susceptor provided in the chamber; supplying the plural reaction gases to a susceptor surface where the wafer receiving portion is provided, from corresponding gas supplying portions provided to be separated from each other and to oppose the susceptor surface; supplying from a separation gas supplying portion a first separation gas to a separation area provided between plural process areas along a circumferential direction of the susceptor, wherein the reaction gases are supplied from the corresponding gas supplying portions to the corresponding plural process areas, thereby reducing the plural reaction gases flowing into the separation area; depositing a film by carrying out relative rotation of the susceptor with respect to the reaction gas supplying portions and the separation gas supplying portion using a first rotation mechanism, in order to allow the substrate to be positioned in turn in the plural process areas and the separation areas, thereby producing a layer of a reaction product; and rotating the substrate around a center thereof using a second rotation mechanism by a predetermined rotation angle in a midst of the step of depositing the film.

A fourth aspect of the present invention provides a computer readable storage medium storing a computer program for use in a film deposition apparatus according to the first or the second aspect, the computer program including a group of instructions for causing the film deposition apparatus to execute a film deposition method according to the third aspect.

### BRIEF DESCRIPTION OF THE DRAWINGS

FIG. 1 is a cross-sectional view of a film deposition apparatus according to a first embodiment of the present invention;

FIG. 2 is a perspective view of an inner configuration of the film deposition apparatus of FIG. 1;

FIG. 3 is a plan view of the film deposition apparatus of FIG. 1;

FIG. 4 is a cross-sectional view illustrating a separation area and process areas in the film deposition apparatus of FIG. 1;

FIG. 5 is an enlarged cross-sectional view of the film deposition apparatus of FIG. 1;

FIG. 6 is an enlarged cross-sectional view of the film deposition apparatus of FIG. 1;

FIG. 7 is a perspective view illustrating a part of the film deposition apparatus of FIG. 1;

FIG. 8 schematically illustrates a flow pattern of purge gases in the film deposition apparatus of FIG. 1;

FIG. 9 is a broken perspective view of the film deposition apparatus of FIG. 1;

FIG. 10 is a cross-sectional view illustrating a mechanism that rotates a substrate in the film deposition apparatus of FIG. 1;

FIG. 11 is a flowchart of film deposition procedures carried out using the film deposition apparatus of FIG. 1;

FIG. 12 schematically illustrates a flow pattern of gases in the film deposition apparatus of FIG. 1;

FIG. 13 schematically illustrates how the substrate is rotated around its center in the film deposition apparatus of FIG. 1;

FIG. 14 is an explanatory view for explaining repetition of a film deposition step and a rotation step in the film deposition procedures carried out using the film deposition apparatus of FIG. 1;

FIG. 15 is a schematic view of a rotation mechanism in a film deposition apparatus according to a second embodiment of the present invention;

FIG. 16 is a cross-sectional view illustrating a film deposition apparatus according to a third embodiment of the present invention;

FIG. 17 is a perspective view illustrating the film deposition apparatus of FIG. 16;

FIG. 18 is a plan view illustrating the film deposition apparatus of FIG. 16;

FIG. 19 is a broken perspective view illustrating the film deposition apparatus of FIG. 16;

FIG. 20 is a cross-sectional view illustrating the film deposition apparatus of FIG. 16;

FIG. 21 is a perspective view illustrating an inner configuration of a film deposition apparatus according to a fourth embodiment;

FIG. 22 is a plan view illustrating an inner configuration of the film deposition apparatus of FIG. 21;

FIG. 23 schematically illustrates apart of the film deposition apparatus of FIG. 21;

FIG. 24 is a perspective view illustrating a part of the film deposition apparatus of FIG. 21;

FIG. 25 is an explanatory view illustrating how a substrate is rotated in the film deposition apparatus of FIG. 21;

FIG. 26 is an explanatory view for explaining repetition of a film deposition step and a rotation step in the film deposition procedures carried out using the film deposition apparatus of FIG. 21;

FIG. 27 is an explanatory view for explaining an effect of rotating the substrate around its center;

FIG. 28 is a schematic view illustrating a rotation mechanism in a film deposition apparatus according to a fifth embodiment of the present invention;

FIG. 29 illustrates a modified example of the rotation mechanism of FIG. 28;

FIG. 30 is a plan view illustrating a film deposition apparatus according to a sixth embodiment of the present invention;

FIG. 31 is a cross-sectional view illustrating the film deposition apparatus of FIG. 30;

FIG. 32 is a schematic view illustrating a film deposition apparatus according to a seventh embodiment;

FIGS. 33 through 38 illustrate modified examples of a convex portion in the embodiments of the present invention;

FIG. 39 illustrates a modified example of the convex portion provided for a reaction gas nozzle;

FIG. 40 illustrates a modified example of the convex portion in the embodiments of the present invention;

FIG. 41 illustrates another example of a reaction gas nozzle arrangement in the embodiments of the present invention;

FIG. 42 is a schematic view illustrating a substrate process apparatus to which the film deposition apparatus according to the embodiments (including the modified examples) of the present invention is applied;

FIG. 43 is a schematic view illustrating a substrate process apparatus to which the film deposition apparatus according to the embodiments (including the modified examples) of the present invention;

FIG. 44 is a perspective view illustrating a rotation mechanism in the substrate process apparatus;

FIG. 45 is a perspective view illustrating another rotation mechanism in the substrate process apparatus; and

FIG. 46 illustrates simulation results carried out to confirm an effect demonstrated by the film deposition apparatus according to the embodiments of the present invention.

### DETAILED DESCRIPTION OF THE PREFERRED EMBODIMENT

According to an embodiment of the present invention, there are provided a film deposition apparatus and a film deposition method that are capable of improving uniformity of a film, and a computer readable medium storing a computer program for causing the film deposition apparatus to carry out the film deposition method.

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific size should be determined by a person having ordinary skill in the art in view of the following non-limiting embodiments.

### First Embodiment

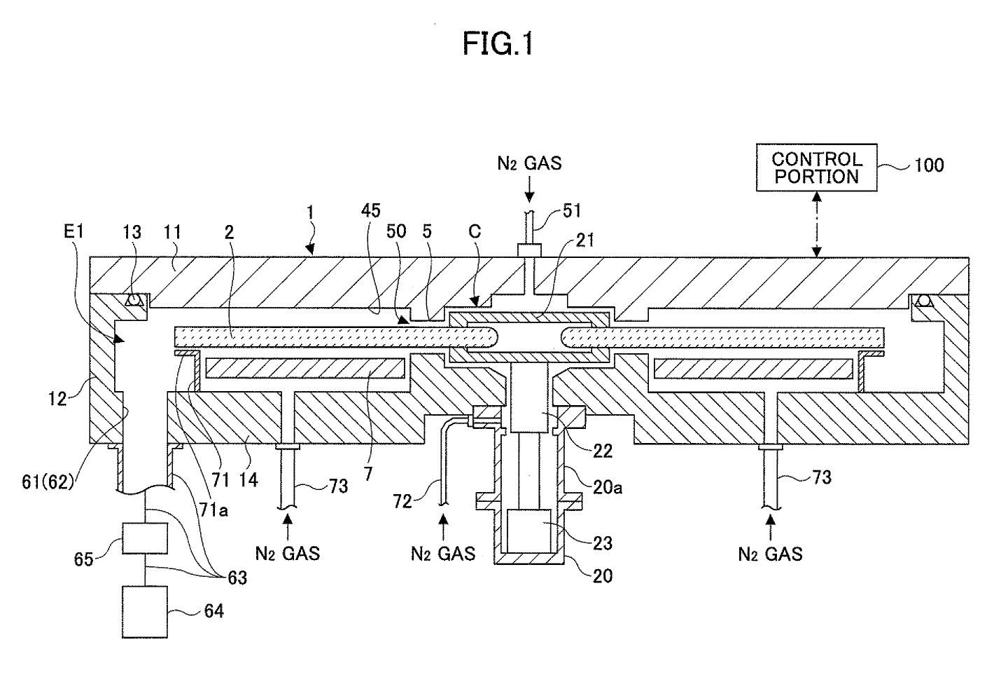

As shown in FIGS. 1 through 3, a film deposition apparatus according to an embodiment of the present invention is provided with a substantially flattened vacuum chamber 1 having a cylinder top view shape, and a susceptor 2 that is arranged inside the vacuum chamber 1 and has a rotation center at a center of the vacuum chamber 1. The vacuum chamber 1 is provided with a chamber body 12 that has a substantially cup-shape to accommodate the susceptor 2, and a ceiling plate 11 configured to hermetically close a top opening of the chamber body 12. The ceiling plate 11 is hermetically coupled with the chamber body 12 via a sealing member 13 such as an O-ring that has a ring shape and is placed on a circumferential top surface of the chamber body 12. The ceiling plate 11 can be brought upward from and downward on the chamber body 12 by a driving mechanism (not shown).

The susceptor 2 is made of a carbon plate having a thickness of about 20 mm in this embodiment, and has a circular shape having a diameter of about 960 mm. A top surface, a reverse surface, and a side surface of the susceptor 2 may be coated with silicon carbide (SiC). In addition, the susceptor 2 is fixed at its center portion on a cylinder-shaped core portion 21, which in turn is fixed on a top end of a rotational shaft 22 that vertically extends. The rotational shaft 22 penetrates through a bottom portion 14 of the chamber body 12 and is attached at its bottom end on a driving portion 23 as a rotation mechanism that rotates the rotational shaft 22 clockwise in this embodiment. The rotational shaft 22 and the driving portion 23 are accommodated in a cylinder-shaped case body 20 having an opening at its top portion. A flange portion of the case body 20 is hermetically attached on a lower surface of the bottom portion 14 of the chamber body 12 so that an inner environment of the case body 20 is isolated from an outer environment.

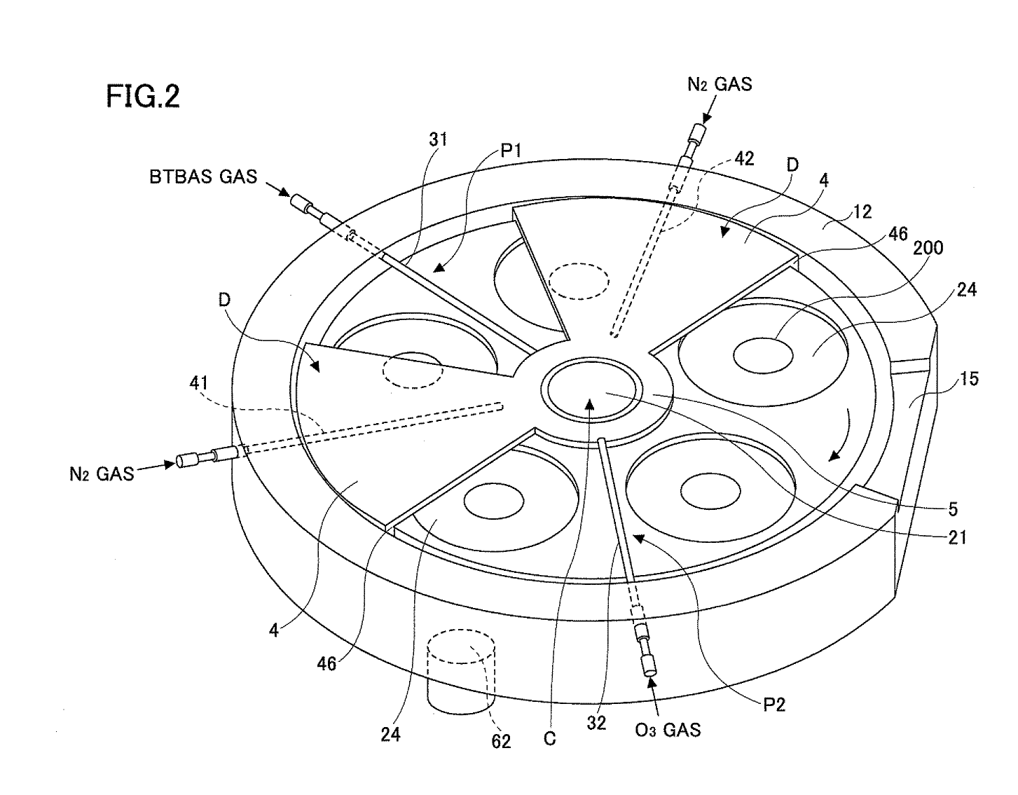

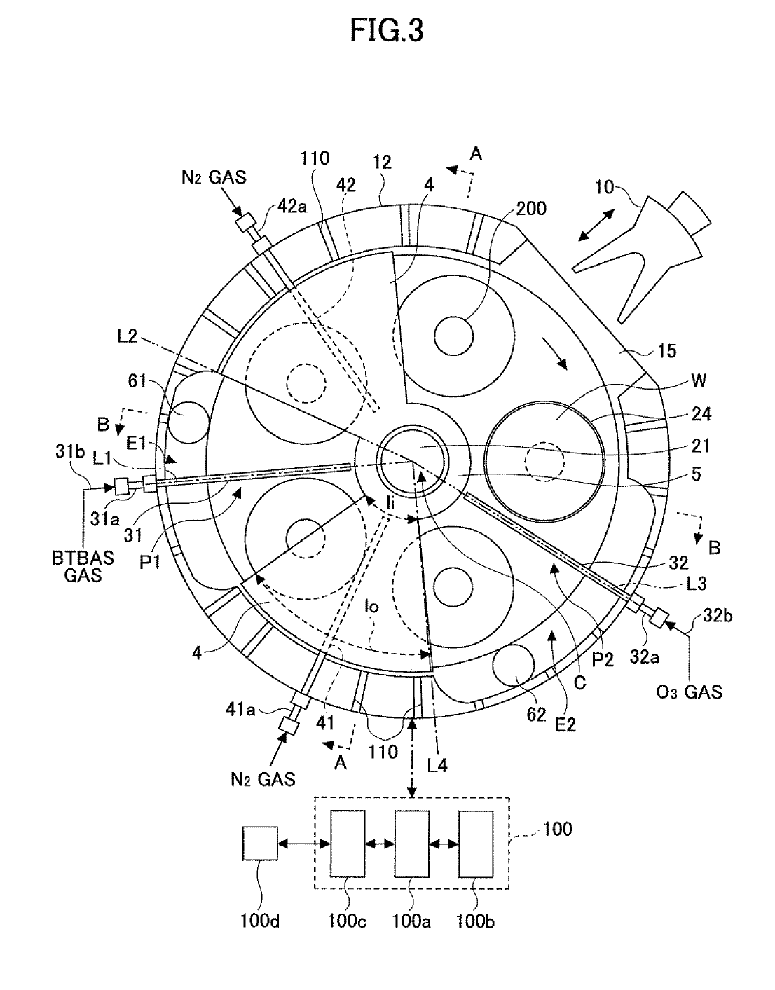

Plural (e.g., five) wafer receiving portions 24 having a circular concave shape are provided on and in a top surface of the susceptor 2, as shown in FIGS. 2 and 3. The wafer receiving portions 24 are arranged in a rotation direction (circumferential direction) and receive corresponding substrates such as semiconductor wafers (referred to as wafers). The wafer receiving portions 24 can be revolved around a rotational center of the susceptor 2 due to rotation of the susceptor 2. Incidentally, only one wafer W is shown in one of the wafer receiving portions 24 in FIG. 3, for simplicity of illustration.

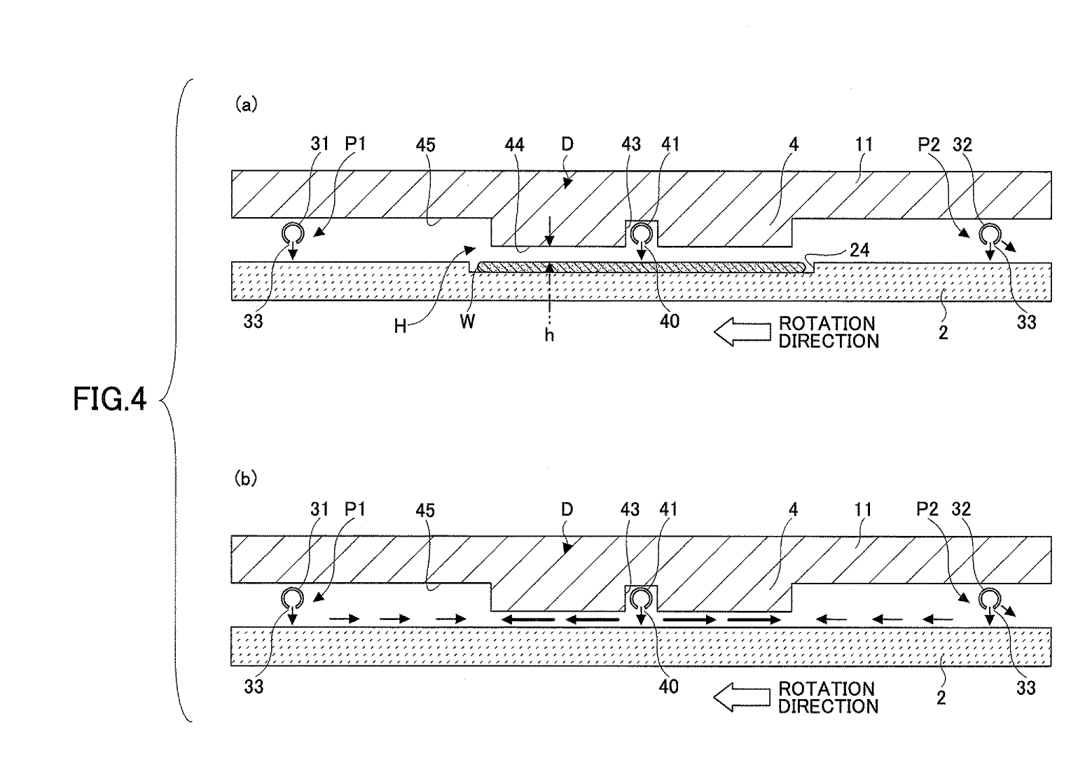

FIG. 4 is a projected diagram illustrating a cross-section of the vacuum chamber 1 taken along a co-axial circle of the susceptor 2. As shown in a subsection (a) of FIG. 4, the wafer receiving portions 24 have a diameter larger than a diameter of the wafer W by about 4 mm, for example, and a depth substantially equal to a thickness of the wafer W. When the wafer W is placed in the wafer receiving portion 24, the top surface of the wafer W is substantially at the same elevation as the top surface of the susceptor 2 (an area not including the susceptor receiving portion 24). If there is a relatively large step between the top surfaces of the susceptor 2 and the wafer W, the step may cause gas turbulence in the vacuum chamber 1. “Being substantially at the same elevation” means here that the top surfaces of the susceptor 2 and the wafer W are at the same elevation, or a difference between the top surfaces of the susceptor 2 and the wafer W is within about 5 mm, while the difference is preferably as close to zero as possible to the extent allowed by machining accuracy. In addition, as shown in FIGS. 2 and 3, the susceptor 2 is provided at a bottom of the wafer receiving portions 24 with an elevation plate 200 that supports a back center portion and its vicinity of the wafer W to move the wafer W upward and downward.

The wafer receiving portion 24 is provided in order to prevent the wafer W from falling off the susceptor 2 due to centrifugal force caused by the rotating susceptor 2. The wafer receiving portion 24 may be realized as plural guide members that are provided on the susceptor 2 and along the circumference of the wafer W in order to position the wafer W, or a chuck mechanism such as an electrostatic chuck provided in the susceptor 2, in other embodiments. When such a chuck mechanism is employed, an area where the wafer W is positioned by the chucking mechanism serves as the wafer receiving portion.

In addition, as shown in FIGS. 2 and 3, a first reaction gas nozzle 31, a second reaction gas nozzle 32, and separation gas nozzles 41, 42 are provided above the susceptor 2, and these nozzles 31, 32, 41, 42 extend in radial directions. These nozzles 31, 32, 41, 42 may be made of quartz glass. With this configuration, the wafer receiving portions 24 can move through and below the nozzles 31, 32, 41, and 42. In the illustrated example, the second reaction gas nozzle 32, the separation gas nozzle 41, the first reaction gas nozzle 31, and the separation gas nozzle 42 are arranged clockwise in this order. These gas nozzles 31, 32, 41, and 42 are introduced into the vacuum chamber 1 through plural through-holes 110 (FIG. 3) made in the circumferential wall of the chamber body 12, and supported by attaching gas introduction ports 31a, 32a, 41a, 42a onto the outer surface of the circumferential wall of the chamber body 12. Incidentally, the through-holes 110 that are not used for the gas nozzles 31, 32, 41, 42 are sealed by a sealing member (not shown), according to which the inner environment of the vacuum chamber 1 is kept hermetically sealed.

In addition, although the gas nozzles 31, 32, 41, 42 are introduced into the vacuum chamber 1 from the circumferential wall of the chamber body 12 in the illustrated example, the gas nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer top surface of the ceiling plate 11. With such an L-shaped conduit, the gas nozzle 31 (32, 41, 42) can be connected to one opening of the L-shaped conduit inside the chamber 1 and the gas inlet port 31a (32a, 41a, 42a) can be connected to the other opening of the L-shaped conduit outside the chamber 1.

Although not shown, the reaction gas nozzle 31 is connected to a gas supplying source of bis (tertiary-butylamino) silane (BTBAS), which is a first source gas, via a gas supplying line 31b provided with valves, flow rate controllers, (not shown) and the like, and the reaction gas nozzle 32 is connected to a gas supplying source of O₃ (ozone) gas, which is a second source gas, via a gas supplying line 32b provided with valves, flow rate controllers, (not shown) and the like.

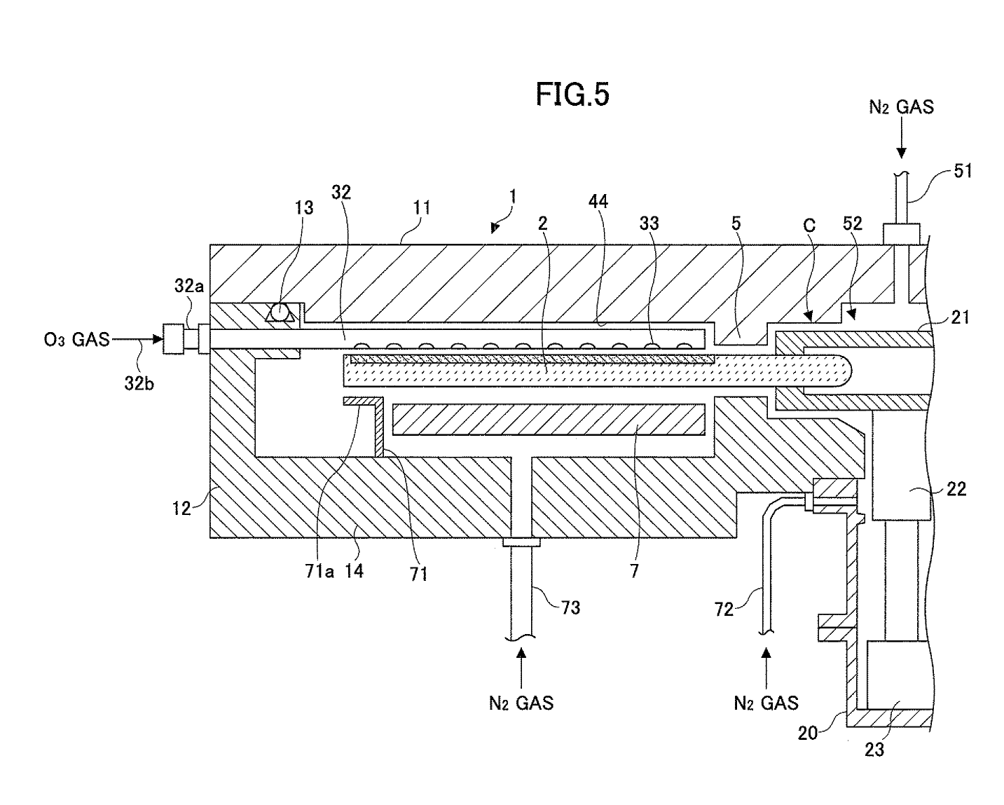

As shown in FIG. 5, the reaction gas nozzle 31 has plural ejection holes 33 for ejecting the reaction gas downward, which are arranged at predetermined intervals along a longitudinal direction of the reaction gas nozzle 31. In this embodiment, the ejection holes 33 have a diameter of about 5 mm, and are arranged at intervals of about 10 mm along the longitudinal direction. A distance between the reaction gas nozzle 31 and the wafer W may be about 1 mm to about 4 mm, and preferably about 2 mm. The reaction gas nozzle 32 has the same configuration as the reaction nozzle 31 in this embodiment. Incidentally, an area below the reaction gas nozzle 31 may be referred to as a process area P1 for allowing the BTBAS to be adsorbed on the wafer W, and an area below the reaction gas nozzle 31 may be referred to as a process area P2 for allowing the BTBAS gas adsorbed on the wafer W to be oxidized by the O₃ gas.

On the other hand, the separation gas nozzles 41, 42 are connected to a gas supplying source (not shown) of the separation gas via a gas supplying line (not shown) provided with valves, flow rate controllers, or the like. The separation gas may be nitrogen (N₂) gas, or inert gases such as helium (He), argon (Ar), and the like. In addition, the separation gas is not limited to these gases, but may be any gas that does not influence film deposition carried out in the vacuum chamber 1, while the N₂ gas is used as the separation gas. The separation gas nozzles 41, 42 have plural ejection holes 40 for ejecting the N₂ gas downward, which are arranged at predetermined intervals along the longitudinal directions of the separation gas nozzles 41, 42. In this embodiment, the ejection holes 40 have a diameter of about 0.5 mm and are arranged at intervals of about 10 mm along the longitudinal direction of the separation gas nozzles 41, 42. A distance between the separation gas nozzles 41, 42 and the wafer W may be about 1 mm to about 4 mm, and is preferably about 3 mm.

The separation gas nozzles 41, 42 are provided in corresponding separation areas D configured to separate the process area P1 and the process area P2. In each of the separation areas D, a convex portion 4 is provided on the ceiling plate 11 of the vacuum chamber 1, as shown in FIGS. 2, 3 and the subsections (a) and (b) of FIG. 4. The convex portion 4 has a top view shape of a sector whose apex lies at the center of the chamber 1 and whose arced periphery lies near and along the inner circumferential wall of the chamber body 12. In addition, the convex portion 4 has a groove portion 43 that extends in order to bisect the convex portion 4 in a radius direction. In the groove portion 43, the separation gas nozzle 41 (42) is accommodated. A distance between a center axis of the separation gas nozzle 41 (42) and one of the sides of the sector-shaped convex portion 4 is the same as a distance between the center axis of the separation gas nozzle 41 (42) and the other of the sides of the sector-shaped convex portion 4.

Incidentally, the groove portion 43 is formed to bisect the convex portion 4 in this embodiment, but may be formed so that an upstream side of the convex portion 4 relative to the rotation direction of the susceptor 2 is wider.

According to the above configuration, there are flat lower ceiling surfaces 44 (first ceiling surfaces) on both sides of the separation gas nozzle 41 (42) and higher ceiling surfaces 45 (second ceiling surfaces) outside of the lower ceiling surfaces 44, as shown in the subsection (a) of FIG. 4. The convex portion 4 (ceiling surface 44) forms a separation space, which is a thin space, in order to impede the first reaction gas and the second reaction gas from entering the space between the convex portion 4 and the susceptor 2.

Referring to a subsection (b) of FIG. 4, the O₃ gas flowing from the reaction gas nozzle 32 toward the convex portion 4 along the rotation direction of the susceptor 2 is impeded from entering the space between the convex portion 4 and the susceptor 2. In addition, the BTBAS gas flowing from the reaction gas nozzle 32 toward the convex portion 4 is impeded from entering the space between the convex portion 4 and the susceptor 2. “The gas being impeded from entering” means here that the N₂ gas as the separation gas ejected from the separation gas nozzle 41 spreads between the ceiling surface 44 and the susceptor 2 and flows out to spaces below the ceiling surface 45 adjacent to the first ceiling surface 44, in the illustrated example, so that the reaction gases are unable to enter the separation space from the space below the ceiling surfaces 45. In addition, “The gases cannot enter the separation space” means not only that the gases are completely prevented from entering the separation space, but that the gases cannot proceed farther toward the separation gas nozzle 41 and thus be intermixed with each other even if a fraction of the reaction gases enter the separation space. Namely, as long as such an effect is demonstrated, the separation area D is to separate the process area P1 and the process area P2. Therefore, a degree of thinness of the thin space (space below the convex portion 4) is determined in such a manner that a pressure difference between the thin space and the space adjacent to the thin space (space below the higher ceiling space 45) is maintained in order to provide an effect of “the gas being unable to enter”. Incidentally, the BTBAS gas or the O₃ gas adsorbed on the wafer W can pass through and below the convex portion 4. Therefore, the gases in “the gases being impeded from entering” mean the gases in a gaseous phase.

In this embodiment, when a wafer having a diameter of about 300 mm is supposed to be processed in the vacuum chamber 1, the convex portion 4 has a circumferential length of, for example, about 140 mm along an inner arc li (FIG. 3) that is at a distance 140 mm away from the rotation center of the susceptor 2, and a circumferential length of, for example, about 502 mm along an outer arc lo (FIG. 3) corresponding to the outermost portion of the wafer receiving portions 24 of the susceptor 2. In addition, a circumferential length from one side wall of the convex portion 4 through the nearest side wall of the groove portion 43 along the outer arc lo is about 246 mm.

In addition, the height h (see the subsection (a) of FIG. 4) of the bottom surface of the convex portion 4, or the ceiling surface 44, measured from the upper surface of the susceptor 2 (or the wafer W) is, for example, about 0.5 mm through about 10 mm, and preferably about 4 mm. In this case, the rotational speed of the susceptor 2 is, for example, 1 through 500 revolutions per minute (rpm). In order to ascertain the separation function performed by the separation area D, the size of the convex portion 4 and the height h of the ceiling surface 44 from the susceptor 2 may be determined depending on the pressure in the vacuum chamber 1 and the rotational speed of the susceptor 2 through experimentation.

Referring to FIGS. 1, 2, and 3, the ring-shaped protrusion portion 5 is provided on the lower surface of the ceiling plate 11, so that an inner circumference of the protrusion portion 5 faces an outer circumferential surface of the core portion 21. The protrusion portion 5 opposes the susceptor 2 in an area outside of the core portion 21. In addition, the protrusion portion 5 is formed integrally with the convex portion 4, and lower surfaces of the convex portion 4 and the protrusion portion 5 form one plane. In other words, the lower surface of the protrusion portion 5 is as high as the lower surface of the convex portion 4. However, the protrusion portion 5 and the convex portion 4 are not integrally formed in other embodiments, but may be separately formed. Incidentally, FIGS. 2 and 3 illustrate an inner configuration of the vacuum chamber 1 whose ceiling plate 11 is removed while the convex portions 4 remain inside the vacuum chamber 1.

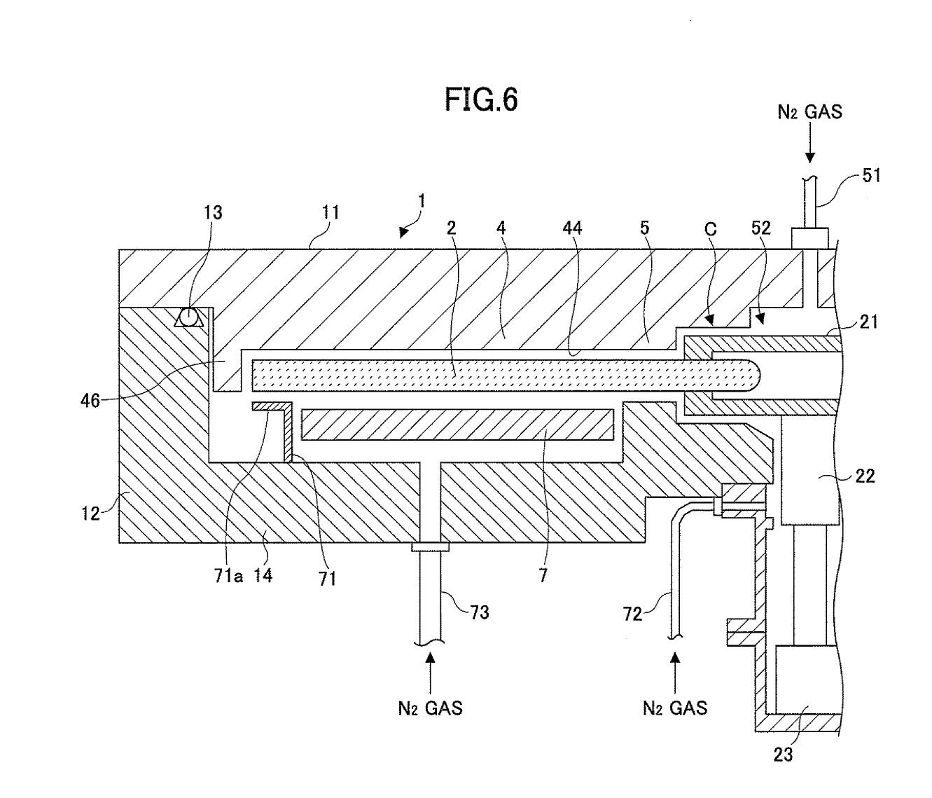

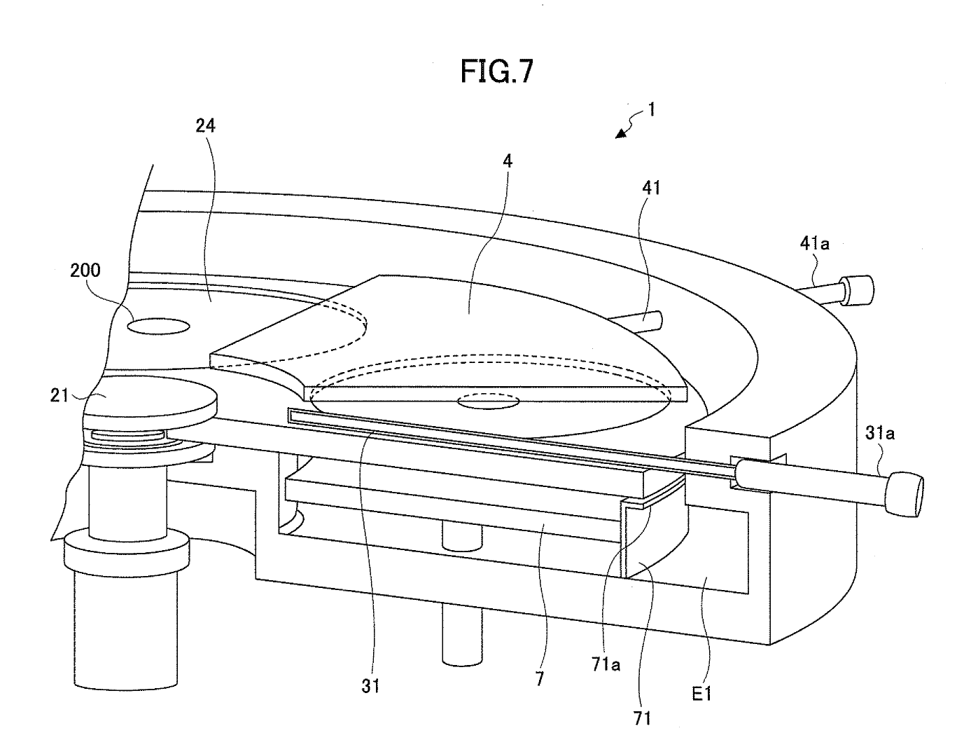

FIG. 6 illustrates a half of a cross-sectional view taken along A-A line in FIG. 3, where the convex portion 4 and the protrusion portion integrally formed with the convex portion 4 are illustrated. As shown, the convex portion 4 has a bent portion 46 that is bent in an L-shape at an edge thereof. Because the convex portion 4 can be removed along with the ceiling plate 11 from the chamber body 12, there are slight gaps between the bent portion 46 and the susceptor 2 and between the bent portion 46 and the chamber body 12. However, the bent portion 46 substantially fills out a space between the susceptor 2 and the chamber body 12, thereby preventing the first reaction gas (BTBAS) ejected from the first reaction gas nozzle 31 and the second reaction gas (ozone) ejected from the second reaction gas nozzle 32 from being intermixed through the space between the susceptor 2 and the chamber body 12. The gaps between the bent portion 46 and the susceptor 2 and between the bent portion 46 and the chamber body 12 may be the same as the height h of the ceiling surface 44 from the susceptor 2. In the illustrated example, a side wall facing the outer circumferential surface of the susceptor 2 serves as an inner circumferential wall of the separation area D.

While the chamber body 12 has a vertical surface close to an outer circumferential surface of the bent portion 46 in the separation area D, as shown in FIG. 6, the chamber body 12 has an indented portion at the inner circumferential portion opposed to the outer circumferential surface of the susceptor 2 in an area excluding the separation area D. Specifically, the indented portions are provided for corresponding process portions P1, P2. The indented portion in gaseous communication with the process area P1 is referred to as an evacuation area E1, and the indented portion in gaseous communication with the process area P2 is referred to as an evacuation area E2. Below the evacuation areas E1, E2, evacuation ports 61, 62 are formed, respectively, as shown in FIGS. 1 and 3. The evacuation ports 61, 62 are connected to an evacuation unit such as a vacuum pump 64 via an evacuation pipe 63 in which a pressure controller 65 is provided along with valves, as shown in FIG. 1.

The evacuation ports 61, 62 are provided on corresponding sides of the separation area D relative to the rotation direction of the susceptor 2, seen from above, in order to allow the separation area D to provide the separation effect. Specifically, the evacuation port 61 is located between the process area P1 and the separation area D located downstream relative to the rotation direction of the susceptor 2 in relation to the process area P1, and the evacuation port 62 is located between the process area P2 and the separation area D located downstream relative to the rotation direction of the susceptor 2 in relation to the process area P2. With such a configuration, the BTBAS gas is evacuated substantially exclusively from the evacuation port 61, and the O₃ gas is evacuated substantially exclusively from the evacuation port 62. In the illustrated example, the evacuation port 61 is provided between the reaction gas nozzle 31 and an extended line along a straight edge of the convex portion 4 located downstream relative to the rotation direction of the susceptor 2 in relation to the reaction gas nozzle 31, the straight edge being closer to the reaction gas nozzle 31. In addition, the evacuation port 62 is provided between the reaction gas nozzle 32 and an extended line along a straight edge of the convex portion 4 located downstream relative to the rotation direction of the susceptor 2 in relation to the reaction gas nozzle 32, the straight edge being closer to the reaction gas nozzle 32. In other words, the evacuation port 61 is provided between a straight line L1 shown by a chain line in FIG. 3 that extends from the center of the susceptor 2 along the reaction gas nozzle 31 and a straight line L2 shown by a two-dot chain line in FIG. 3 that extends from the center of the susceptor 2 along the straight edge on the upstream side of the convex portion 4 concerned. Additionally, the evacuation port 62 is provided between a straight line L3 shown by a chain line in FIG. 3 that extends from the center of the susceptor 2 along the reaction gas nozzle 32 and a straight line L4 shown by a two-dot chain line in FIG. 3 that extends from the center of the susceptor 2 along the straight edge on the upstream side of the convex portion 4 concerned.

While the two evacuation ports 61, 62 are formed in the chamber body 12 in this embodiment, three evacuation ports may be formed in other embodiments. For example, an additional evacuation portion may be provided between the reaction gas nozzle 32 and the separation area D located upstream relative to the rotation direction of the susceptor 2 in relation to the reaction gas nozzle 32. A further additional evacuation portion may be arbitrarily provided. In the illustrated example, the evacuation ports 61, 62 are provided lower than the susceptor 2 so that the vacuum chamber 1 is evacuated through a gap between the circumference of the susceptor 2 and the inner circumferential wall of the chamber body 12. However, the evacuation ports 61, 62 may be provided in the circumferential wall of the chamber body 12. When the evacuation portions 61, 62 are provided in the circumferential wall, the evacuation ports 61, 62 may be located higher than the top surface of the susceptor 2. In this case, gases flow along the top surface of the susceptor 2 and into the evacuation ports 61, 62 located higher than the top surface of the susceptor 2. Therefore, it is advantageous in that particles in the vacuum chamber 1 are not blown upward by the gases, compared to when the evacuation ports are provided, for example, in the ceiling plate 11.

As shown in FIGS. 1, 5 and the like, a heater unit 7 as a heating portion is provided in a space between the bottom portion 14 of the chamber body 12 and the susceptor 2, so that the wafers W placed on the susceptor 2 are heated through the susceptor 2 at a temperature determined by a process recipe. In addition, a cover member 71 is provided beneath the susceptor 2 and near the outer circumference of the susceptor 2 in order to surround the heater unit 7, so that the space (heater housing space) where the heater unit 7 is housed is partitioned from the outside area of the cover member 71. The cover member 71 has a flange portion 71a at the top. The flange portion 71a is arranged so that a slight gap is maintained between the lower surface of the susceptor 2 and the flange portion in order to substantially prevent gas from flowing inside the cover member 71.

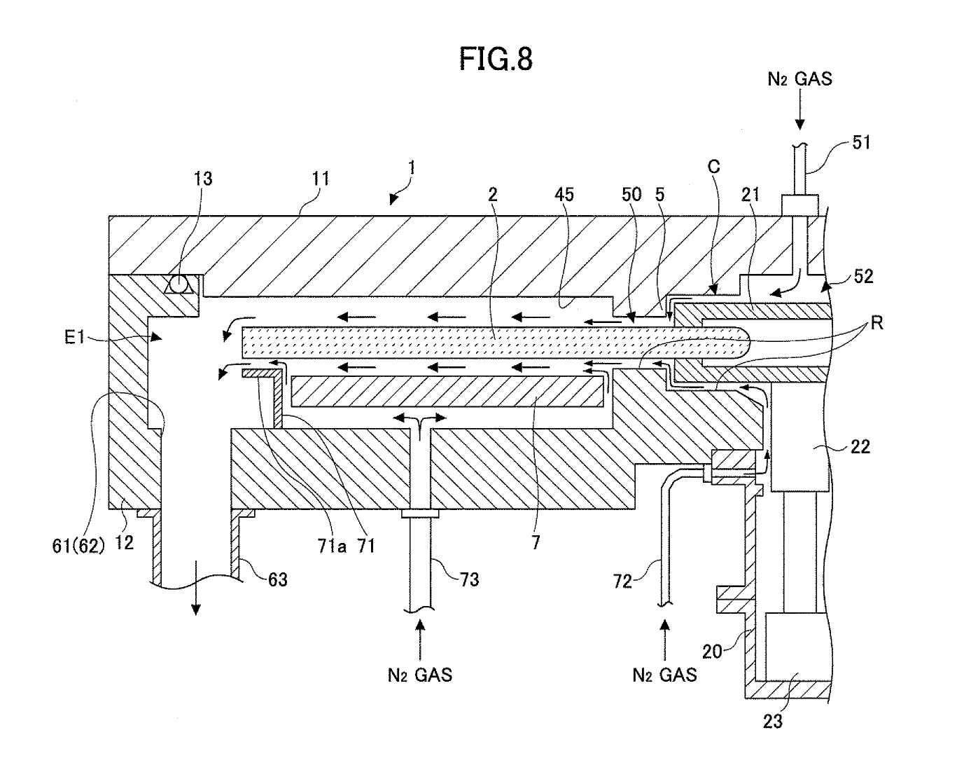

Referring to FIG. 8, the bottom portion 14 has a raised portion R inside of the heater unit 7. An upper surface of the raised portion R comes close to the susceptor 2 and the core portion 21, leaving slight gaps between the susceptor 2 and the upper surface of the raised portion R and between the upper surface of the raised portion R and the bottom surface of the core portion 21. In addition, the bottom portion 14 has a center hole through which the rotational shaft 22 passes. An inner diameter of the center hole is slightly larger than a diameter of the rotational shaft 22, leaving a gap for gaseous communication with the case body 20 through the flanged pipe portion 20a. A purge gas supplying pipe 72 is connected to an upper portion of the flange portion 20a. In addition, plural purge gas supplying pipes 73 are connected to areas below the heater unit 7 at predetermined angular intervals in order to purge the space where the heater unit 7 is housed (heater unit housing space).

With such a configuration, N₂ purge gas flows from the purge gas supplying pipe 72 to the heater unit housing space through a gap between the rotational shaft 22 and the center hole of the bottom portion 14, a gap between the core portion 21 and the raised portion R of the bottom portion 14, and a gap between the bottom surface of the susceptor 2 and the raised portion R of the bottom portion 14. In addition, N₂ gas flows from the purge gas supplying pipes 73 to the heater unit housing space. Then, these N₂ gases flow into the evacuation port 61 through the gap between the flange portion 71a and the bottom surface of the susceptor 2. These flows of N₂ gas are illustrated by arrows in FIG. 8. The N₂ gases serve as separation gases that substantially prevent the BTBAS (O₃) gas from flowing around the space below the susceptor 2 to be intermixed with the O₃ (BTBAS) gas.

Referring to FIG. 8, a separation gas supplying pipe 51 is connected to a center portion of the ceiling plate 11 of the vacuum chamber 1. From the separation gas supplying pipe 51, N₂ gas as a separation gas is supplied to a space 52 between the ceiling plate 11 and the core portion 21. The separation gas supplied to the space 52 flows through a narrow gap 50 between the protrusion portion 5 and the susceptor 2 and along the upper surface of the susceptor 2 to reach the evacuation area E1. Because the space 52 and the gap 50 are filled with the separation gas, the BTBAS gas and the O₃ gas are not intermixed through the center portion of the susceptor 2. In other words, the film deposition apparatus according to this embodiment is provided with a center area C defined by a rotational center portion of the susceptor 2 and the vacuum chamber 1 and configured to have an ejection opening for ejecting the separation gas toward the upper surface of the susceptor 2 in order to separate the process area P1 and the process area P2. In the illustrated example, the ejection opening corresponds to the gap 50 between the protrusion portion 5 and the susceptor 2.

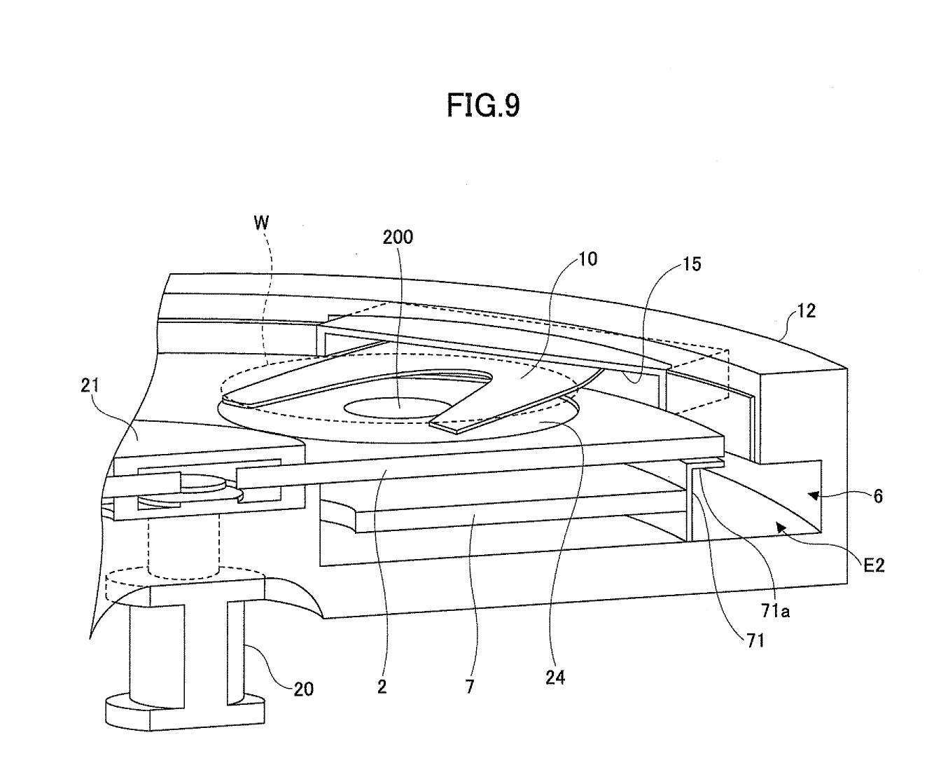

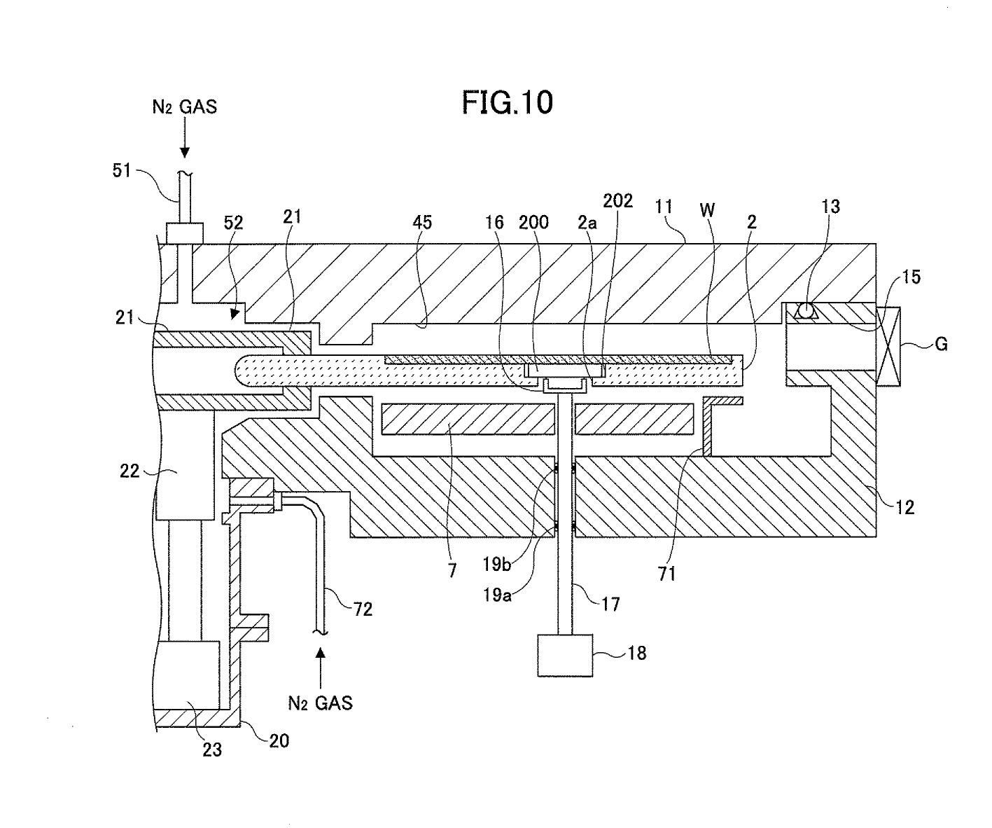

As shown in FIGS. 2, 3, and 9, a transfer opening 15 is made on a circumferential wall of the chamber body 12. The transfer opening 15 is opened and closed by a gate valve G (FIG. 10). The wafer W is transferred in and out from the vacuum chamber 1 through the transfer opening 15 by a transfer arm 10 provided outside of the vacuum chamber 1.

As shown in FIG. 10, the wafer receiving portion 24 is provided with an elevation plate 200 by which the wafer W is supported from a lower center portion thereof and brought upward and downward, in order to transfer the wafer W to/from the transfer arm 10. As shown in FIG. 10, a concave portion 202 is provided in substantially the center of the wafer receiving portion 24, as shown in FIG. 10. The concave portion 202 has an opening 2a in substantially the center thereof. The elevation plate 200 is housed so that the opening 2a is closed. In addition, a top surface of the elevation plate 200 is at the same elevation as or slightly lower than a bottom surface of the concave portion 202.

Incidentally, the transfer arm 10 has a U-shaped distal end so that the transfer arm 10 can receive the wafer W without interference with the elevation plate 200.

Because the wafer W is transferred into the vacuum chamber 1 by the transfer arm 10 and placed on the wafer receiving portion 24 when one of the wafer receiving portions 24 of the susceptor 2 is aligned with the transfer opening 15 and the gate valve G is opened, an elevation mechanism that supports the elevation plate 200 and brings the wafer W upward and downward is provided below the wafer receiving portion 24 in alignment with the transfer arm 10, as shown in FIG. 10. The elevation mechanism includes lift pins 16 that support the elevation plate 200 from the lower surface of the elevation plate 200, an elevation shaft 17 that vertically extends to penetrate the heater unit housing space and the bottom portion 14 of the chamber body 12 and supports the lift pins 16, and an elevation apparatus 18 that bring upward and downward the lift pins 16 and the elevation shaft 17 and rotates the lift pins 16 and the elevation shaft 17 around a vertical axis. With such a configuration, the elevation plate 200 can be brought upward and downward in order to receive and transfer the wafer W from and to the transfer arm 10, and brought upward in order to rotate the wafer W.

Incidentally, a bearing portion 19a and a magnetic fluid sealing portion 19b are provided between the elevation shaft 17 and the bottom portion 14 of the vacuum chamber 1.

In addition, the film deposition apparatus according to this embodiment is provided with a control portion 100 that controls the film deposition apparatus. The control portion 100 includes a process controller 100a composed of, for example, a computer including a central processing unit (CPU), a user interface portion 100b, and a memory device 100c. The user interface portion 100b includes a display that displays a process, and a keyboard or a touch panel (not shown) by which an operator of the film deposition apparatus chooses a process recipe, a process manager changes process parameters of the process recipe, and the like.

The memory device 100c stores control programs or process recipes for causing the process controller 100a to carry out various processes, and process parameters for various processes. Especially, the memory device 100c stores process conditions such as a target thickness of a film to be deposited, the number of film deposition steps (described below), and a rotation angle θ° of the wafer W that is rotated in a rotation step (describe below). In addition, these programs or process recipes have a group of instructions for, for example, sending control signals to each component or part of the film deposition apparatus, in order to cause the film deposition apparatus to carry out, for example, operations (a film deposition method) described later. These control programs or process recipes are read out by the process controller 100a due to an instruction from the user interface portion 100b, and executed. Moreover, these programs or recipes may be stored in a computer readable storage medium 100d, and installed into the memory device 100c through an input/output (I/O) device (not shown). The computer readable storage medium may be a hard disk, a compact disk (CD), a CD-readable, a CD-rewritable, a digital versatile disk (DVD)-rewritable, a flexible disk, a semiconductor memory, or the like. Additionally, the programs or recipes may be downloaded to the memory device 100c through a communication line.

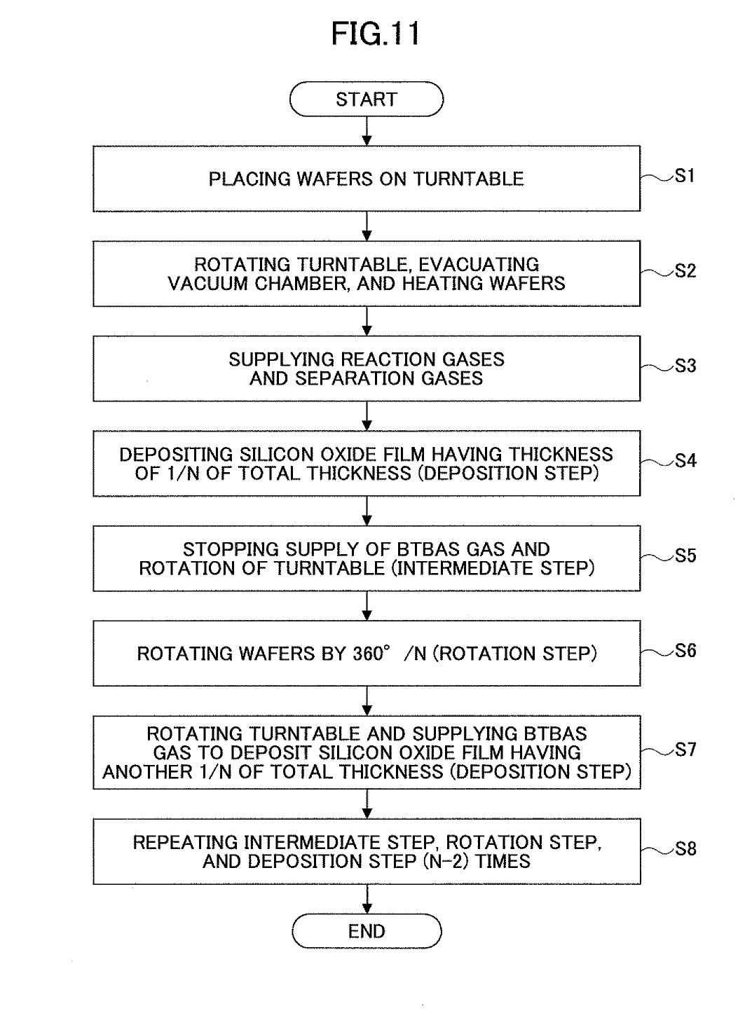

Next, an effect of this embodiment is described with reference to FIGS. 11 through 14. In the following, an example where a silicon oxide film having a target thickness of T (e.g., 80 nm) is deposited on the wafer W is explained. First, when the gate valve G is opened, the wafer W (having a diameter of, for example, 300 mm) is transferred into the vacuum chamber 1 through the transfer opening 15 by the transfer arm 10, and placed on the wafer receiving portion 24 of the susceptor 2 (Step S1). Specifically, after the wafer receiving portion 24 is located in alignment with the transfer opening 15, the wafer W is brought into the vacuum chamber 1 and held above the elevation plate 200 by the transfer arm 10. Next, the elevation plate 200 is brought up through an open area of the U-shaped distal end of the transfer arm 10 to support the wafer W from the lower surface of the wafer W. After the transfer arm 10 is retracted from the vacuum chamber 1, the elevation plate 200 is brought down and housed in the concave portion 202 of the wafer receiving portion 24, so that the wafer W is placed in the wafer receiving portion 24. Such transfer-in of the wafer W is repeated by intermittently rotating the susceptor 2, and five wafers W are placed in the corresponding wafer receiving areas 24 of the susceptor 2. Subsequently, the susceptor 2 is rotated clockwise at a rotational speed of, for example, one through 500 rpm, or preferably 240 rpm; the vacuum chamber 1 is evacuated to the lowest reachable pressure; and the wafers W are heated to a set temperature of, for example, 350° C. by the heater unit 7 (Step S2). Specifically, the susceptor 2 is heated in advance by the heater unit 7, and the wafers W is heated to the set temperature by placing the wafers W on the susceptor 2.

Next, the N₂ gas is supplied from the separation gas nozzles 41, 42 to the vacuum chamber 1 at flow rates of, for example, 10,000 standard cubic centimeters per minute (sccm), and from the separation gas supplying pipe 51 and the purge gas supplying pipe 72 at a predetermined flow rate. The pressure controller 65 (FIG. 1) controls the inner pressure of the vacuum chamber 1 at a predetermined pressure of, for example, 1067 Pa (8 Torr). Then, the BTBAS gas and the O₃ gas are supplied into the vacuum chamber 1 from the reaction gas nozzle 31 and the reaction gas nozzle 32 at flow rates of, for example, 200 sccm and 10000 sccm, respectively (Step S3). Incidentally, a flow rate of the N₂ gas from the separation gas supplying pipe 51 may be about 5000 sccm.

Because the wafers W alternately pass through the process area P1 and the process area P2 due to the rotation of the susceptor 2, the BTBAS gas is adsorbed on the wafers W and then the O₃ gas is adsorbed on the wafers W to oxidize the BTBAS gas adsorbed on the wafers W, thereby forming one or more layers of the silicon oxide as a reaction product of the BTBAS gas and the O₃ gas. The rotations of the susceptor 2 (adsorptions in the process areas P1, P2) are carried out predetermined times, for example, 20 times, so that the silicon oxide film having 1/N (N≧2), or 1/8 (N=8, 80/8=10 nm) in this example, of the target thickness T is deposited on the wafers W (deposition step: Step S4).

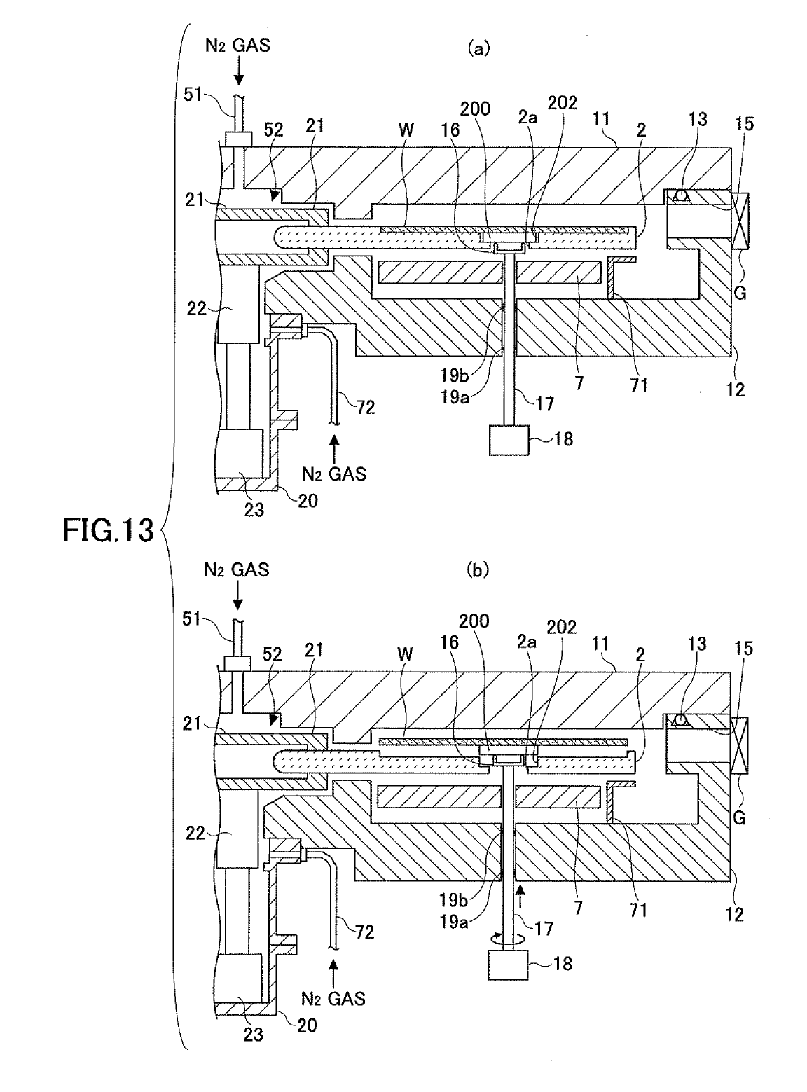

Next, the supply of the BTBAS gas is terminated, and the susceptor 2 is rotated and stopped so that the wafer receiving portion 24 is located above the lift pins 16 as an intermediate step (Step S5), as shown in a subsection (a) of FIG. 13. When the supply of the BTBAS gas is terminated, the BTBAS gas in the vacuum chamber 1 is immediately evacuated, so that the wafers W are not influenced by the BTBAS gas even when the rotation of susceptor 2 is stopped. As shown in a subsection (b) of FIG. 13, the wafer W is brought upward and rotated by 360°/N, namely 360°/8=45° in this example by the lift pins 16 in a rotation step. Then, the wafer W is brought down onto the wafer receiving portion 24 (Step S6). After this, the susceptor 2 is intermittently rotated, so that the above rotation of the wafer W is carried out for the remaining wafers W. Incidentally, when the supply of the BTBAS gas is terminated, the supply of the O₃ gas may also be terminated.

Incidentally, the terminating of the supplying the BTBAS gas, the stopping of rotating the susceptor 2, and rotating the wafer W are carried out by sending control signals for controlling the valves (not shown) provided in the gas supplying pipe 31b (FIG. 3), the driving portion 23, and the elevation mechanism (the lift pins 16, the elevation shaft 17, and the elevation apparatus 18 (FIG. 10) to these components and elements from the control portion 100.

Next, another film deposition step is carried out by rotating the susceptor 2 and supplying the BTBAS gas, so that a silicon oxide film having a thickness of 10 mm (target thickness T/N=80/8) is deposited on the wafer W (Step S7). Here, because the wafer W is rotated clockwise by 45° in the rotation step (Step S6), the wafer W differs in orientation at Step S7 compared with the same wafer W at Step S4, and passes through and below the process areas P1, P2. After Step S7 is completed, the silicon oxide film having a total thickness of 20 nm (target thickness T/N×2=80/8×2) has been deposited on the wafer W.

Subsequently, the intermittent step, the rotation step, and the film deposition step are repeated (N−2) times, or 6 times in this example (Step S8). In other words, the supply of the BTBAS gas is terminated and the rotation of the susceptor 2 is stopped (the intermediate step); the wafers W are rotated by 45° (the rotation step); another 10 nm (T/N=80/8) of the silicon oxide is deposited on the wafer W; and these steps are repeated 6 times in the written order. According to these repetitions, the silicon oxide film having a thickness of 10 nm is deposited on the wafers W after every wafer rotation of 45°, and thus the silicon oxide film having a thickness of 60 nm (10 nm×6 rotations) is deposited on the wafers W after rotation of 270° (45°×6 rotations). Therefore, the silicon oxide film having a total thickness of 80 nm (60 nm+20 nm) is deposited on the wafers W after the wafers W are rotated 315° (45°+270°) around substantially the center thereof, when compared to the wafers W before the film deposition (or at the time the wafers W are transferred into the vacuum chamber 1).

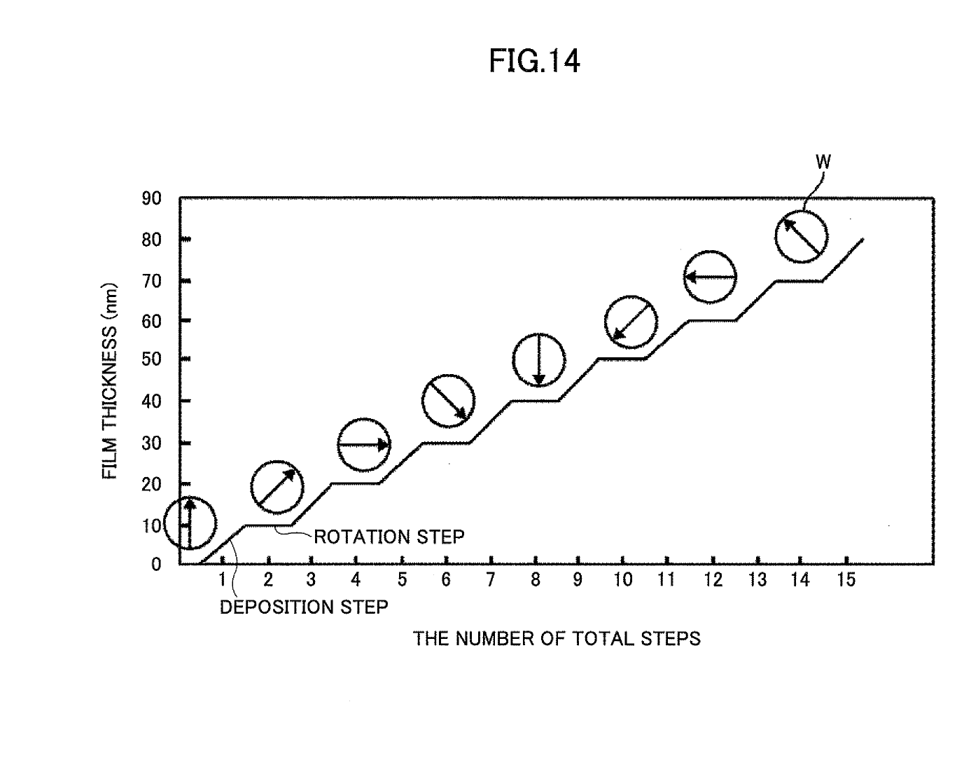

FIG. 14 schematically illustrates a relationship between the rotation angle of the wafers W and a thickness of the silicon oxide film to be deposited on the wafers W. As shown, the wafers W alternatively undergo the 8 (N) deposition steps in total and the 7 (N−1) rotation steps in total, and as a result, the silicon oxide film having a thickness of 80 nm is deposited while the wafers W are rotated substantially one revolution (specifically, 315°). Incidentally, arrows on the wafer W in FIG. 14 schematically represent the rotations of the wafer W at every rotation step. For example, the leftmost arrow represents the wafer W before the first film deposition step begins, and the next arrow to the immediate right represents the wafer W that is rotated by 45° in the first rotation step. In addition, the horizontal axis indicates the number of steps combining the film deposition step and the subsequent rotation step.

After the film deposition process is completed in the above manner, the supply of the gases is terminated, and the vacuum chamber 1 is evacuated to vacuum. Then, the wafers W are transferred out from the vacuum chamber 1 by the transfer arm 10 and the elevation plate 200, following procedures opposite to when the wafers W are transferred into the vacuum chamber 1. Incidentally, because the wafers W are rotated by 315° in total after the film deposition process as stated above, each of the wafers W may be rotated by an angle of 45° by the lift pins 16, so that the wafers W are oriented in the same direction as the wafers W at the time the wafers W are transferred into the vacuum chamber 1.

In this embodiment, after the susceptor 2 is rotated predetermined times in order to allow the wafers W to alternately pass through the process areas P1, P2 where the corresponding two types of the reaction gases (the BTBAS gas and the O₃ gas) are supplied to the upper surface of the wafers W, which leads to deposition of a film having a predetermined thickness on the wafers W, the wafers W are rotated around their respective centers, and the film deposition step is repeated. Therefore, even if a film tends to be thick at some areas and thin at other areas in the wafer W placed in the wafer receiving portion 24 of the susceptor 2, such thickness difference can be cancelled out because the thick area may be positioned in the thin area by the rotation of the wafer W and a relatively thin film is deposited on the area in the next film deposition step, and vice versa. Accordingly, even when film thickness variations may be caused by, for example, a non-uniform flow of the reaction gases or non-uniform reaction gas concentration, such non-uniformity can be cancelled out, and thus the film thickness and property uniformities across the wafer W can be improved.

In the above example, the 8 film deposition steps are carried out with the 7 rotation steps of rotating each of the wafers W by 45°, each of which is carried out every two film deposition steps, in order to deposit the silicon oxide film having the target thickness T. According to this, thickness variations at each step are cancelled out, and a thickness uniformity of 1% or less can be realized, as described later.

In addition, because the wafers W are rotated around their respective centers inside the vacuum chamber 1, it does not take a long time to rotate the wafers W compared to a case where the wafers W are rotated outside the vacuum chamber 1. Therefore, the thickness uniformity across the wafer can be improved without reducing throughput.

The number N of the film deposition steps may be two (with one rotation step, the rotation angle of 180°) or more, which is understood from simulation results described later. While the greater number of the film deposition steps is thought to result in better uniformity, it may decrease the throughput. Therefore, the film deposition steps are preferably repeated two to eight times. In addition, while the silicon oxide film having the same thickness is deposited in each of the N film deposition steps in the above example, the silicon oxide films having different thicknesses may be deposited in the corresponding film deposition steps. For example, in the case of the target thickness of 80 nm, the silicon oxide film having 60 nm is deposited in the first film deposition step, and the silicon oxide film having 20 nm is deposited in the second film deposition step after a wafer rotation of 180°. Even in this case, the film uniformity can be improved compared to a case where the wafers W are not rotated around their respective centers. In addition, while each of the wafers W is rotated by 360°/N in each rotation step in the above example, the rotation angle θ may be set in the following manner, as long as the target thickness is realized after the film deposition process. For example, when depositing a silicon oxide film having a target thickness T of 80 nm, each of the wafers W may be rotated by 30° in each rotation step, or by 45° in the first rotation step and 30° in the subsequent 6 rotation steps. Moreover, after a silicon oxide film of 60 nm thick is deposited on the wafers W in the first film deposition step and each of the wafers W is rotated by 90° in the first rotation step, a silicon oxide film of 20 nm thick may be deposited in the next film deposition step in the case of a target thickness T of 80 nm, in other embodiments. In other words, as long as a silicon oxide film is deposited on the wafers W in the first deposition step and on the wafers W rotationally shifted by a rotation angle θ (≠0, 360) in any one of the second or later film deposition steps, the film thickness at each deposition step and the rotation angle at each rotation step may be arbitrarily determined. Even when the film thickness at each deposition step and the rotation angle at each rotation step are arbitrarily determined, the film thickness uniformity can be improved more than that in a case where the silicon oxide film is deposited without rotating the wafers W around their respective centers.

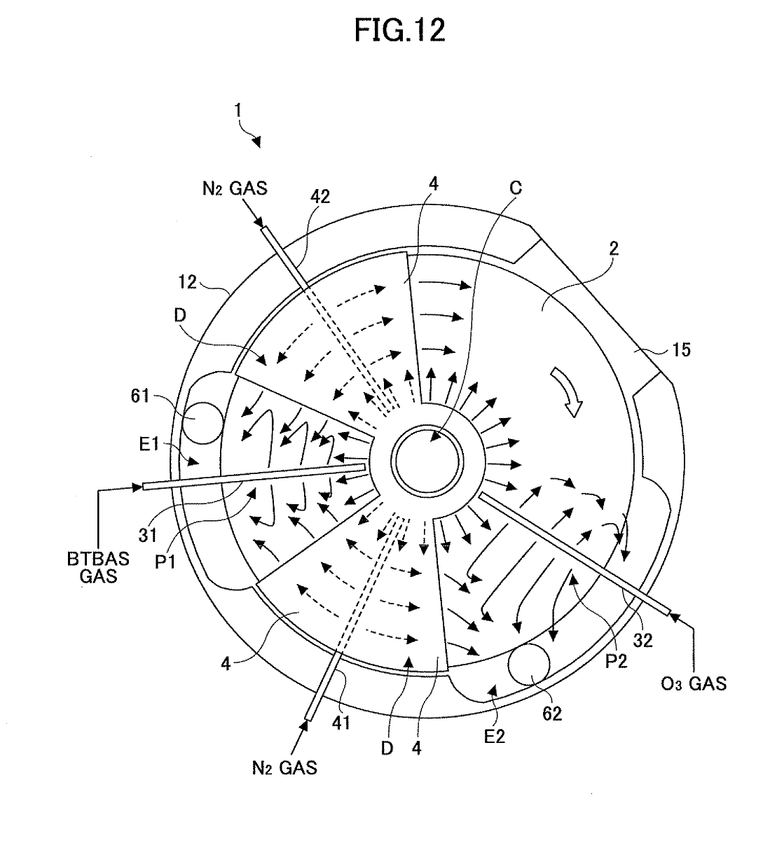

In the film deposition apparatus according to this embodiment, because the N₂ gas is supplied in the separation area D between the process areas P1, P2 and in the center area C, the BTBAS gas and the O₃ gas are evacuated without being intermixed with each other, as shown in FIG. 12. In addition, there are the narrow gaps between the bent portion 46 and the outer circumferential surface of the susceptor 2, and the BTBAS gas and the O₃ gas are not intermixed through the gaps. Therefore, atmospheres in the process area P1 and the second area P2 are completely separated; the BTBAS gas is evacuated through the evacuation port 61; and the O₃ gas is evacuated through the evacuation port 62. As a result, the BTBAS gas and the O₃ gas are not intermixed in gaseous phase with each other.

In addition, because the evacuation areas E1, E2 are formed by the indented inner circumferential surface of the chamber body 12, corresponding to the spaces below the higher ceiling surfaces 45 where the reaction gas nozzles 31, 32 are arranged and the evacuation ports 61, 62 are positioned below the evacuation areas E1, E2, respectively, the thin spaces below the convex portions 4 have a higher pressure than the center area C and the spaces below the higher ceiling surfaces 45.

Incidentally, because the heater unit housing space below the susceptor 2 is purged with the N₂ gas, the BTBAS gas that has flowed into the evacuation area E1 and the O₃ gas that has flowed into the evacuation area E2 are not intermixed with each other through the heater unit housing space.

Furthermore, because the ALD (MLD) is carried out by allowing the plural wafers W to alternately pass through and below the process areas P1, P2 due to the rotation of the susceptor 2 on which the plural wafers W are placed along the circumferential direction of the susceptor 2, this process can be carried out at higher production throughput. In addition, there are provided the separation areas D including the lower ceiling surface 44 between the process areas P1, P2 in the rotation direction and the center area C defined by the rotation center portion of the susceptor 2 and the vacuum chamber 1. Moreover, the separation gases are supplied from the separation areas D and the center area C toward the process areas P1, P2, and the reaction gases supplied to the process areas P1, P2 are evacuated along with the separation gases through the gap between the outer circumference of the susceptor 2 and the inner circumferential surface of the vacuum chamber 1. Therefore, the reaction gases are substantially prevented from being intermixed. As a result, an appropriate ALD (MLD) mode deposition can be realized, and deposition of the reaction product on the susceptor 2 is prevented, or extremely reduced, thereby reducing generation of particles. Incidentally, the present invention may be applied when only one wafer W is placed on the susceptor 2.

Next, a gas flow pattern in the vacuum chamber of the film deposition apparatus according to this embodiment of the present invention is explained.

FIG. 12 schematically illustrates a flow pattern of the gases supplied from the gas nozzles 31, 32, 41, 42 into the vacuum chamber 1. As shown, part of the O₃ gas, even if only a little, ejected from the second reaction gas nozzle 32 hits and flows along the top surface of the susceptor 2 (and the surface of the wafer W) in a direction opposite to the rotation direction of the susceptor 2. Then, the O₃ gas is pushed back by the N₂ gas flowing along the rotation direction, and changes the flow direction toward the edge of the susceptor 2 and the inner circumferential wall of the chamber body 12. Finally, this part of the O₃ gas flows into the evacuation area E2 and is evacuated from the chamber 1 through the evacuation port 62.

Another part of the O₃ gas ejected from the second reaction gas nozzle 32 hits and flows along the top surface of the susceptor 2 (and the surface of the wafers W) in the same direction as the rotation direction of the susceptor 2. This part of the O₃ gas mainly flows toward the evacuation area E2 due to the N₂ gas flowing from the center portion C and suction force through the evacuation port 62. On the other hand, a small portion of this part of the O₃ gas flows toward the separation area D located downstream of the rotation direction of the susceptor 2 in relation to the second reaction gas nozzle 32 and may enter the gap between the ceiling surface 44 and the susceptor 2. However, because the height h of the gap is designed so that the O₃ gas is impeded from flowing into the gap under film deposition conditions intended, the small portion of the O₃ gas cannot flow into the gap. Even if a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the top surface of the susceptor 2 in the rotation direction flows into the evacuation area E2 and is evacuated by the evacuation port 62, as shown in FIG. 12.

Similarly, part of the BTBAS gas ejected from the first reaction gas nozzle 31 to flow along the top surface of the susceptor 2 (and the surface of the wafers W) in a direction opposite to the rotation direction of the susceptor 2 is substantially prevented from flowing into the gap between the susceptor 2 and the ceiling surface 44 of the convex portion 4 located upstream relative to the rotation direction of the susceptor 2 in relation to the first reaction gas supplying nozzle 31. Even if only a fraction of the BTBAS gas flows into the gap, this BTBAS gas is pushed backward by the N₂ gas ejected from the separation gas nozzle 41 in the separation area D. The BTBAS gas pushed backward flows toward the outer circumferential edge of the susceptor 2 and the inner circumferential wall of the chamber body 12, along with the N₂ gases from the separation gas nozzle 41 and the center portion C, and then is evacuated by the evacuation port 61 through the evacuation area El.

Another part of the BTBAS gas ejected from the first reaction gas nozzle 31 to flow along the top surface of the susceptor 2 (and the surface of the wafers W) in the same direction as the rotation direction of the susceptor 2 cannot flow into the gap between the susceptor 2 and the ceiling surface 44 of the convex portion 4 located downstream relative to the rotation direction of the susceptor 2 in relation to the first reaction gas supplying nozzle 31. Even if a fraction of this part of the BTBAS gas flows into the gap, this BTBAS gas is pushed backward by the N₂ gases ejected from the center portion C and the separation gas nozzle 42 in the separation area D. The BTBAS gas pushed backward flows toward the evacuation area El, along with the N₂ gases from the separation gas nozzle 41 and the center portion C, and then is evacuated by the evacuation port 61.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. The BTBAS molecules and the O₃ molecules adsorbed on the wafer W are allowed to go through the separation area D, contributing to the film deposition.

Additionally, the BTBAS gas in the process area P1 (the O₃ gas in the process area P2) is substantially prevented from flowing into the center area C, because the separation gas is ejected toward the outer circumferential edge of the susceptor 2 from the center area C, as shown in FIGS. 8 and 12. Even if a fraction of the BTBAS gas in the process area P1 (the O₃ gas in the process area P2) flows into the center area C, the BTBAS gas (the O₃ gas) is pushed backward, so that the BTBAS gas in the process area P1 (the O₃ gas in the process area P2) is substantially prevented from flowing into the process area P2 (the process area P1) through the center area C.

Moreover, the BTBAS gas in the process area P1 (the O₃ gas in the process area P2) is substantially prevented from flowing into the process area P2 (the process area P1) through the space between the susceptor 2 and the inner circumferential wall of the chamber body 12. This is because the bent portion 46 is formed downward from the convex portion 4 so that the gaps between the bent portion 46 and the susceptor 2 and between the bent portion 46 and the inner circumferential wall of the chamber body 12 are as small as the height h of the ceiling surface 44 of the convex portion 4, the height being measured from the susceptor 2, thereby substantially avoiding gaseous communication between the two process areas P1, P2, as stated above. Therefore, the BTBAS gas is evacuated via the evacuation port 61, and the O₃ gas is evacuated via the evacuation port 62, and thus the two reaction gases are not intermixed. In addition, the space (heater unit housing space) below the susceptor 2 is purged by the N₂ gas supplied from the purge gas supplying pipes 72, 73. Therefore, the BTBAS gas cannot flow through and below the susceptor 2 into the process area P2.

Incidentally, during the film deposition process, the N₂ gas as the separation gas is also supplied from the separation gas supplying pipe 51, and thus the N₂ gas is ejected toward the upper surface of the susceptor 2 from the center area C, namely the space 50 between the protrusion portion 5 and the susceptor 2. In this embodiment, a space that is below the higher ceiling surface 45 and in which the reaction gas nozzle 31 (32) is arranged has a lower pressure than that in the thin space between the lower ceiling surface 44 and the susceptor 2. This is partly because the evacuation area El (E2) is provided adjacent to the space below the ceiling surface 45, and the space is evacuated directly through the evacuation area E1 (E2), and partly because the height h of the thin space is designed to maintain the pressure difference between the thin space and the space where the reaction gas nozzle 31 (32) is arranged.

As stated above, because the two source gases (BTBAS gas, O₃ gas) are substantially prevented from being intermixed in the vacuum chamber 1 of the film deposition apparatus according to this embodiment, a substantially realistic ALD can be realized, thereby providing excellent film thickness controllability.

### Second Embodiment

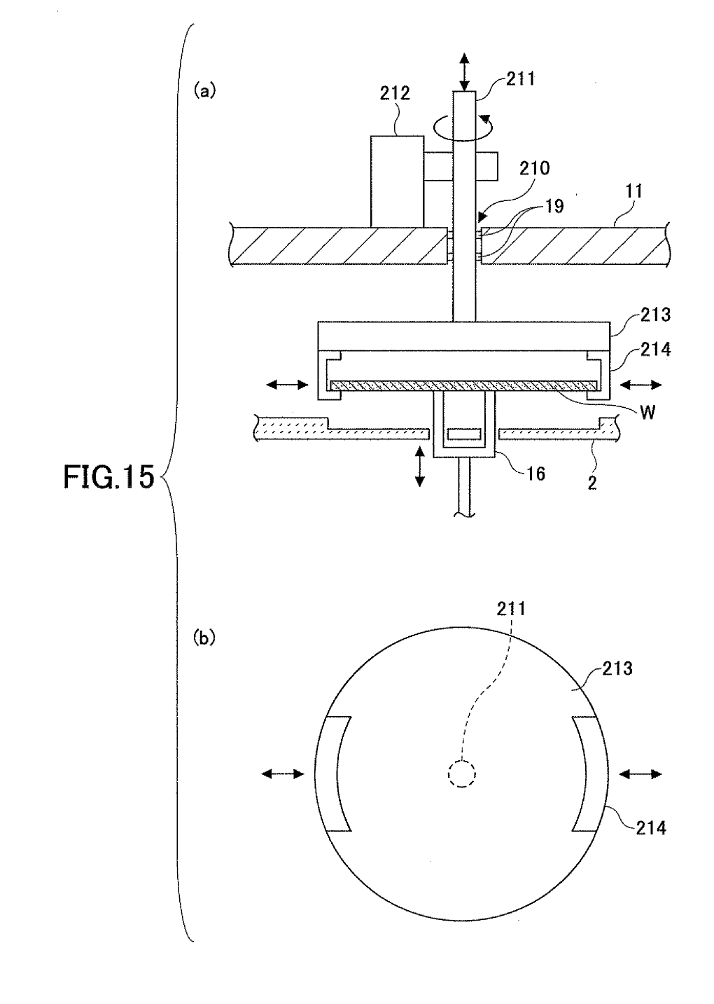

While the film deposition apparatus according to the first embodiment is provided with the elevation mechanism 18 that brings upward/downward and rotates the wafer W, a film deposition apparatus according to a second embodiment is provided with an elevation mechanism and a rotation mechanism that are separated from each other. Specifically, a through-hole 210 is formed above the lift pins 16 and in the ceiling plate 11, and an elevation shaft 211 is provided in order to extend from above the ceiling plate 11 into the vacuum chamber 1 through the through-hole 210, as shown in a subsection (a) of FIG. 15. In addition, a rotation mechanism 212 that rotates the elevation shaft 211 around a vertical axis thereof is arranged on the ceiling plate 11. The rotation mechanism 212 can bring the elevation shaft 211 upward/downward. Moreover, an elevation plate 213 is connected to a bottom end of the elevation shaft 211, and holding mechanisms 214, 214 having an inner indented portion for holding the wafer W from both sides thereof in order to support a back side surface of the wafer W are arranged below the elevation plate 213. The holding mechanisms 214, 214 oppose each other along a direction of a diameter of the wafer W, and are apart from each other in a distance greater than a diameter of the wafer W. Incidentally, the same reference symbols are given to the same and corresponding members and components as the previously explained members and components, in FIG. 15. In addition, a subsection (b) of FIG. 15 illustrates a lower side of the elevation plate 213.

When the wafer W is not rotated around its center, for example, when the wafer W is transferred into/out from the vacuum chamber 1, or the film deposition is being carried out, the elevation plate 213 (holding mechanism 214) is positioned near the inner surface of the ceiling plate 11 in order not to interfere with the susceptor 2. When the wafer W needs to be rotated around its center, the wafer W is positioned above the lift pins 16 by rotating and stopping the susceptor 2, and the elevation plate 213 (holding mechanism 214) is lowered, keeping the holding mechanisms 214, 214 apart from each other at the distance greater than the diameter of the wafer W. Next, the lift pins 16 bring upward and hold the wafer W so that the wafer W is positioned between the holding mechanisms 214, 214. Then, the holding mechanisms 214, 214 are moved closer to each other until the edge of the wafer W enters the indented portions of the holding mechanisms 214, 214. Subsequently, when the lift pins 16 are lowered, the wafer W is held at its back surface by the holding mechanisms 214, 214. Then, the wafer W is rotated around its center by a predetermined rotation angle by the rotation mechanism 212. After this, the lift pins 16 are raised to hold the back surface of the wafer W, and procedures opposite to the procedures where the wafer W is transferred from the lift pins 16 to the holding mechanism 214, 214 are carried out, so that the wafer W is placed in the wafer receiving portion 24. According to the second embodiment, the film deposition step and the rotation step are carried out in the same manner as the first embodiment, and thus the same effect as the first embodiment is demonstrated.

### Third Embodiment

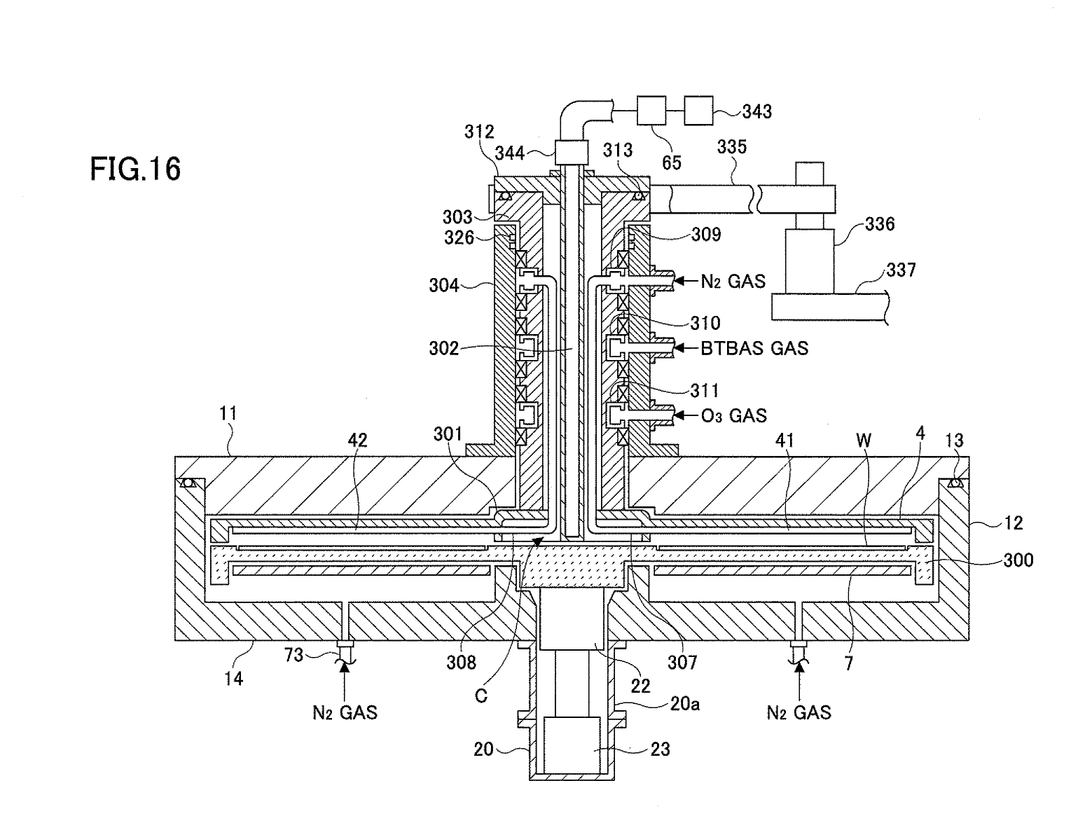

While the susceptor 2 is rotated in relation to the gas nozzles 31, 32, 41, 42 in the above embodiments, the gas nozzles 31, 32, 41, 42 may be rotated in relation to the stationary susceptor 2. As a third embodiment, a configuration that enables such relative rotation is explained with reference to FIGS. 16 through 20.

A susceptor 300 is provided in the vacuum chamber 1, in the place of the susceptor 2 explained in the above embodiments. A rotational shaft 22 is connected to a center of a lower surface of the susceptor 300 in order to rotate the susceptor 300 when the wafers W are placed on and removed from the susceptor 300. Five wafer receiving portions 24, each of which has the elevation plate 200, are formed on the susceptor 300 in this embodiment.

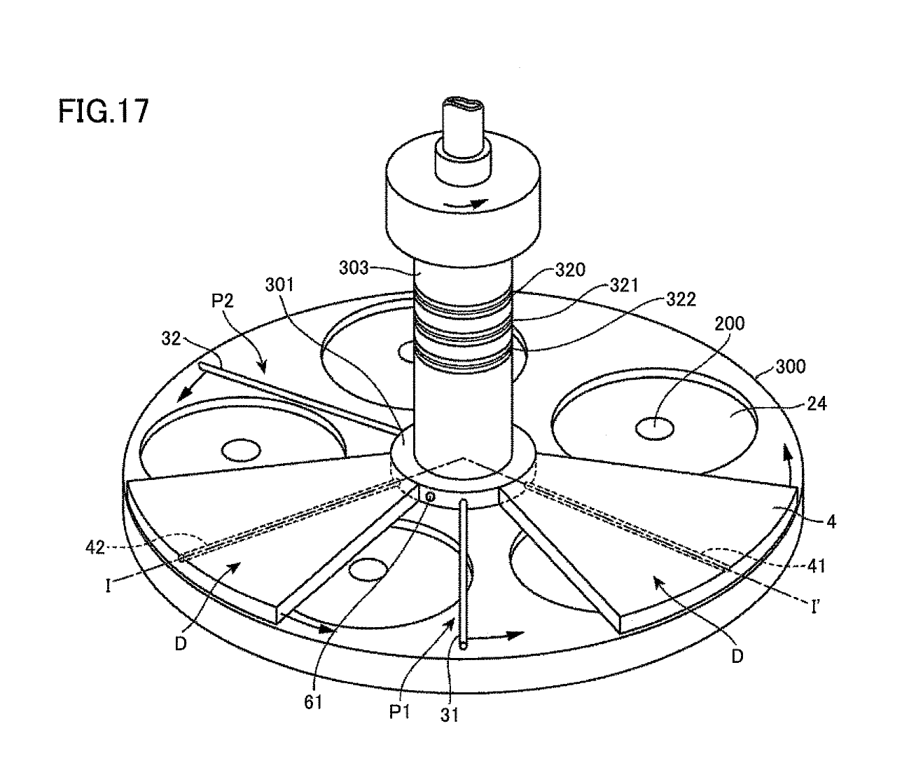

As shown in FIGS. 16 through 18, the gas nozzles 31, 32, 41, 42 are attached to a planar core portion 301 that has a disk shape and are provided above a center portion of the susceptor 300. Base portions of the gas nozzles 31, 32, 41, 42 penetrate a circumferential wall of the core portion 301. The core portion 301 is configured to be rotatable counterclockwise around a vertical axis, as described later. By rotating the core portion 301, the gas nozzles 31, 32, 41, 42 are rotated above the susceptor 300. Incidentally, FIG. 17 illustrates a positional relationship among the susceptor 300, the gas nozzles 31, 32, 41, 42, and the convex portions 4.

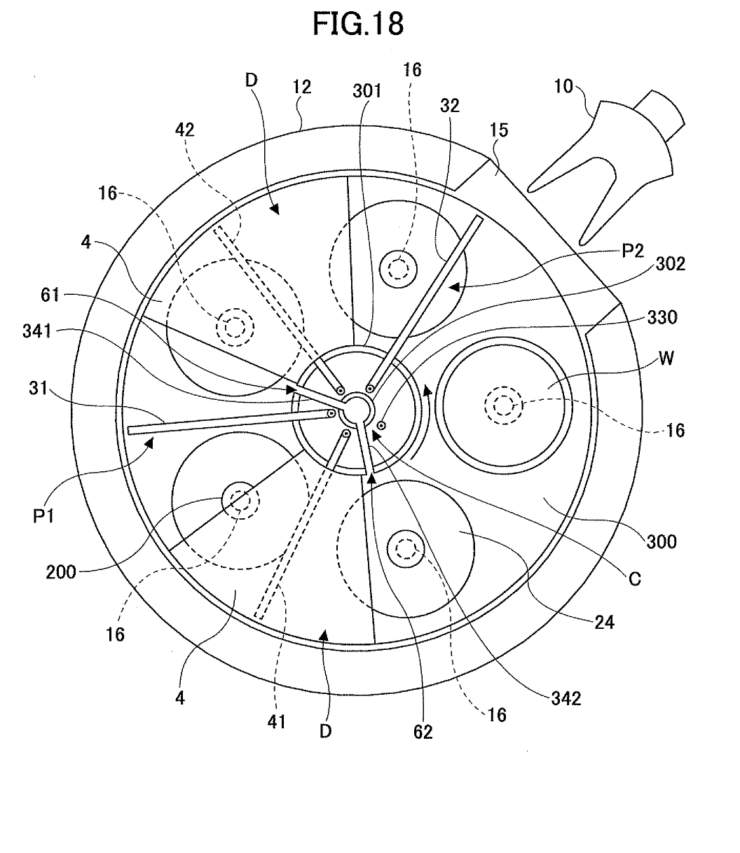

As shown in FIG. 17, the convex portions 4 are attached to the circumferential surface of the core portion 301, and thus rotated along with the gas nozzles 31, 32, 41, 42. Two evacuation ports 61, 62 are provided on the circumferential surface of the core portion 301. Specifically, the evacuation port 61 is formed between the reaction gas nozzle 31 and the convex portion 4 located upstream of the rotation direction of the reaction gas nozzle 31, and the evacuation port 62 is formed between the reaction gas nozzle 32 and the convex portion 4 located upstream of the rotation direction of the reaction gas nozzle 32. These evacuation ports 61, 62 are connected to an evacuation pipe 302 via corresponding conduits 341, 342 (FIG. 18), so that the reaction gases and the separation gases are evacuated from the process areas P1, P2. With these configurations, the evacuation port 61 evacuates substantially exclusively the BTBAS gas ejected from the reaction gas nozzle 31, and the evacuation port 62 evacuates substantially exclusively the O₃ gas ejected from the reaction gas nozzle 32.

As shown in FIG. 16, a rotational cylinder 303 is connected to a center portion of an upper surface of the core portion 301, and is rotatable around a vertical axis inside a sleeve 304 attached on the ceiling plate 11 of the vacuum chamber 1. When the rotational cylinder 303 is rotated, the core portion 301 is rotated by the rotational cylinder, and thus the gas nozzles 31, 32, 41, 41 are rotated by the core portion 301. The core portion 301 provides an open space on the lower side thereof. In this open space, the gas nozzles 31, 32, 41, 42 that penetrate the circumferential wall of the core portion 301 are connected to a first reaction gas supplying pipe 305, a second reaction gas supplying pipe 306, a first separation gas supplying pipe 307, and a second separation gas supplying pipe 308, respectively. The first reaction gas supplying pipe 305 is connected to a BTBAS gas supplying source (not shown), the second reaction gas supplying pipe 306 is connected to an O₃ gas supplying source (not shown), and the first and the second separation gas supplying pipes 307, 308 are connected to separation gas supplying sources (not shown). Incidentally, only the separation gas supplying pipes 307, 308 are illustrated in FIG. 16, for the sake of convenience.

The gas supplying pipes 305, 306, 307, 308 are bent upward in an L shape near the rotation center of and in the open space of the core portion 301 (or around the evacuation pipe 302), penetrate a ceiling portion of the core portion 301, and extend upward inside the cylinder 303.

As shown in FIGS. 16, 17, and 19, the rotational cylinder 303 has a small cylinder and a large cylinder stacked on the small cylinder. The larger cylinder is rotatable supported by an upper end surface of the sleeve 304. The smaller cylinder of the cylinder 303 is inserted into the sleeve 304 and is rotatable inside the sleeve 304, while the bottom end portion of the cylinder 303 (the smaller cylinder) is connected to the core portion 301.

In an outer circumferential surface of the cylinder 303, three ring-shaped gas spreading conduits are provided along the outer circumferential surface at predetermined vertical intervals. In the illustrated examples, a separation gas spreading conduit 309 for spreading the separation gas is arranged at the top; a BTBAS gas spreading conduit 310 for spreading the BTBAS gas is arranged in the middle; and an O₃ gas spreading conduit 311 for spreading the O₃ gas is arranged at the bottom. In FIG. 16, a reference symbol 312 represents a lid portion of the rotational cylinder 303, and a reference symbol 313 represents a sealing member such as an O-ring by which the lid portion 312 and the rotational cylinder 303 are closely (or hermetically) coupled with each other.

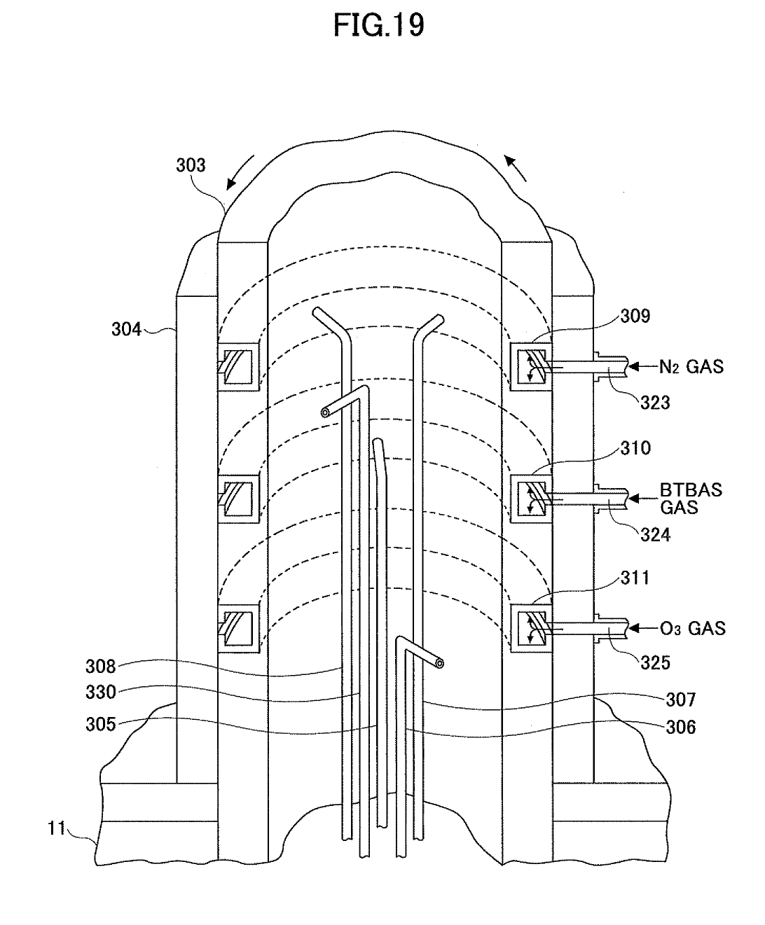

The gas spreading conduits 309 through 311 have corresponding slits 320, 321, 322 open toward the inner circumferential surface of the sleeve 304. The corresponding gases are supplied to the gas spreading conduits 309 through 311 through the corresponding slits 320, 321, 322. In addition, as shown in FIG. 19, gas supplying ports 323, 324, 325 are provided at levels corresponding to the slits 320, 321, 322 in the sleeve 304 that surrounds the rotational cylinder 303. The gases supplied to the gas supplying ports 323, 324, 325 flow into the corresponding gas spreading conduits 309, 310, 311 through the corresponding slits 320, 321, 322, which are open toward the gas supplying ports 323, 324, 325.

The rotational cylinder 303 inserted into the inside of the sleeve 304 has an outer diameter that is as close to an inner diameter of the sleeve 304 as possible, which makes it possible to close the slits 320, 321, 322 with the inner surface of the sleeve 304, except for the gas supplying ports 323, 324, 325. As a result, the gases supplied to the corresponding gas spreading conduits 309, 310, 311 can spread only in the gas spreading conduits 309, 310, 311, and do not leak into the vacuum chamber 1 or outside of the film deposition apparatus. Incidentally, a reference symbol 326 in FIG. 16 represents a sealing member such as a magnetic fluid sealing that prevents the gases from leaking out through a gap between the rotational cylinder 303 and the sleeve 304. Although not shown, the sealing members 326 are provided above and below each of the gas spreading conduits 309, 310, 311, so that the gas spreading conduits 309, 310, 311 are certainly sealed. In FIG. 19, the sealing member 326 is omitted.

Referring to FIG. 19, the gas supplying pipes 307, 308 are connected at the inner circumferential surface of the rotational cylinder 303 to the gas spreading conduit 309; the first reaction gas supplying pipe 305 is connected at the inner circumferential surface of the rotational cylinder 303 to the gas spreading conduit 310; and the second reaction gas supplying pipe 306 is connected at the inner circumferential surface of the rotational cylinder 303 to the gas spreading conduit 311. With such configurations, the separation gas supplied from the gas supplying port 323 spreads in the gas spreading conduit 309 and flows into the vacuum chamber 1 through the gas supplying pipes 307, 308 and the separation gas nozzles 41, 42 in this order; the first reaction gas (BTBAS gas) supplied from the gas supplying port 324 spreads in the gas spreading conduit 310 and flows into the vacuum chamber 1 through the gas supplying nozzle 305 and the first reaction gas nozzle 31 in this order; and the second reaction gas (O₃ gas) supplied from the gas supplying port 325 spreads in the gas spreading conduit 311 and flows into the vacuum chamber 1 through the gas supplying nozzle 306 and the second reaction gas nozzle 32 in this order. Incidentally, the evacuation pipe 302 (FIG. 16) is omitted in FIG. 19, for the sake of convenience.

As shown in FIG. 19, a purge gas supplying pipe 330 is connected to the separation gas spreading conduit 309, extends downward inside the rotational cylinder 303, and is open to the inner space (open space) of the core portion 301, so that N₂ gas can be supplied into the inner space. As shown in FIG. 16, the core portion 301 is supported by the rotational cylinder 303 so that the bottom end of the core portion 301 is located at the height h from the upper surface of the susceptor 300. With this, the core portion 301 can be rotated without interfering with the susceptor 300. If there is a gap between the susceptor 300 and the core portion 301, the BTBAS (O₃) gas in the process area P1 (P2) may flow into the process area P2 (P1) through the gap between the susceptor 300 and the core portion 301.

However, because the N₂ gas is supplied from the purge gas supplying pipe 330 to the inner space of the core portion 301, the inner space being open toward the susceptor 301, and flows toward the process areas P1, P2 through the gap between the core portion 301 and the susceptor 300, the BTBAS (O₃) gas in the process area P1 (P2) can be substantially prevented from flowing into the process area P2 (P1) through the gap between the susceptor 300 and the core portion 301, in this embodiment. Namely, the film deposition apparatus in this embodiment includes the center area C that is defined by the center portions of the susceptor 300 and the vacuum chamber 1 and has an ejection opening formed along the rotation direction of the core portion 301 in order to eject the N₂ gas along the upper surface of the susceptor 300. In this case, the N₂ gas serves as the separation gas to substantially prevent the BTBAS (O₃) gas in the process area P1 (P2) from flowing into the process area P2 (P1) through the gap between the susceptor 300 and the core portion 301. Incidentally, the gap between the core portion 301 and the susceptor 300 corresponds to the ejection opening.

Referring again to FIG. 16, a driving belt 335 is wound around an outer circumference of the larger cylinder of the rotational cylinder 303. The driving belt 335 conveys rotational force from the driving portion 336 as a rotation mechanism arranged above the vacuum chamber 1 to the rotational cylinder 303, thereby rotating the rotational cylinder 303 inside the sleeve 304. As a result, the core portion 301 is rotated. Incidentally, a reference symbol 337 represents a supporting member that supports the driving portion 336 above the vacuum chamber 1.

In addition, the evacuation pipe 302 is arranged along the rotational center of the rotational cylinder 303 inside the rotational cylinder 303, as shown in FIG. 16. A bottom end portion of the evacuation pipe 302 penetrates the upper surface of the core portion 301 into the inner space of the core portion 301, and closes in the inner space. Suction pipes 341, 342 are connected at one end to a circumference of the evacuation pipe 302 extending inside the core portion 301, as shown in FIG. 18. In addition, the other ends of the suction pipes 341, 342 are open in the circumference of the core portion 301. With such configurations, the vacuum chamber 1 can be evacuated by the evacuation pipe 302 through the suction pipes 341, 342, without evacuating the N₂ gas inside the core portion 301.

Incidentally, while the evacuation pipe 302 is omitted in FIG. 19, as stated above, the gas supplying pipes 305, 306, 307, 308 and the purge gas supplying pipe 330 are arranged around the evacuation pipe 302.

As shown in FIG. 16, an upper end portion of the evacuation pipe 302 penetrates the lid portion 312 of the rotational cylinder 303 and is connected to, for example, a vacuum pump 343 as an evacuation portion. Incidentally, a reference symbol 344 represents a rotary joint that rotatably connects the evacuation pipe 302 to a pipe downstream of the evacuation pipe 302.

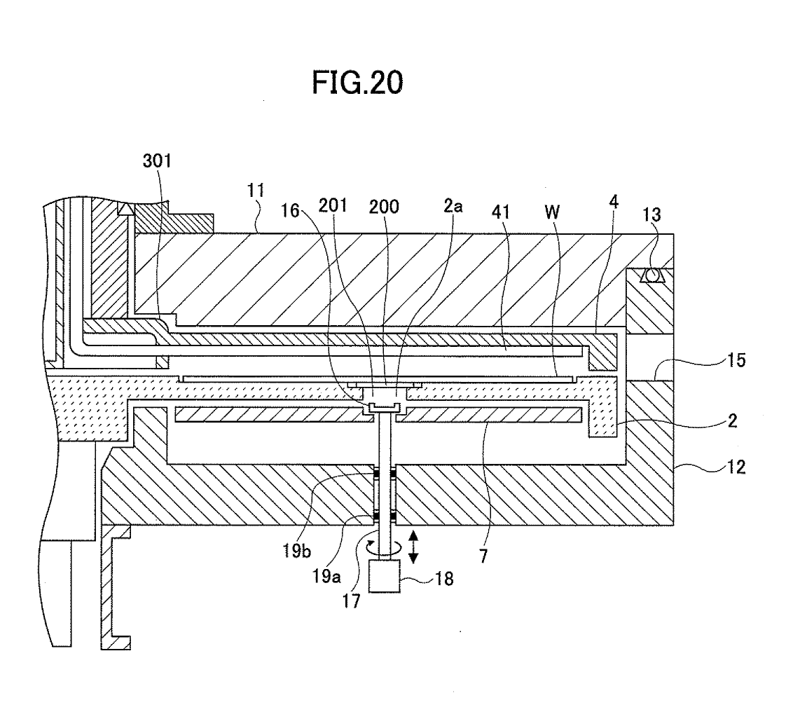

Referring to FIG. 20, the lift pins 16 are arranged below the susceptor 300. Specifically, the lift pins 16 are arranged below the corresponding wafer receiving portions 24, as shown FIG. 18. Namely, because the susceptor 300 is not rotated during the film deposition process but the gas nozzles 31, 32, 41, 42 and the rotational cylinder 303 are rotated in this embodiment, the lift pins 16, the elevation shafts 17, the elevation mechanisms 18, the bearing portions 19a, and the magnetic fluid sealing portions 19b are provided below the corresponding wafer receiving portions 24, so that the wafers W placed in the corresponding wafer receiving portions 24 can be independently rotated. In addition, when the wafer W is transferred into/out from the vacuum chamber 1, the susceptor 300 is rotated so that each of the wafer receiving portions 24 is aligned with the transfer opening 15 in a one-to-one manner. Therefore, the lift pins 16 are brought downward when the susceptor 300 needs to be rotated in order not to interfere with the susceptor 300 and upward when the wafers W need to be rotated.

A film deposition method using the film deposition apparatus according to this embodiment is explained in the following, focusing on steps different from the steps S1 through S8 shown in FIG. 11. First, the lift pins 16 are brought downward in order not to interfere with the rotation of the susceptor 300 at Step S1, and the wafers W are placed in the corresponding wafer receiving portions 24 while the susceptor 300 is intermittently rotated.

Next, the rotation of the susceptor 300 is stopped so that the wafer receiving portions 24 are located above the corresponding lift pins 16, at Step S2. Then, the rotational cylinder 303 is rotated counterclockwise. At this time, while the gas spreading conduits 309, 310, 311 provided in the rotational cylinder 303 are rotated accordingly, parts of the slits 320, 321, 322 of the corresponding gas spread conduits 309, 310, 311 are always open to corresponding openings of the gas supplying ports 323, 324, 325. Therefore, the gases can be continuously supplied to the corresponding gas spreading conduits 309, 310, 311.

The gases supplied to the gas spreading conduits 309, 310, 311 are supplied to the corresponding process areas P1, P2 and separation areas D from the corresponding reaction gas nozzles 31, 32 and separation gas nozzles 41, 42 through the corresponding gas supplying pipes 305, 306, 307, 308 connected to the corresponding gas spreading conduits 309, 310, 311. Because these gas supplying pipes 305, 306, 307, 308 are fixed on the rotational cylinder 303, and the reaction gas nozzles 31, 32 and the separation as nozzles 41, 42 are fixed on the rotational cylinder 303 through the core portion 301, the gas supplying pipes 305, 306, 307, 308 and the gas nozzles 31, 32, 41, 42 are rotated along with the rotational cylinder 303 and supply the corresponding gases to the vacuum chamber 1.

At this time, the purge gas supplying pipe 330 rotating integrally with the rotational cylinder 303 supplies the N₂ gas as the separation gas, and thus the N₂ gas is ejected from the center area C, namely, the gap between the core portion 301 and the susceptor 300, along the upper surface of the susceptor 300. In addition, because the evacuation ports 61, 62 are formed in the circumference of the core portion 301 in order to open to the spaces below the second ceiling surfaces 45 where the reaction gas nozzles 31, 32 are arranged, pressures of the spaces below the second ceiling surfaces 45 are lower than the pressures of the thin spaces below the first ceiling surface 44 and the center area C. Therefore, the BTBAS gas and the O₃ gas are not intermixed and are independently evacuated from the vacuum chamber 1 in the same manner as the film deposition apparatus in the previous embodiments.

During the film deposition step, the process areas P1, P2 and the separation areas D pass through and above the wafers W placed on the stationary susceptor 300. After the silicon oxide film having a predetermined thickness is deposited on the wafers W, the rotation step is carried out at a predetermined timing independently with respect to the wafers W in the same manner as explained above, so that the wafers W are independently rotated. When the wafers W are rotated in such a manner, the supply of the BTBAS gas and/or the O₃ gas maybe stopped; and the rotation of the rotational cylinder 303 maybe stopped. In addition, the supply of the BTBAS gas and the O₃ gas and the rotation of the rotational cylinder 303 are not necessarily stopped when the wafers W are rotated in the rotation step. In this case, when the process area P2 or the separation areas D pass through and above one of the wafers W, the wafer W is preferably rotated in order not to expose the wafer W to the BTBAS gas.

Even in this embodiment, the film deposition that can provide high thickness uniformity across the wafer is carried out providing the same effects and advantages as the previous embodiments. In addition, the holding mechanisms 214, 214 explained in the second embodiment may be provided in order to rotate the wafer W in the film deposition apparatus according to this embodiment where the gas nozzles 31, 32, 41, 42, the convex portion 4, and the rotational cylinder 303 are rotated. In this case, the rotation of the wafers W at the rotation step is carried out when the rotational cylinder 303 is stopped.

### Fourth Embodiment

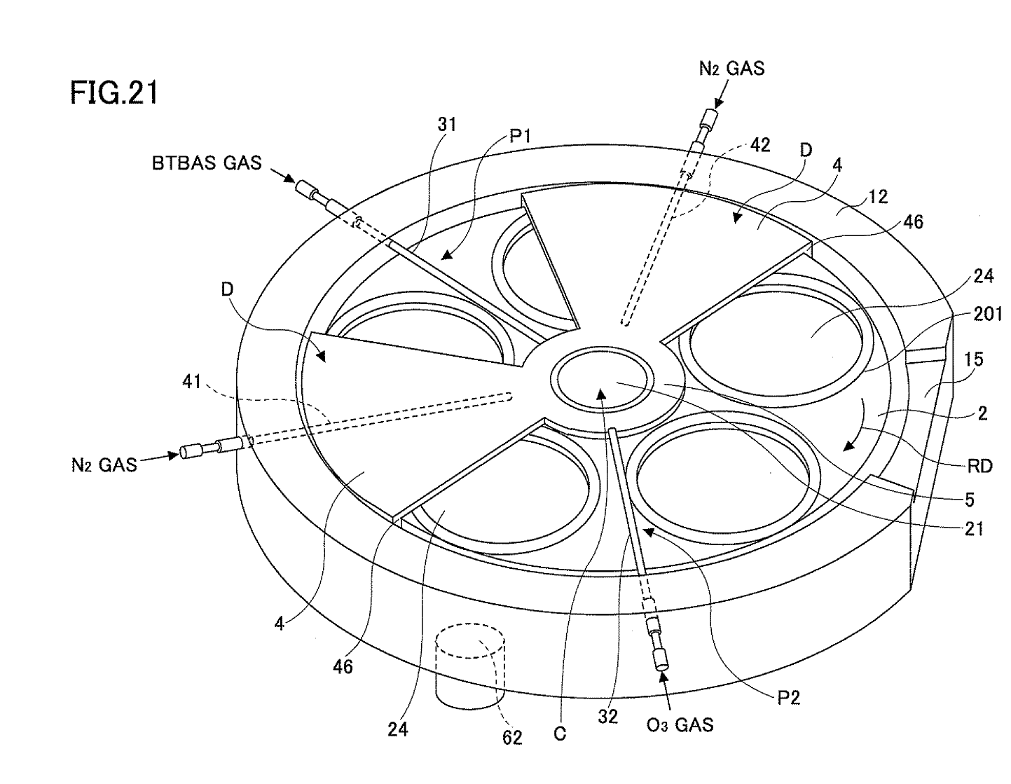

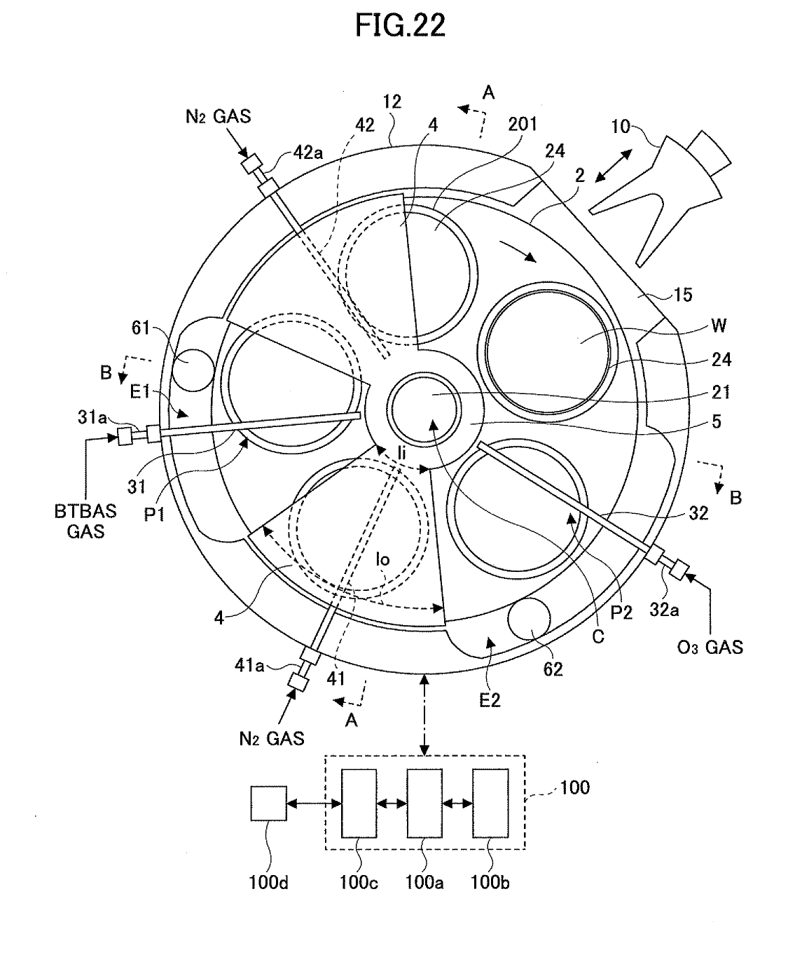

Next, a film deposition apparatus according to a fourth embodiment of the present invention is explained. Referring to FIGS. 21 and 22, plural (e.g., five) susceptor trays 201 having circular top view shapes are provided on the susceptor 2. In the illustrated example, the susceptor trays 201 are arranged at angular intervals of about 72° in the susceptor 2. An outer diameter of the susceptor tray 201 maybe larger than a diameter of the wafer W, for example, by about 10 mm through about 100 mm. Each of the susceptor trays 201 has a wafer receiving portion 24 having a circular concave shape. In FIG. 22, only one susceptor tray 201 is illustrated for the sake of convenience.

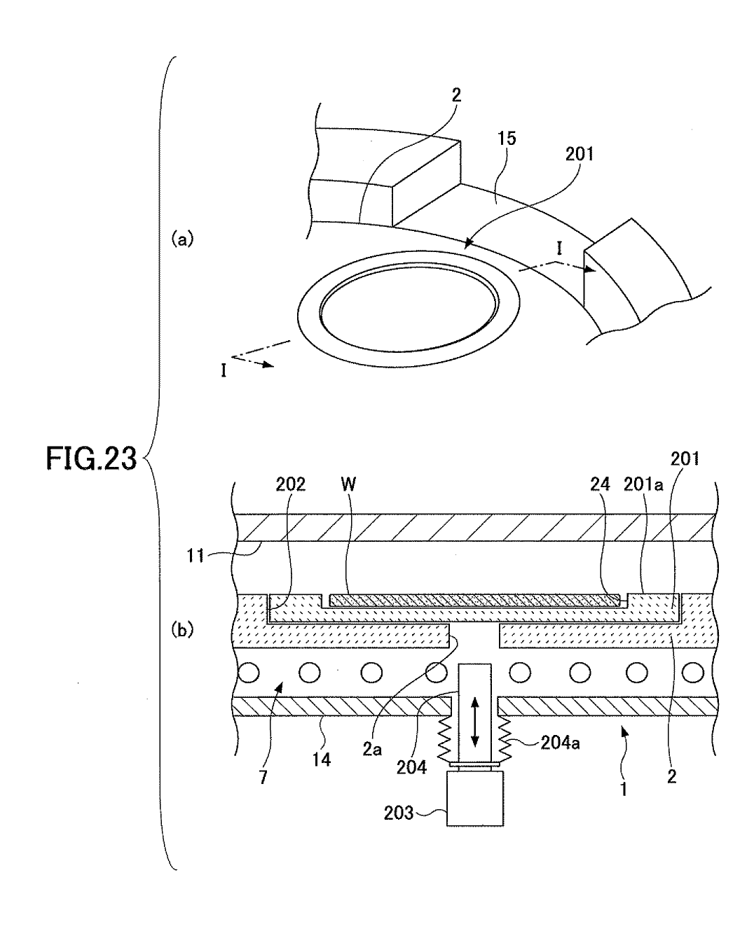

A subsection (a) of FIG. 23 illustrates the transfer opening 15 (see FIGS. 2, 3) formed on the circumferential wall of the chamber body 12 of the vacuum chamber 1, and the susceptor tray 201 that is aligned with the transfer opening 15. The transfer opening 15 is used when the wafer W is transferred into/out from the vacuum chamber 1. A subsection (b) of FIG. 23 is a cross-sectional view taken along I-I line in the subsection (a) of FIG. 23.

Referring to the subsection (b) of FIG. 23, the susceptor 2 is provided with a concave portion 202 in which the susceptor tray 201 is detachably (or removably) accommodated. At the substantial center of the concave portion 202, there is provided an opening 2a. A driving apparatus 203 is arranged below the susceptor tray 201 and outside of the vacuum chamber 1, and an elevation rod 204 is attached on an upper portion of the driving apparatus 203. The elevation rod 204 is attached hermetically sealed to the bottom portion 14 of the vacuum chamber 1 via a bellows 204a and a magnetic fluid sealing (not shown). The driving apparatus 203 includes, for example, a pressure cylinder and a stepping motor, and moves upward/downward and rotates the elevation rod 204. When the elevation rod 204 is moved upward by the driving apparatus 203, the elevation rod 204 comes in contact with the lower surface of the susceptor tray 201 through the opening 2a and moves the susceptor tray 201 upward. In addition, when the susceptor tray 201 is away from the susceptor 2, the elevation rod 204 can rotate the susceptor tray 201. When the elevation rod 204 is moved downward by the driving apparatus 203, the susceptor tray 204 is also moved downward and accommodated in the concave portion 202 of the susceptor 2.

Incidentally, the elevation rod 204 is provided not to interfere with the heater unit 7 arranged below the susceptor 2. When the heater unit 7 is composed of plural ring-shaped heater elements, for example, as shown in the subsection (b) of FIG. 23, the elevation rod 204 can go through a space between two adjacent ring-shaped heater elements to reach the lower surface of the susceptor tray 201.

In addition, when the susceptor tray 201 is accommodated in the concave portion 202, an upper surface 201a of the susceptor tray 201 forms the same plane along with the upper surface of the susceptor 2. If there is a relatively large step between the top surfaces of the susceptor 2 and the susceptor tray 201, the step may cause gas turbulence in the vacuum chamber 1, which adversely influences thickness uniformity of the film deposited on the wafer W. In order to reduce such a problem, the upper surface 201a and the upper surface of the susceptor 2 are at the same elevation, thereby reducing gas turbulence.

As shown in the subsection (b) of FIG. 23, the wafer receiving portion 24 of the susceptor tray 204 has a diameter larger than the diameter of the wafer W, for example, by about 4 mm, and a depth that is the same as the thickness of the wafer W. Therefore, when the wafer W is placed in the wafer receiving portion 24, the upper surface of the wafer W is at the same elevation as the upper surface of the susceptor 2 and the upper surface 201a of the susceptor tray 201. If there is a relatively large step between the top surfaces of the susceptor 2 and the wafer W, the step may cause gas turbulence in the vacuum chamber 1. “Being substantially at the same elevation” means here that the top surfaces of the susceptor 2 and the wafer W are at the same elevation, or a difference between the top surfaces of the susceptor 2 and the wafer W is within about 5 mm, while the difference is preferably as close to zero as possible to the extent allowed by machining accuracy. Incidentally, the same explanation can be given to the same elevation of the upper surface of the susceptor 2 and the upper surface 201a of the susceptor tray 201.

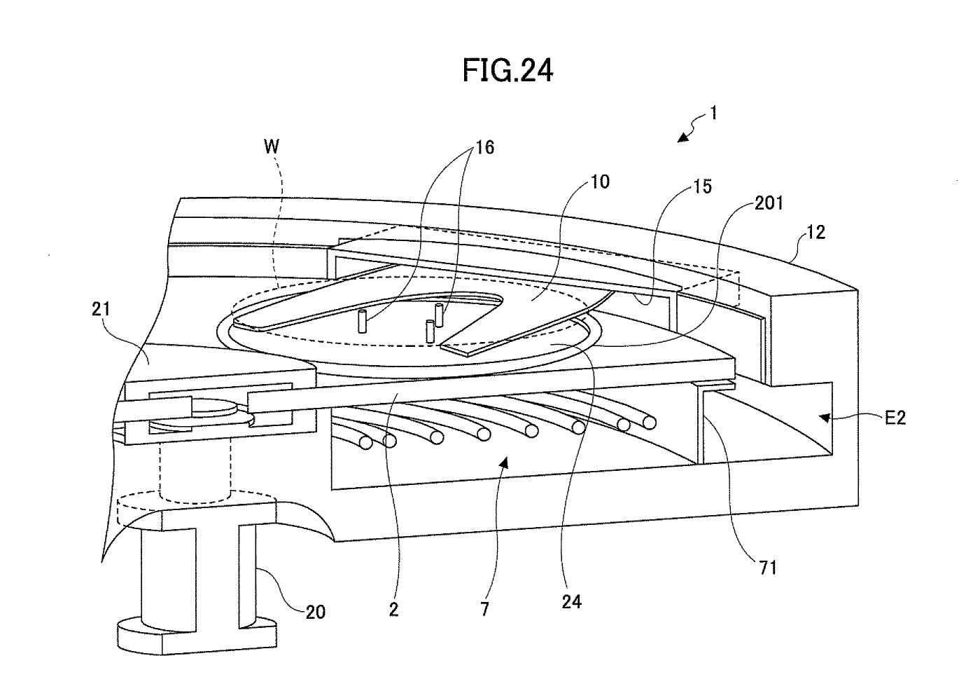

Referring again to FIG. 22, the transfer arm 10 facing the transfer opening 15 is illustrated. The transfer arm 10 transfers the wafer W into/out from the vacuum chamber 1 through the transfer opening 15 (see FIG. 24). The transfer opening 15 is provided with a gate valve (not shown), which opens and closes the transfer opening 15. When the susceptor tray 201 is aligned with the transfer opening 15 and the gate valve is opened, the wafer W is transferred into the vacuum chamber 1, and placed in the wafer receiving portion 24. In order to place the wafer W in the wafer receiving portion 24 from the transfer arm 10, or to bring the wafer W upward from the wafer receiving portion 24, there are provided three through-holes (not shown) in the susceptor tray 201 and the bottom portion of the concave portion 202 of the susceptor 2. The lift pins 16 that are vertically movable through the through-holes are provided (see FIG. 24). The lift pins 16 are moved upward/downward by an elevation mechanism (not shown) through the through-holes formed in the susceptor tray 201 and the bottom portion of the concave portion 202.

Next, operations (film deposition method) of the film deposition apparatus according to this embodiment are explained.

(Wafer Transfer-In Process)

A wafer transfer-in process where the wafer W is placed on the susceptor 2 is explained with reference to the previously referred to drawings. First, one of the susceptor trays 201 are aligned with the transfer opening 15 by rotating the susceptor 2, and the gate valve (not shown) is opened. Next, the wafer W is transferred into the vacuum chamber 1 by the transfer arm 10 through the transfer opening 15, and held above the wafer receiving portion 24, as shown in FIG. 24. Then, the lift pins 16 are brought upward to receive the wafer W from the transfer arm 10, and the transfer arm 10 retracts from the vacuum chamber 1. After the gate valve (not shown) is closed, the lift pins 16 are brought downward so that the wafer W is placed in the wafer receiving portion 24 of the susceptor tray 201.

After this series of procedures are repeated the same number of times as the number of the wafers W to be processed in one run, the wafer transfer-in process is completed.

(Film Deposition Step)

After the wafers W are transferred in, the vacuum chamber 1 is evacuated to the reachable pressure by the vacuum pump 64 (FIG. 1). Then, the susceptor 2 begins rotating clockwise around the center thereof seen from the above. The susceptor 2 is heated to a predetermined temperature (for example, 300° C.) by the heater unit 7 in advance, and the wafers W can also be heated at substantially the same temperature by being placed on the susceptor 2. After the wafers W are heated and maintained at the predetermined temperature, N₂ gas is supplied from the separation gas nozzles 41, 42; the BTBAS gas is supplied to the process area P1 through the reaction gas nozzle 31; and the O₃ gas is supplied to the process area P2 through the reaction gas nozzle 32.

When the wafer W passes through the process area P1 below the reaction gas nozzle 31, BTBAS molecules are adsorbed on the upper surface of the wafer W; and when the wafer W passes through the process area P2 below the reaction gas nozzle 32, O₃ molecules are adsorbed on an upper surface of the wafer W and oxidize the BTBAS molecules. Therefore, when the wafer W passes the process areas P1, P2 one time due to the rotation of the susceptor 2, one molecular layer of silicon oxide is produced on the upper surface of the wafer W.

After the wafers W alternately pass through the process areas P1, P2 several times, a wafer rotation step where the wafers W are rotated around their respective centers is carried out. First, the supply of the BTBAS gas and the O₃ gas is terminated, and the rotation of the susceptor 2 is stopped. At this time, the susceptor 2 is stopped so that one of the susceptor trays 201 on the susceptor 2 is located in alignment with the transfer opening 15 of the vacuum chamber 1. Alternatively, the susceptor 2 is stopped, and then the position of one of the susceptor trays 201 is adjusted in order to be aligned with the transfer opening 15. With this, the susceptor tray 201 is located above the elevation rod 204 and the elevation mechanism 203, as explained with reference to FIG. 23. Namely, the susceptor 2 is stopped so that the elevation rod 204 can pass through the opening 2a in the center of the concave portion 202 of the susceptor 2.

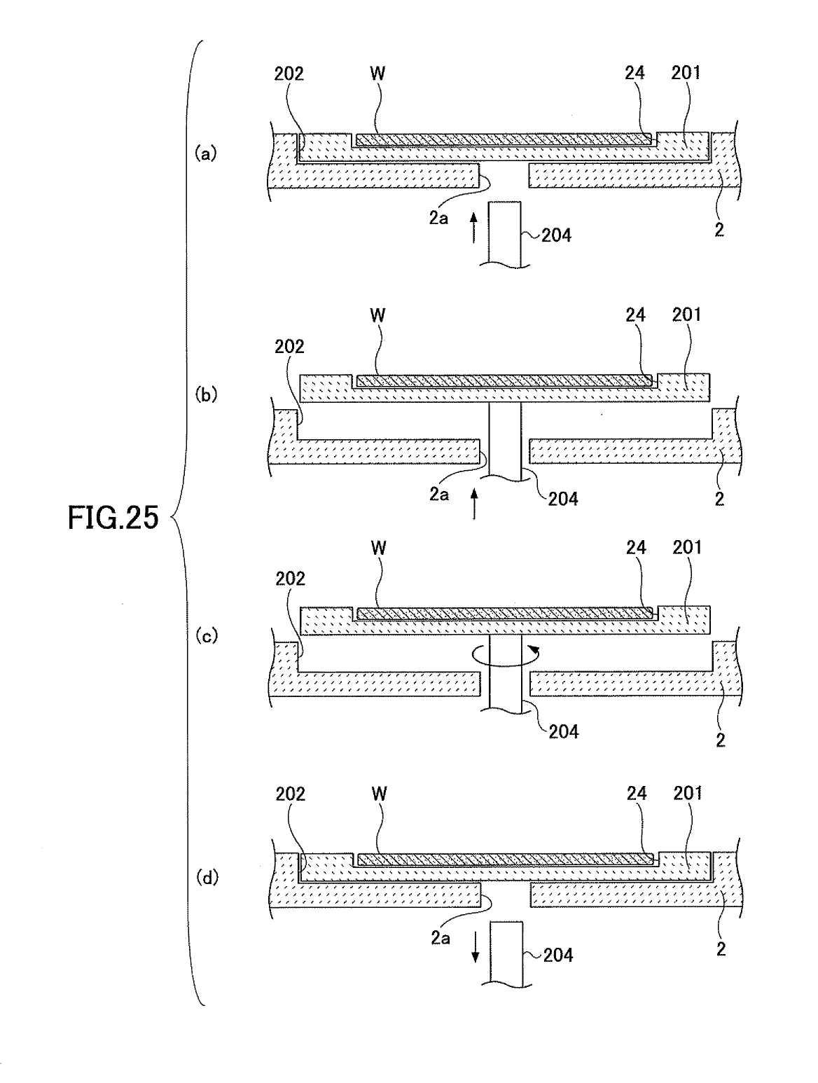

Next, the elevation rod 204 is brought upward through the opening 2a as shown in a subsection (a) of FIG. 25(a), and pushes the susceptor tray 201 upward (a subsection (b) of FIG. 25). Then, the susceptor tray 201 is rotated by 45° by the elevation rod 204 while being kept above the susceptor 2, as shown in a subsection (c) of FIG. 25. With this, the wafer W placed on the susceptor tray 201 is also rotated by 45°. Subsequently, the elevation rod 204 is brought downward and thus the susceptor tray 201 is accommodated in the concave portion 202 of the susceptor 2.

Next, the susceptor 2 is rotated so that another susceptor tray 201 next to the susceptor tray 201 that has been rotated is located in alignment with the transfer opening 15. After this, the above procedures explained with reference to the subsections (a) through (d) of FIG. 25 are repeated, and thus the rotation of the susceptor tray 201 concerned is completed. Subsequently, the same procedures are repeated for the remaining susceptor trays 201, and thus the rotation step is completed.

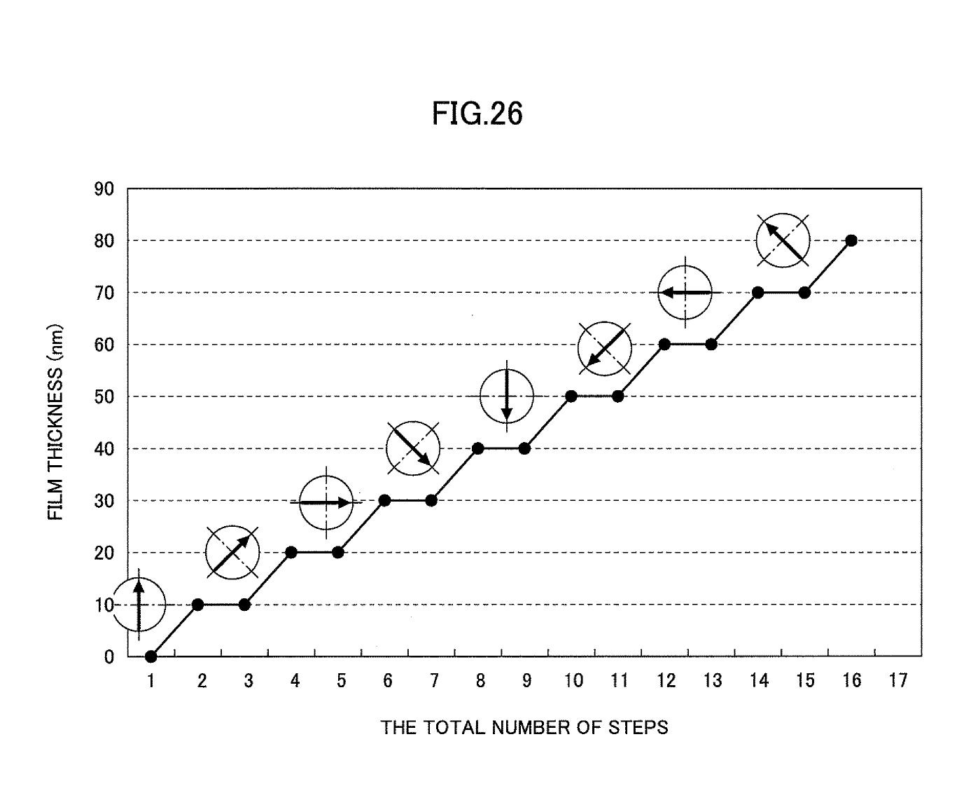

The rotation step is carried out (360°/θ°−1) times and every time a thickness of the film is increased by T×(360°/θ°) nm, from the beginning to the end of the film deposition, where θ is a rotation angle per rotation, and T (nm) is a target thickness. For example, when the silicon oxide film having a total thickness of 80 nm is to be deposited and the rotation angle θ is 45°, the rotation of each of the wafers W is carried out 7 (360°/45°−1) times during the film deposition process of depositing the silicon oxide film. In this case, one rotation step is carried out every time a thickness of the silicon oxide film is increased by about 10 (80/8) nm. These procedures may be explained in the following manner with reference to FIG. 26. The silicon oxide film is deposited at Step 1; the film deposition of the silicon oxide film is recessed at the time a thickness of the silicon oxide film becomes about 10 nm: and the wafers W are rotated around their respective centers by 45° at Step 2. Next, the film deposition is started again (Step 3); the film deposition of the silicon oxide film is recessed at the time a thickness of the silicon oxide film is increased by about an additional 10 nm; and the wafers W are rotated in the same direction around their respective centers by 45° (Step 4). When these procedures are repeated, the wafers W are rotated 7 times around their respective centers by 45° and the film deposition is repeated 8 times while the silicon oxide film having the target thickness of 80 nm is deposited. With such a film deposition process with the rotation steps, a thicker area and a thinner area that may be formed in the wafer W can be effectively compensated for, thereby improving an across-a-wafer thickness uniformity. Specific effects (or advantages) will be explained later.

Incidentally, when the susceptor tray 201 is rotated, the susceptor tray 201 may be only slightly brought upward so that the lower surface of the susceptor tray 201 does not contact the susceptor 2. Specifically, a difference between the lower surface of the susceptor tray 201 and the upper surface of the susceptor 2 may be from about 1 mm through about 10 mm.

After the silicon oxide film having the target thickness has been deposited on the wafers W, the supply of the BTBAS gas and the O₃ gas is terminated, the rotation of the susceptor 2 is stopped, and thus the film deposition step is completed.

(Wafer Transfer-Out Step)

After the film deposition step, the vacuum chamber 1 is purged. Then, the wafers W are transferred out one by one in accordance with procedures opposite to those in the wafer transfer-in step. Namely, after the wafer receiving portion 24 is in alignment with the transfer opening 15 and the gate valve is opened, the lift pins 16 are brought upward to hold the wafer W above the susceptor 2. Next, the transfer arm 10 proceeds below the wafer W, and receives the wafer W when the lift pins 16 are brought down. Then, the transfer arm 10 retracts from the vacuum chamber 1, so that the wafer W is transferred out from the vacuum chamber 1. With these procedures, one wafer W is transferred out. Subsequently, the procedures are repeated until all the wafers W are transferred out.

Because the wafers W are rotated around their respective centers when the film deposition step is recessed in the film deposition apparatus according to this embodiment, the film deposition uniformity can be improved. Effects (or advantages) provided by such rotation of the wafers W are explained in the following.

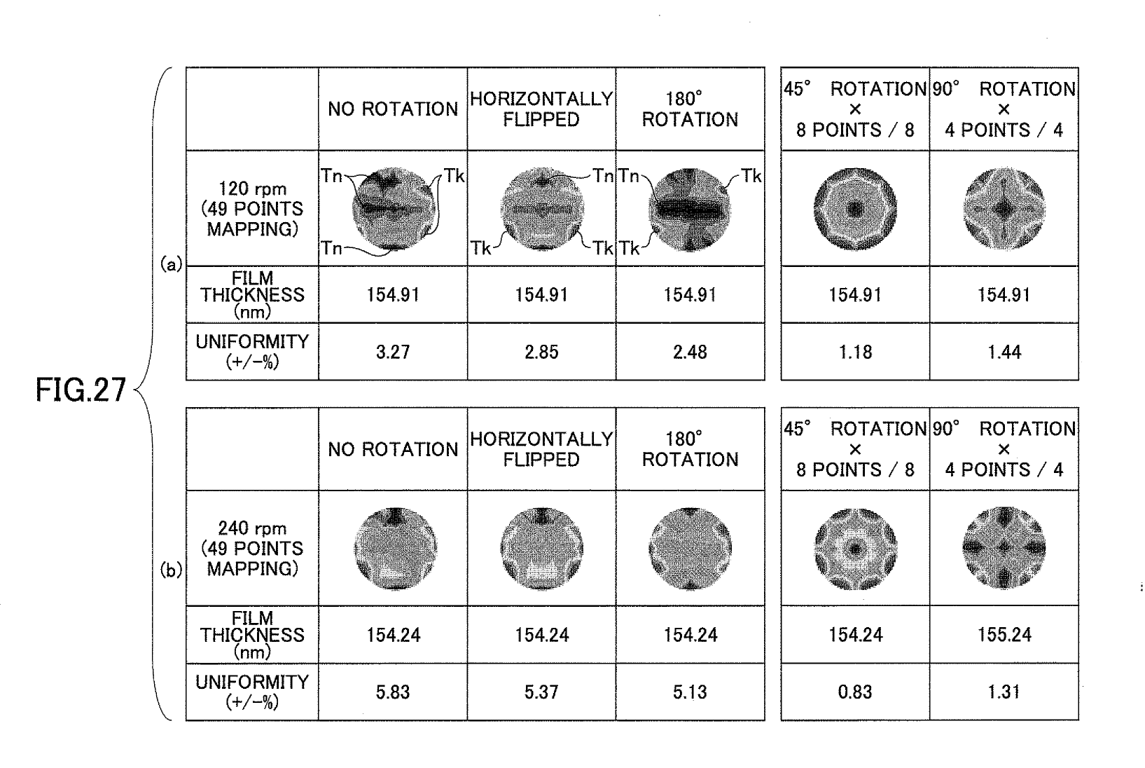

FIG. 27 summarizes results of the study carried out to confirm the effects of the film deposition method explained above. In columns of “no rotation”, thickness distributions of the silicon oxide film deposited on the wafer W having a diameter of 8 inches without rotating the wafers around their respective centers and with rotating the susceptor 2 are illustrated. The thickness distribution was obtained by measuring the thickness of the silicon oxide film by ellipsometry at 49 points over the wafer W, and carrying out interpolation using the measured thicknesses. For example, in the column “no rotation” of a subsection (a) of FIG. 27, a dark area shown by a reference symbol Tn has a smaller film thickness; a thickness becomes greater away from the area Tn; and an area shown by a reference symbol Tk has a greater film thickness. The thickness distribution is illustrated in the same manner in other columns of FIG. 27.

The subsection (a) of FIG. 27 illustrates thickness distributions of the silicon oxide films deposited with the rotation of the susceptor 2 at 120 revolutions per minute (rpm), and the subsection (b) of FIG. 27 illustrates thickness distributions of the silicon oxide films deposited with the rotation of the susceptor 2 at 240 rpm. The target thickness is about 155 nm regardless of the rotational speeds. The flow rates of the BTBAS gas and the O₃ gas are the same in both cases of 120 rpm and 240 rpm.

Referring to the column of “no rotation” of the subsection (a) of FIG. 27, the silicon oxide film is thinner in an area substantially along a diameter of the wafer W and in another area near one edge of the wafer W. Thickness uniformity across the wafer W is about 3.27%, which is obtained in accordance with (the greatest thickness−the smallest thickness among the 49 points)/(an average thickness of the 49 points).

Assuming that such a thickness distribution could be horizontally flipped, the thickness uniformity may be improved, as shown in a column “HORIZONTALLY FLIPPED” of the subsection (a) of FIG. 27. In addition, when the wafer W is rotated by 180° in the rotation step during the film deposition, the thickness uniformity is also improved. However, in the case of “HORIZONTALLY FLIPPED” and “180° ROTATION”, the thicker area and the thinner area are not very effectively compensated for because of a substantially symmetric distribution of the film thickness, which leads to a limited improvement. Especially, the thinner area is rather enlarged in the case of “180° ROTATION”.

On the other hand, when the wafer W is rotated three times by a rotation angle of 90° each during the film deposition to the thickness of about 155 nm, the thickness uniformity is improved to 1.44% as shown in a column of “90° ROTATION” of the subsection (a) of FIG. 27. Moreover, when the wafer W is rotated seven times by a rotation angle of 45° each during the film deposition to the thickness of about 155 nm, the thickness uniformity is further improved to 1.18% as shown in a column of “45° ROTATION” of the subsection (a) of FIG. 27. Such an improvement may be achieved because a thicker area in the wafer W in the case of “NO ROTATION” can be moved to a thinner area by the rotation of the wafer W at the rotation step, and vice versa, so that the thickness can be averaged out. Incidentally, a total rotation angle may be greater than 360° (one rotation), and a rotation angle at a time may be greater than zero and smaller than 360°, or preferably greater than or equal to 45° and smaller than or equal to 90°.

When the susceptor 2 is rotated at a rotational speed of 240 rpm, the same (or similar) results are obtained, as shown in the subsection (b) of FIG. 27. Specifically, in the case of 240 rpm, the thickness uniformity of 0.83% can be obtained, as shown in a column of “45° ROTATION”. From these results, the effects of the film deposition method according to this embodiment can be understood.

In addition, if the rotation of the susceptor 2 and the rotation of the susceptor tray 201 are simultaneously carried out (in such a manner called planetary rotation of the susceptor tray 201), particles may be generated because the susceptor 2 and the susceptor tray 201 may graze each other. However, because the susceptor tray 201 can be rotated when the susceptor tray 201 is away from the susceptor 2 in the above film deposition method, the susceptor 2 and the susceptor tray 201 do not graze each other, thereby reducing particle generation.

### Fifth Embodiment

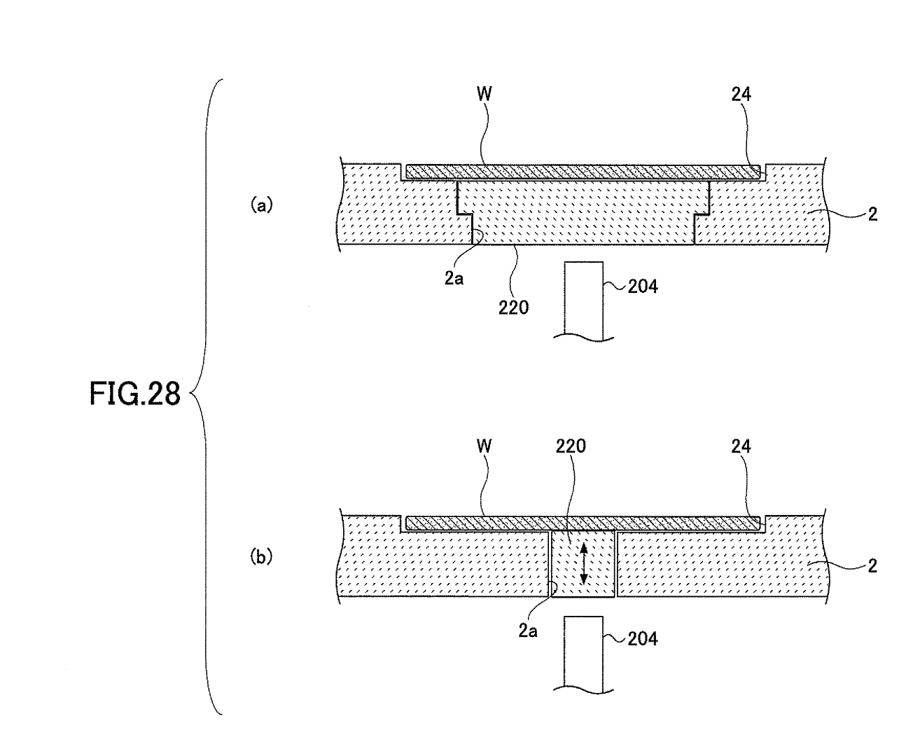

Next, a film deposition apparatus according to a fifth embodiment of the present invention is explained with reference to FIG. 28. FIG. 28 is a cross-sectional view of the film deposition apparatus of the fifth embodiment, which corresponds to the subsection (b) of FIG. 23. Referring to a subsection (a) of FIG. 28, the wafer receiving portion 24 is formed in the susceptor 2, and a stepped opening 2a that vertically penetrates the wafer receiving portion 24 is formed in substantially the center of the wafer receiving portion 24. The opening 2a has a shape of a circle concentric to the wafer receiving portion 24. An inner diameter of an upper portion of the opening 2a is smaller than the diameter of the wafer W by about 4 mm through about 10 mm. A susceptor plug 220 having a corresponding shape to the opening 2a is detachably (or removably) fit into the opening 2a with substantially no gap therebetween. Namely, the susceptor plug 220 has a top view shape of a circle and a side view shape of T.

In addition, a driving apparatus (not shown) having the same configuration as the driving apparatus 203 shown in the subsection (b) of FIG. 23 is arranged below the susceptor plug 220, and the elevation rod 204 is attached on an upper portion of the driving apparatus. Referring again to the subsection (a) of FIG. 28, when the elevation rod 204 is brought upward by the driving apparatus, the susceptor plug 220 is brought upward by the elevation rod 204, and when the elevation rod 204 is rotated by the driving apparatus, the susceptor plug 220 is rotated by the elevation rod 204. Therefore, the wafer W is brought upward and rotated by the susceptor plug 204. When the susceptor plug 220 is brought downward into the opening 2a of the susceptor 2 by the driving apparatus (not shown), the wafer W is brought downward by the susceptor plug 220, and placed in the wafer receiving portion 24. With such a configuration, the same effects as the susceptor tray 201 can be demonstrated.

Incidentally, when the susceptor plug 220 is fit into the opening 2a, an upper surface of the susceptor plug 220 and the upper surface of the wafer receiving portion 24 (excluding the upper surface of the susceptor plug 220) form one plane. Therefore, an entire lower surface of the wafer W can contact the upper surface of the wafer receiving portion 24, and thus a favorable temperature uniformity can be maintained across the wafer W.

In addition, the susceptor plug 220 may be altered as shown in a subsection (b) of FIG. 28. Namely, an opening 2a that is concentric to the wafer receiving portion 24 and has a cylindrical shape is formed in the substantial center of the wafer receiving portion 24 of the susceptor 2. A susceptor plug 220 having a cylindrical shape is detachably (or removably) fit into the cylindrical opening 2a with substantially no gap therebetween. With such a configuration, the wafer W is brought upward, rotated, and brought down in the wafer receiving portion 24 by the elevation rod 204 and a driving apparatus (not shown) via the susceptor plug 220. Therefore, the same effects as the susceptor tray 201 can be demonstrated.

### Altered Examples of the Fourth and Fifth Embodiments

The fourth embodiment may be altered by arranging five elevation rods 204 and the corresponding five driving apparatuses 203 below the corresponding susceptor trays 201 at equal angular intervals (namely, the configuration shown in FIG. 23 may be provided for all the susceptor trays 201), and modifying the driving portion 23 (see FIG. 1) so that the susceptor 2 is brought upward and downward. With this, the five susceptor trays 201 are located above the corresponding five elevation rods 204 and the corresponding five driving apparatuses. 203; the elevation rods 204 are brought upward to touch the lower surfaces of the corresponding susceptor trays 201; and the susceptor 2 is brought downward by the driving portion 23 so that the susceptor trays 201 are away from the susceptor 2. At this time, the susceptor trays 201 and the wafers W placed on the corresponding susceptor trays 201 can be rotated by the corresponding elevation rods 204. Therefore, all the wafers W can be rotated around their respective centers at a time, thereby reducing time required for rotating the wafers W. Then, the susceptor 2 is brought upward to receive the susceptor trays 201, the elevation rods 204 are brought downward, and thus the film deposition step can be started. When the susceptor plug 220 is used in the place of the susceptor tray 201, the same alteration can be realized.

Incidentally, the susceptor trays 201 (or susceptor plugs 220) may be brought relatively upward with respect to the susceptor 2 by the corresponding elevation rods 204, instead of bringing the susceptor 23 downward by the driving portion 23, if the height h of the ceiling surface (the convex portion 4) from the upper surface of the susceptor 2 is sufficient.

In addition, at least three arc-shaped slits may be formed in the concave portion 202 of the susceptor 2, instead of the opening 2a, so that the slits extend along a circle having its center at the center of the concave portion 202. Moreover, elevation pins may be arranged below the concave portion 202, instead of the elevation rods 204, so that the elevation pins can be moved upward/downward through the corresponding slits and along the arc shape of the corresponding slits by a predetermined driving mechanism. With these configurations, the elevation pins can move upward to push the susceptor tray 201 away from the susceptor 2, and move along the arc shape of the slits to rotate the susceptor tray 201 in the rotation step. In this case, a central angle corresponding to an arc length of each of the slits (or an angle formed by the center of the concave portion 202, one end of the slit and the other end of the slit) may be determined to equal to the rotation angle of the wafer W. Alternatively, the central angle may be, for example, 110°, while the rotation angle of the susceptor W is set to be greater than or equal to 0° and greater than or equal to 110°.

In addition, the lift pins 16 (see FIG. 24, for example) may be used in order to bring the wafer W upward and rotate the wafer W around its center. In this case, the concave portion 202 of the susceptor 2 and the susceptor tray 201 detachably mounted into the concave portion 202 are not necessary, but the wafer receiving portion 24 is formed in the susceptor 2. In addition, the three arc-shaped slits are formed in the wafer receiving portion 24, and the lift pins 16 are configured to move upward/downward through and along the corresponding slits. With these configurations, the lift pins 16 can move upward through the corresponding slits to bring the wafer W away from the wafer receiving portion 24, and along the corresponding slits, thereby rotating the wafer W at the rotation step. The central angle of the slits may be determined in the same manner as explained above.

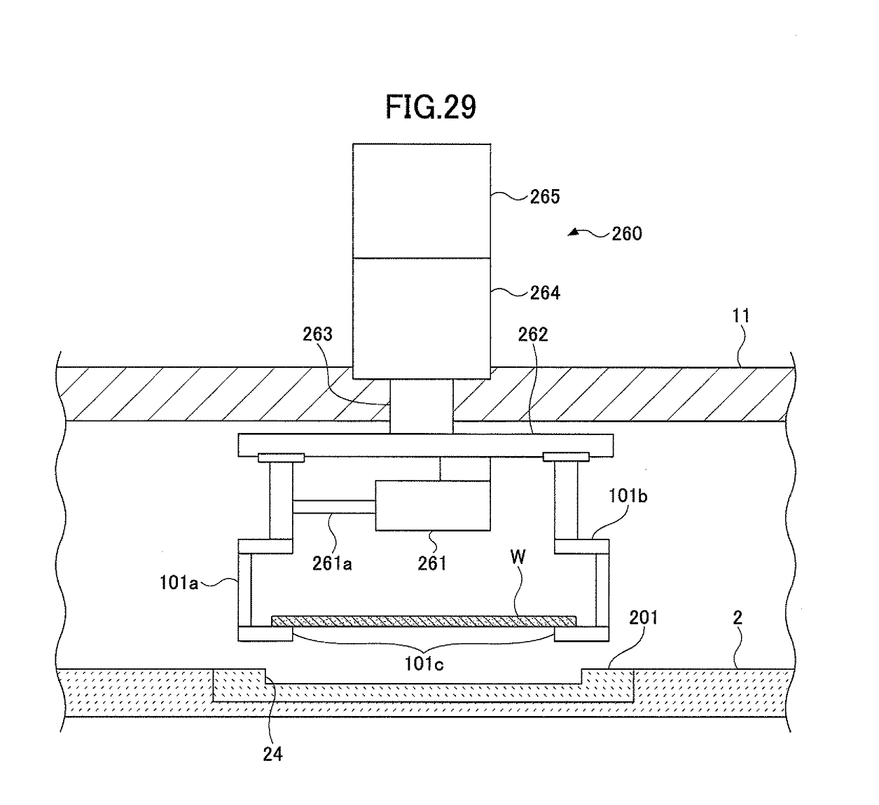

Moreover, the wafer W may be grasped from above, rather than pushed from below, and moved upward for rotation. FIG. 29 is a cross-sectional view of a wafer lifter that can grasp the wafer W from above in order to bring upward and rotate the wafer W. As shown, a wafer lifter 260 includes a guide 262 between the susceptor 2 and the ceiling plate 11 in the vacuum chamber 1. In addition, the wafer lifter 260 includes three arms 101a, 101b, etc., (the other one is omitted in the drawing), a solenoid 261, a shaft 263, and a motor 265. The arms 101a, 101b, etc., have end-effectors 101c at the distal end, and the end-effectors 101c contact the lower surface of the wafer W. The solenoid 261 is attached on a lower surface of the guide 262 and coupled at one end to the arm 101a via a rod 261a. The shaft 263 goes through the ceiling plate 11 hermetically sealed by a sealing member 264 such as a magnetic fluid sealing member, and is coupled to an upper center portion of the guide 262. In addition, the shaft 263 is moved upward/downward and rotated by the motor 265. The susceptor tray 201 is provided with concave portions (not shown) that allow the corresponding end-effectors 101c of the arms 101a, 101b, etc., of the wafer lifter 260 to contact the lower surface of the wafer W placed in the wafer receiving portion 24.

With such configurations, the rotation step can be carried out in the following manner. First, when the film deposition is recessed, the guide 262 and the arms 101a, 101b, etc., are brought downward by the shaft 263 and the motor 165, so that the end-effectors 101c are accommodated in the corresponding concave portions formed in the susceptor tray 201. Next, when arms 101a, 101b, etc., are moved closer to each other by the solenoid 261, the end-effectors 101c can move into a space in the concave portion below the wafer W. Then, when the guide 262 and the arms 101a, 101b, etc., are brought upward by the shaft 263 and the motor 265, the wafer W is brought upward by the end-effectors 101c that contact the lower surface of the wafer W, as shown in FIG. 29. Subsequently, the shaft 263 is rotated by the motor 265, and thus the wafer W is rotated by a rotation angle of, for example, 45°. Next, the arms 101a, 101b, etc., are brought downward by the shaft 263 and the motor 265 in order to place the wafer W on the susceptor 201. At this time, the end-effectors 101c are accommodated in the corresponding concave portions formed in the susceptor tray 201. Subsequently, when the arms 101a, 101b, etc., are moved away from each other by the motor 265, the end-effectors 101c are moved away from each other, which makes it possible to bring the arms 101a, 101b, etc., upward by the shaft 263 and the motor 265. With these procedures, the wafer W can be rotated around its center at the rotation step. Therefore, the same effects explained above are demonstrated.

Incidentally, the wafer receiving portion 24 and the concave portions for the end-effectors may be formed in the susceptor, rather than the susceptor tray 201. In addition, the arms 101a, 101b, etc., may be branched into two branch arms, and the end-effectors 101c may be attached to distal ends of the four branch arms. With this, the wafer W is supported by the four end-effectors 101c, with only two arms 101a, 101b, etc., attached to the guide 262, and the solenoid 261 can be simplified. Alternatively, one of the arms 101a, 101b, etc., may be branched into the two branch arms, and the end-effectors 101c may be attached to distal ends of the two branch arms and to the distal end of the other one of the arms 101a, 101b, etc. In this case, the wafer W can be supported by the three end-effectors 101c, with the two arms 101a, 101b, etc.

In addition, because intermixing of the reaction gases is greatly reduced in the vacuum chamber 1 in the film deposition apparatus according to the embodiments of the present invention, the film is exclusively deposited on the wafers W and the susceptor 2, and almost no film can be deposited on the wafer lifter 260. Therefore, almost no particles are generated from the film deposited on the wafer lifter 260.

### Sixth Embodiment

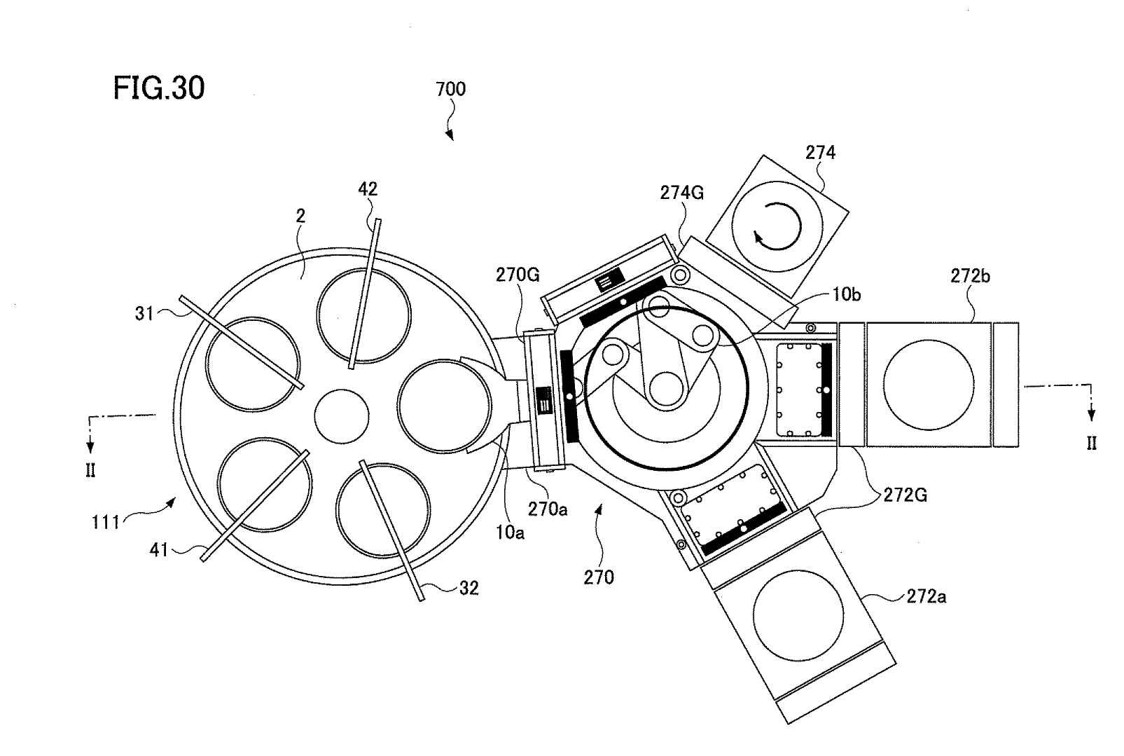

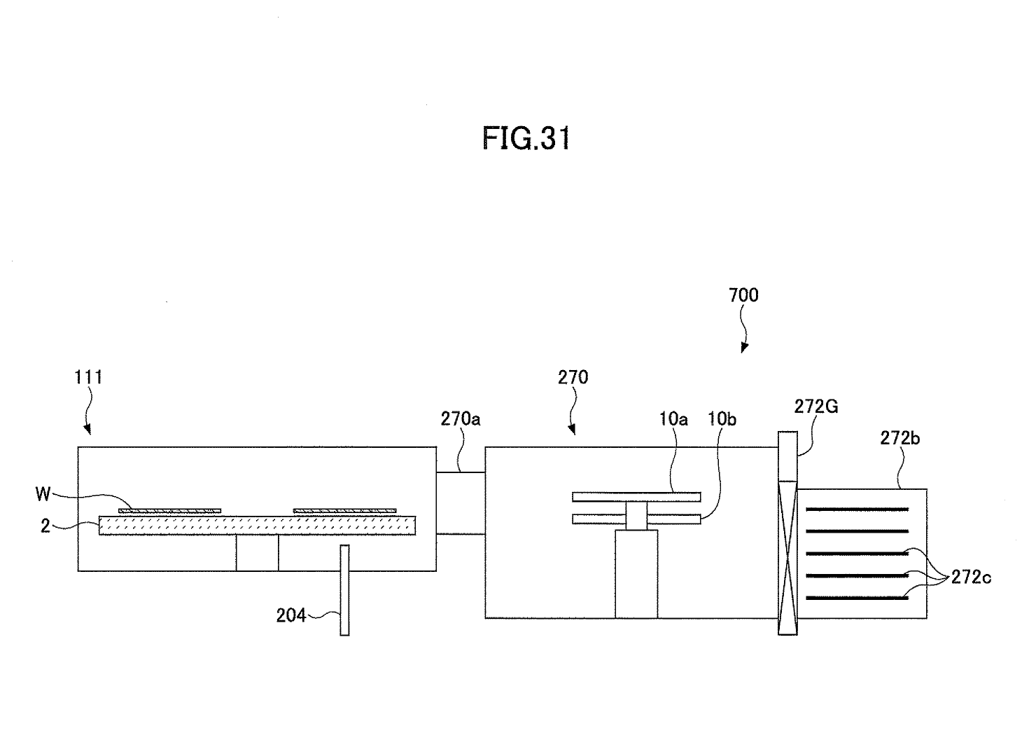

While the wafers W are rotated around their respective centers inside the vacuum chamber 1 in the foregoing embodiments, the wafer W may be temporarily transferred out from the vacuum chamber 1 when the film deposition is discontinued, in other embodiments. In the following, a film deposition apparatus that enables such rotation of the wafer W is explained with reference to FIGS. 30 and 31.

FIG. 30 is a plan view of a film deposition apparatus 700 according to a sixth embodiment of the present invention. As shown, the film deposition apparatus 700 includes a vacuum chamber 111, a transfer passage 270a provided at the transfer opening (not shown) formed in the circumferential wall of the vacuum chamber 111, a gate valve 270G provided in the transfer passage 270a, a transfer module 270 provided to be in gaseous communication with the transfer passage 270a via the gate valve 270G, a wafer rotation unit 274 provided to be in gaseous communication with the transfer module 270 via a gate valve 274G, and load lock chambers 272a, 272b connected to the transfer module 270 via corresponding gate valves 272G.

The vacuum chamber 111 is different from the vacuum chamber 1 in that the vacuum chamber 111 does not include the susceptor tray 201, the susceptor plug 220, or the wafer lifter 260, but is the same as the vacuum chamber 1 in other configurations.

The transfer module 270 includes two transfer arms 10a, 10b that are extendable and pivotable around its base portion. With this, the transfer arms 10a, 10b can transfer the wafer W into/out from the vacuum chamber 111 when the gate valve 270G is opened, as shown in FIG. 30. In addition, when the gate valve 274G is opened, the transfer arms 10a, 10b can transfer the wafer W into/out from the wafer rotation unit 274. Similarly, when the gate valve 272 is opened, the transfer arm 10a, 10b can transfer the wafer W into/out from the corresponding load lock chambers 272a, 272b.

The wafer rotation unit 274 includes a stage 274a that has a circular top view shape and is rotatable, and a rotation mechanism (not shown) that rotates the stage 274a. The stage 274a is provided with lift pins (not shown) that are the same as the lift pins 16 explained above. The lift pins can receive the wafer W from the transfer arms 10a, 10b to place the wafer W on the stage 274a, and transfer the wafer W to the transfer arms 10a. , 10b from the stage 274a. With such a configuration, the wafer W that has been transferred from the transfer arm 10a, 10b onto the stage 274a can be rotated by the rotatable stage 274a.

The load lock chamber 272b includes a five-stage wafer storage 272c that is movable upward/downward by a driving portion (not shown), as shown in FIG. 31 illustrating a cross section taken along II-II line in FIG. 30. One of the wafers W can be stored in each stage of the wafer storage 272c. The load lock chamber 272a has the same configuration, although not shown. One of the load lock chambers 272a, 272b may serve as a buffer chamber where the wafers W are temporarily stored, and the other one of the load lock chambers 272a, 272b may serve as an interface chamber for use in transferring the wafers W from outside (or a process apparatus used in the previous process) into the vacuum chamber 111.

Incidentally, a vacuum system (not shown) is connected to the transfer module 270, the wafer rotation unit 274, and the load lock chambers 272a, 272b. The vacuum system may include a rotary pump, and a turbo molecular pump, if necessary.

In the film deposition apparatus 700 having the above configurations, the film deposition in the vacuum chamber 111 is temporarily discontinued, and the wafer W in the vacuum chamber 111 is transferred out from the vacuum chamber 111 in accordance with procedures opposite to the procedures for transferring the wafer W into the vacuum chamber 111. Next, the wafer W is transferred into the wafer rotation unit 274 and placed on the stage 274b by the transfer arm 10a. After the stage 274b is rotated by a predetermined rotation angle, the transfer arm 10a transfers the wafer W out from the wafer rotation unit 274 and into the load lock chamber 272b as the buffer chamber, and places the wafer W on one of the stages of the wafer storage 272c. During such procedures, the transfer arm 10b transfers another wafer W out from the vacuum chamber 111. In this case, the transfer arm 10a that returns from the load lock chamber 272b and the transfer arm 10b that proceeds toward the wafer rotation unit 274 pass each other in the transfer module 270. Then, the transfer arm 10a moves into the vacuum chamber 111 in order to transfer yet another wafer W out from the vacuum chamber 111, while the transfer arm 10b transfers the other wafer W to the wafer rotation unit 274. In such a manner, all the wafers W in the vacuum chamber 111 are transferred into the wafer rotation unit 274, rotated by the stage 274b in the wafer rotation unit 274, transferred into the load lock chamber 272b as the buffer chamber, and temporarily stored in the load lock chamber 272b. After all the wafers W are stored in the load lock chamber 272b, the transfer arms 10a, 10b transfer the wafers W out from the load lock chamber 272b and into the corresponding wafer receiving portions 24 of the susceptor 2 in the vacuum chamber 111. Because the wafers W have been rotated around their respective centers in the wafer rotation unit 274, the wafers W placed in the corresponding wafer receiving portions 24 are shifted in a rotational direction by a predetermined angle, compared to the positions of the wafers W that had been placed in the corresponding wafer receiving portions 24. Then, the film deposition is restarted. When the thickness of the film on the wafers W is increased by a predetermined thickness, the film deposition is temporarily discontinued, and the above procedures are repeated.

Even with such a rotation step, the same thickness uniformity improving effects as explained in the previous embodiments are demonstrated, thereby providing the film with improved thickness uniformity.

Incidentally, the film deposition apparatus 700 may be provided with two or more wafer rotation units 274. In addition, when there are 10 wafers W in one lot, after the first five wafers W are transferred into and temporarily stored in the load lock chamber 272b as the buffer chamber, the second five wafers W stored in the load lock chamber 272a as the interface chamber are transferred into the vacuum chamber 111 and undergo the film deposition process including the rotation step. In this case, when the film having a predetermined thickness is deposited on the second five wafers W, the film deposition is temporarily discontinued and the second five wafers W are transferred out from the vacuum chamber 111 and the first five wafers W in the load lock chamber 272b may be transferred into the vacuum chamber 111 and undergo the film deposition process including the rotation step.

### Seventh Embodiment

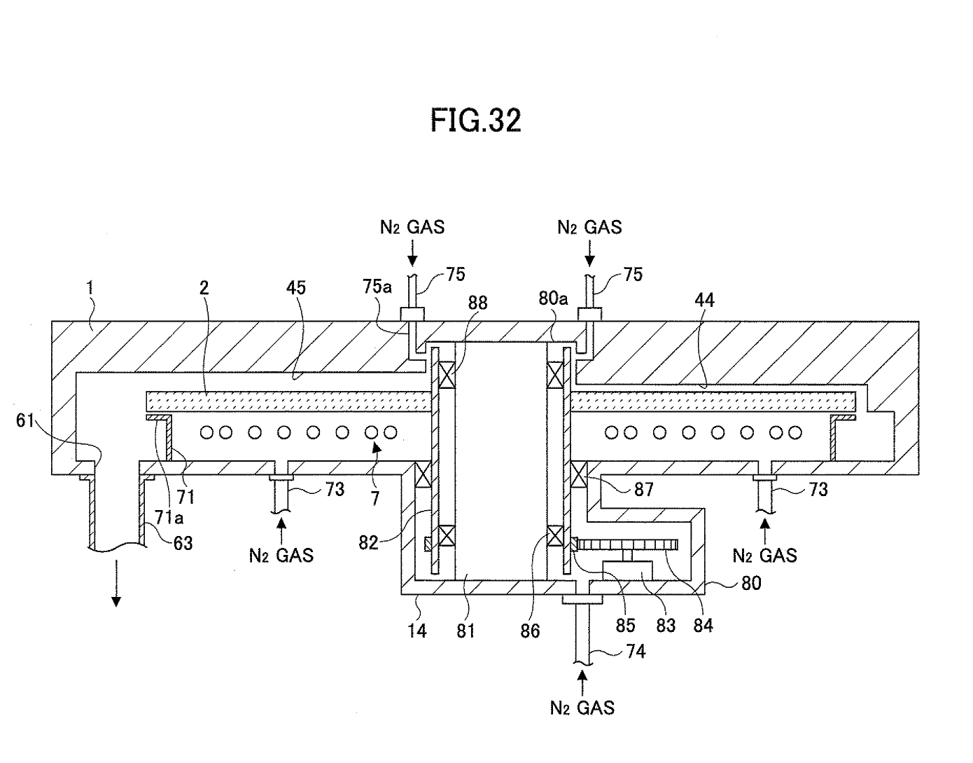

In the previous embodiments, the rotational shaft 22 for rotating the susceptor 2 is located in the center portion of the chamber 1. In addition, the space 52 between the core portion 21 and the ceiling plate 11 is purged with the separation gas in order to impede the reaction gases from being intermixed through the center portion C. However, the chamber 1 (111) may be configured as shown in FIG. 32 in a seventh embodiment. Referring to FIG. 32, the bottom portion 14 of the chamber body 12 has a center opening to which a hermetically sealed housing case 80 is attached. Additionally, the upper ceiling portion has a center concave portion 80a in the center. A pillar 81 is placed on the bottom surface of the housing case 80, and a top end portion of the pillar 81 reaches a bottom surface of the center concave portion 80a. The pillar 81 can substantially prevent the first reaction gas (BTBAS) ejected from the first reaction gas nozzle 31 and the second reaction gas (O₃) ejected from the second reaction gas nozzle 32 from being mixed through the center portion of the chamber 1.

Although not shown, the susceptor 2 of the film deposition apparatus according to the seventh embodiment includes the concave portion 202 to which the susceptor tray 201 (see FIG. 23) is detachably fitted. The opening 2a is formed in the substantial center of the concave portion 202. The susceptor tray 201 is brought upward and rotated by the elevation rod 204 that is movable upward/downward through the opening 2a and rotatable. When the elevation rod 204 is moved downward, the susceptor tray 201 is moved downward and accommodated in the concave portion 202. Sizes of the susceptor tray 201, the concave portion 202, and the like may be determined as explained above. With such a configuration, the susceptor tray 201 and the wafer W placed on the susceptor tray 201 can be rotated by a predetermined rotation angle, thereby improving thickness uniformity.

In addition, a rotation sleeve 82 is provided so that the rotation sleeve 82 coaxially surrounds the pillar 81. The rotation sleeve 82 is supported by bearings 86, 88 attached on an outer surface of the pillar 81 and a bearing 87 attached on an inner side wall of the housing case 80. Moreover, the rotation sleeve 82 has a gear portion 85 formed or attached on an outer surface of the rotation sleeve 82. Furthermore, an inner circumference of the ring-shaped susceptor 2 is attached on the outer surface of the rotation sleeve 82. A driving portion 83 is housed in the housing case 80 and has a gear 84 attached to a shaft extending from the driving portion 83. The gear 84 is meshed with the gear portion 85. With such a configuration, the rotation sleeve 82 and thus the susceptor 2 are rotated by the driving portion 83.

A purge gas supplying pipe 74 is connected to an opening formed in a bottom of the housing case 80, so that a purge gas is supplied into the housing case 80. With this, an inner space of the housing case 80 may be kept at a higher pressure than an inner space of the chamber 1, in order to substantially prevent the reaction gases from flowing into the housing case 80. Therefore, no film deposition takes place in the housing case 80, thereby reducing maintenance frequencies. In addition, purge gas supplying pipes 75 are connected to corresponding conduits 75a that reach from an upper outer surface of the chamber 1 to an inner side wall of the concave portion 80a, so that a purge gas is supplied toward an upper end portion of the rotation sleeve 82. Because of the purge gas, the BTBAS gas and the O₃ gas cannot be intermixed through a space between the outer surface of the rotation sleeve 82 and the side wall of the concave portion 80a. Although the two purge gas supplying pipes 75 are illustrated in FIG. 32, the number of the pipes 75 and the corresponding conduits 75a may be determined so that the purge gas from the pipes 75 can assuredly prevent gas mixture of the BTBAS gas and the O₃ gas in and around the space between the outer surface of the rotation sleeve 82 and the side wall of the concave portion 80a.

In the embodiment illustrated in FIG. 32, a space between the side wall of the concave portion 80a and the upper end portion of the rotation sleeve 82 corresponds to the ejection hole for ejecting the separation gas. In addition, the center area is configured with the ejection hole, the rotation sleeve 82, and the pillar 81.

The present invention has been explained with reference to several embodiments, the present invention is not limited to the foregoing embodiments, but various alterations and modifications may be applied without departing from the scope of the invention set forth in accompanying claims.

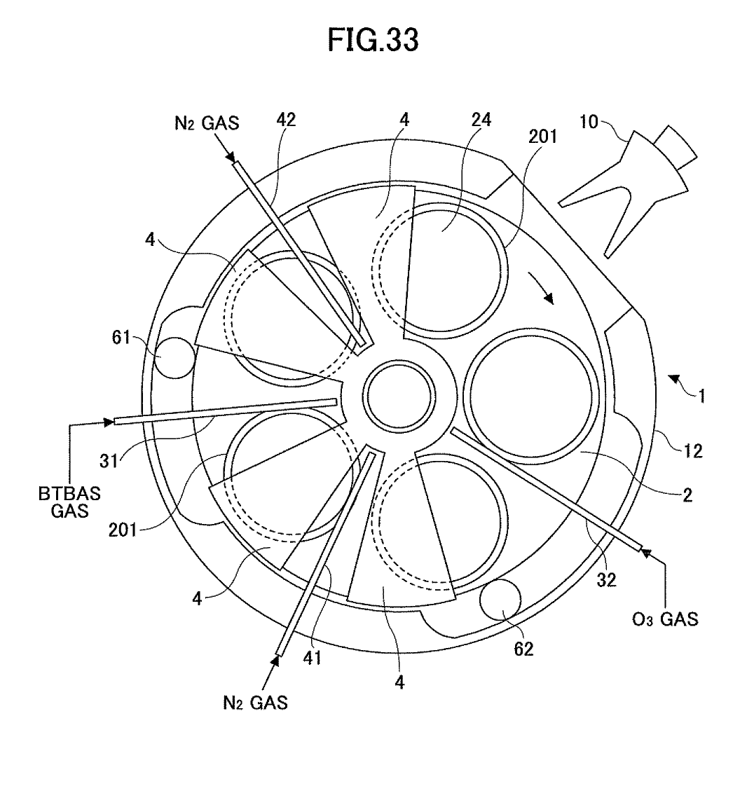

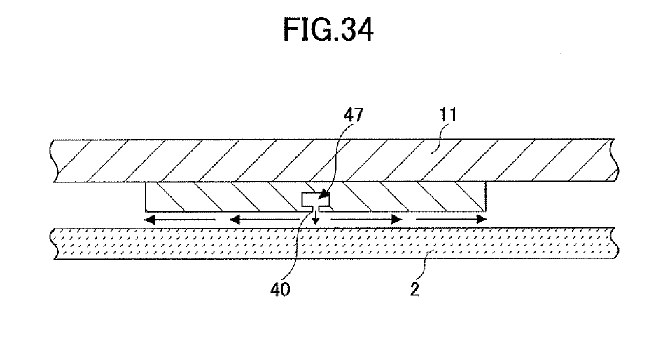

For example, the separation area D is configured by forming the groove portion 43 in a sector-shaped plate to be the convex portion 4, and arranging the separation gas nozzle 41 (42) in the groove portion 43 in this embodiment in the above embodiments. However, two sector-shaped plates may be attached on the bottom surface of the ceiling plate 11 by screws so that the two sector-shaped plates are located with one plate on each side of the separation gas nozzle 41 (32). FIG. 33 is a plan view of such a configuration. In this case, a distance between the convex portion 4 and the separation gas nozzle 41 (42), and a size of the convex portion 4 may be determined taking into consideration ejection rates of the separation gas and the reaction gases, in order to effectively demonstrate the separation effect by the separation areas D.

In the above embodiments, the separation gas nozzle 41 (42) is housed in the groove portion 43 formed in the convex portion 4 and there are the flat lower ceiling surfaces 44 (first ceiling surfaces) on both sides of the separation gas nozzle 41 (42). However, as shown in FIG. 12, a conduit 47 extending along the radial direction of the susceptor 2 may be made inside the convex portion 4, instead of the separation gas nozzle 41 (42), and plural holes 40 may be formed along the longitudinal direction of the conduit 47 so that the N₂ gas as the separation gas may be ejected from the plural holes 40 in other embodiments.

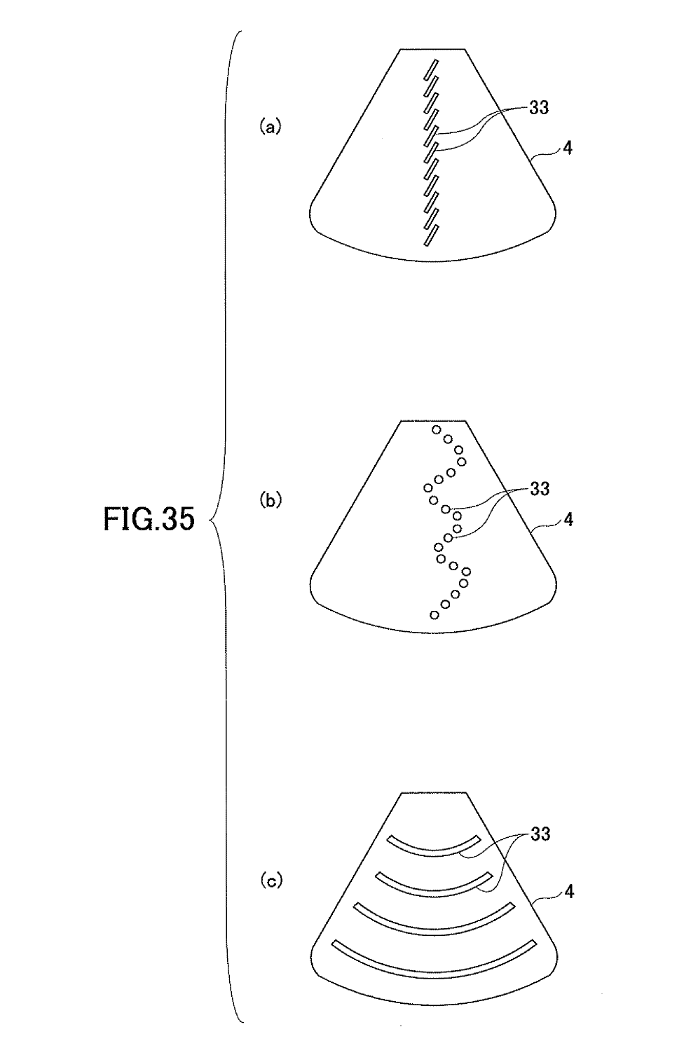

In addition, the convex portion 4 may be hollow, and the separation gas may be introduced into the hollow space. In this case, plural gas ejection holes 33 may be arranged as shown in subsections (a) through (c) of FIG. 35.

Referring to the subsection (a) of FIG. 35, each of the plural gas ejection holes 33 has a shape of a slanted slit. These slanted slits (gas ejection holes 33) are arranged to be partially overlapped with an adjacent slit along the radial direction of the susceptor 2. In the subsection (b) of FIG. 35, each of the plural gas ejection holes 33 has a circular shape. These circular holes (gas ejection holes 33) are arranged along a serpentine line that extends in the radial direction as a whole. In the subsection (c) of FIG. 35, each of the plural gas ejection holes 33 has a shape of an arc-shaped slit. These arc-shaped slits (gas ejection holes 33) are arranged at predetermined intervals in the radial direction of the susceptor 2.

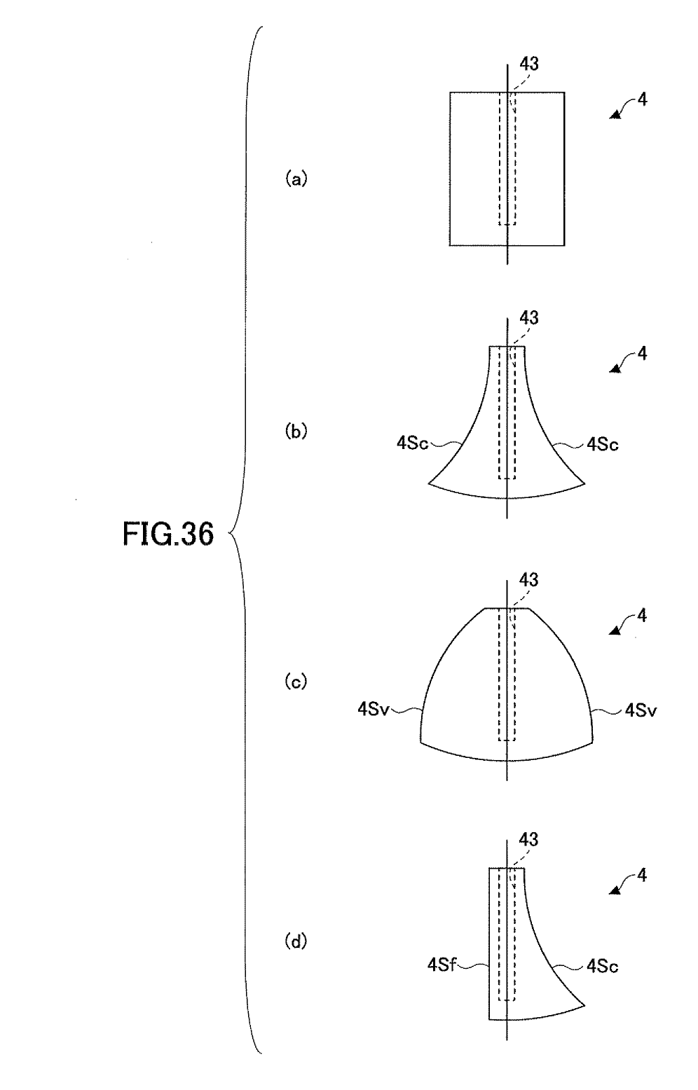

While the convex portion 4 has the sector-shaped top view shape in this embodiment, the convex portion 4 may have a rectangle top view shape as shown in a subsection (a) of FIG. 36, or a square top view shape in other embodiments. Alternatively, the convex portion 4 maybe sector-shaped as a whole in the top view and have concavely curved side surfaces 4Sc, as shown in a subsection (b) of FIG. 36. In addition, the convex portion 4 may be sector-shaped as a whole in the top view and have convexly curved side surfaces 4Sv, as shown in a subsection (c) of FIG. 36. Moreover, an upstream portion of the convex portion 4 relative to the rotation direction of the susceptor 2 (FIG. 1) may have a concavely curved side surface 4Sc and a downstream portion of the convex portion 4 relative to the rotation direction of the susceptor 2 (FIG. 1) may have a flat side surface 4Sf, as shown in a subsection (d) of FIG. 36. Incidentally, dotted lines in the subsections (a) through (d) of FIG. 36 represent the groove portions 43. In these cases, the separation gas nozzle 41 (42) (FIG. 2), which is housed in the groove portion 43 (the subsections (a) and (b) of FIG. 4) extends from the center portion of the vacuum chamber 1, for example, from the protrusion portion 5 (FIG. 1).

Incidentally, the convex portion 4 preferably has a sector-shaped top view, as explained above because of the following reasons. Because a larger centrifugal force is applied to the gases in the vacuum chamber 1 at a position closer to the outer circumference of the susceptor 2, the BTBAS gas, for example, flows toward the separation area D at a higher speed in the positions closer to the outer circumference of the susceptor 2. Therefore, the BTBAS gas is more likely to enter the gap between the ceiling surface 44 and the susceptor 2 in the positions closer to the circumference of the susceptor 2. Under such circumstances, when the convex portion 4 has a greater width (a longer arc length) toward the circumference, the BTBAS gas cannot flow farther into the gap in order to be intermixed with the O₃ gas.

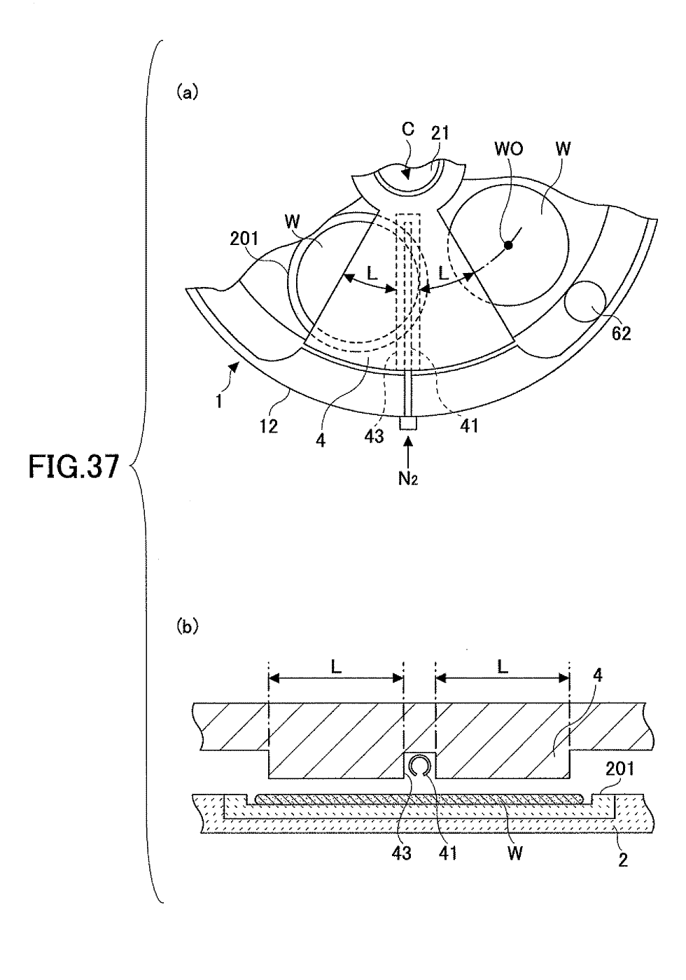

In the following, the size of the convex portion (or the ceiling surface 44) is exemplified again. Referring to subsections (a) and (b) of FIG. 37, the ceiling surface 44 that creates the thin space on both sides of the separation gas nozzle 41 (42) above the susceptor 2 may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the susceptor 2 (wafer W) has to be accordingly small in order to effectively impede the reaction gases from flowing into the thin space. However, when the length L becomes too small and thus the height h has to be extremely small, the susceptor 2 may hit the ceiling surface 44, which may cause wafer breakage and wafer contamination through particle generation. Therefore, measures to dampen vibration of the susceptor 2 or measures to stably rotate the susceptor 2 are required in order to avoid the susceptor 2 hitting the ceiling surface 44. On the other hand, when the height h of the thin space is kept relatively greater while the length L is small, a rotational speed of the susceptor 2 has to be lower in order to avoid the reaction gases flowing into the thin gap between the ceiling surface 44 and the susceptor 2, which is rather disadvantageous in terms of production throughput. From these considerations, the length L of the ceiling surface 44 along the arc corresponding to the route of the wafer center WO is preferably about 50 mm or more. However, the size of the convex portion 4 or the ceiling surface 44 is not limited to the above size, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used.

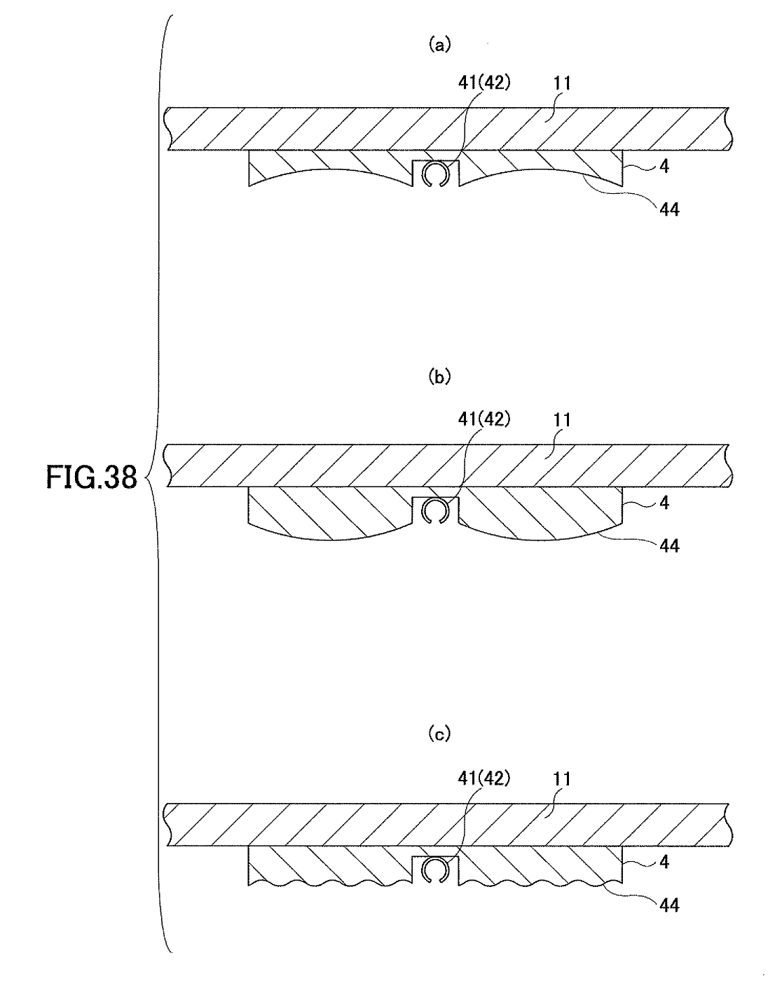

The ceiling surface 44 of the separation area D may have a concavely curved surface shown in a subsection (a) of FIG. 38, a convexly curved surface shown in a subsection (b) of FIG. 38, or a corrugated surface shown in a subsection (c) of FIG. 38, the ceiling surface 44 not being limited to a flat surface.

In addition, while the lower ceiling surfaces 44 are preferably provided in embodiments according to the present invention, the separation gas nozzles 41, 42 may eject the N₂ gas downward to create gas curtains in order to separate the process areas P1, P2 by the gas curtain, without using the lower ceiling surfaces 44.

The heater unit 7 for heating the wafer W may be a heating lamp, instead of a resistive heating element. In addition, the heater unit 7 may be arranged above the susceptor 2 rather than below the susceptor 2, or both above and below the susceptor 2. In addition, when chemical reaction of the reaction gases takes place at lower temperatures, for example, at room temperature, such a heating unit is not necessary.

Incidentally, while five wafers W placed in the corresponding wafer receiving portions 24 can be processed in one run because the susceptor 2 has the five wafer receiving portions 24 in the film deposition apparatuses according to the embodiments, only one wafer W may be placed in one wafer receiving portion 24, or only one wafer receiving portion 24 may be made in the susceptor 2.

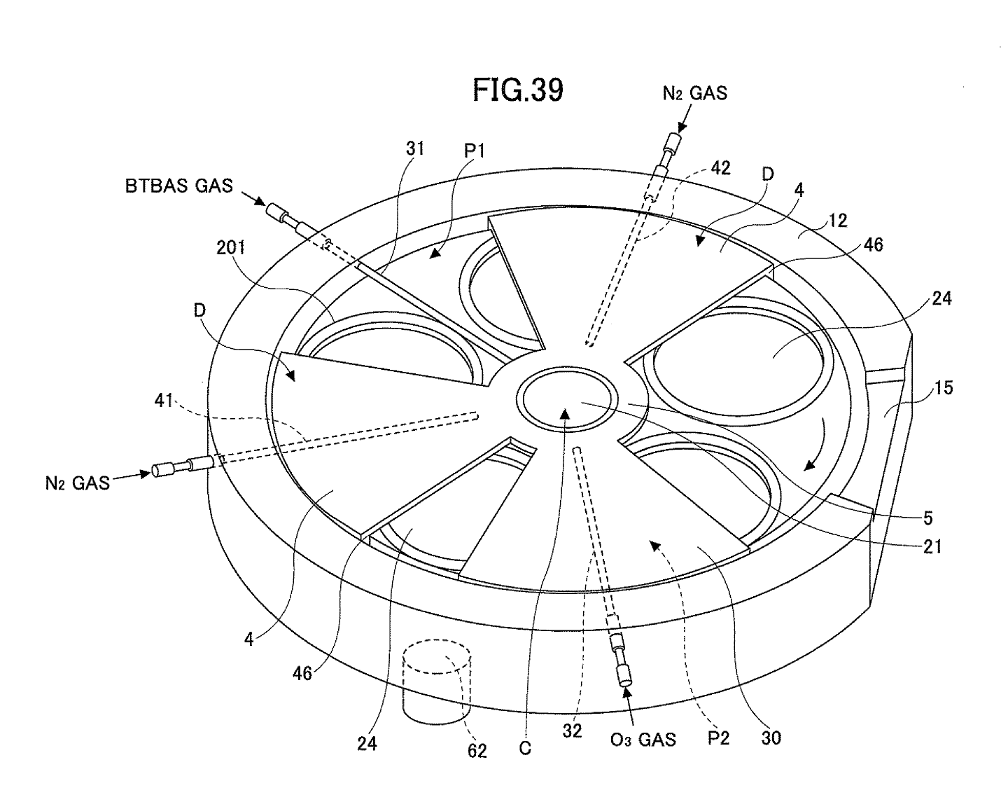

In the above embodiments, the process area P1 and the process area P2 correspond to areas with the ceiling surfaces 45 higher than the ceiling surfaces 44 of the separation areas D. However, at least one of the process areas P1, P2 may have a ceiling surface that is lower than the ceiling surface 45 and opposes the susceptor 2 in both sides of the corresponding reaction gas nozzle 31 or 32. This may impede gas from flowing into a gap between the ceiling surface and the susceptor 2. In this case, this ceiling surface may be lower than the ceiling surface 45 and as low as the ceiling plate 44 of the separation area D. FIG. 39 illustrates an example of such a configuration. As shown, a sector-shaped convex portion 30 is arranged in the process area P2 where the O₃ gas is supplied, and the reaction gas nozzle 32 is housed in a groove portion (not shown) formed in the convex portion 30. In other words, although the process area P2 is used for the reaction gas nozzle 32 to supply the reaction gas, the process area P2 is configured in the same manner as the separation area D. Incidentally, the convex portion 30 may be configured in the same manner as the hollow convex portion, an example of which is illustrated in the subsections (a) through (c) of FIG. 35.

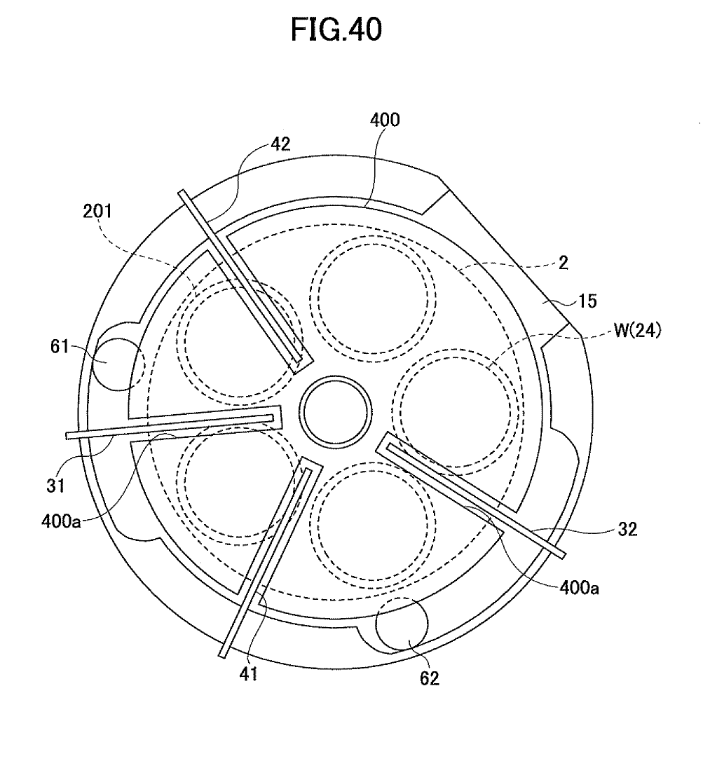

Moreover, the ceiling surface, which is lower than the ceiling surface 45 and as low as the ceiling surface 44 of the separation area D, may be provided for both reaction gas nozzles 31, 32 in order to extend to reach the ceiling surfaces 44 in other embodiments, as shown in FIG. 40, as long as the low ceiling surfaces 44 are provided on both sides of the reaction gas nozzle 41 (42). In other words, another convex portion 400 shown in FIG. 40 may be attached on the bottom surface of the ceiling plate 11, instead of the convex portion 4. Referring to FIG. 40, the convex portion 400 has a shape of substantially a circular plate, opposes substantially the entire upper surface of the susceptor 2, has four slots 400a where the corresponding gas nozzles 31, 32, 41, 42 are housed, the slots 400a extending in a radial direction of the convex portion 400, and leaves a thin space below the convex portion 400 in relation to the susceptor 2. A height of the thin space may be comparable with the height h stated above. When the convex portion 400 is employed, the reaction gas ejected from the reaction gas nozzle 31 (32) spreads to both sides of the reaction gas nozzle 31 (32) below the convex portion 400 (or in the thin space) and the separation gas ejected from the separation gas nozzle 41 (42) spreads to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be intermixed with the other reaction gas ejected from the reaction gas nozzle 32, thereby realizing an appropriate ALD (or MLD). Incidentally, in this case, the elevation rod 204 and the driving apparatus 203 (the subsection (b) of FIG. 23) are arbitrarily arranged in any position, as long as the susceptor tray 201 is brought upward/downward. In addition, a height of the susceptor tray 201 brought upward by the elevation rod 204 from the upper surface of the susceptor 2 may be determined so that the susceptor tray 201 and the wafer placed on the susceptor tray 201 do not touch a lower surface of the convex portion 400 and so that the susceptor tray 201 can be rotated without touching the susceptor 2.

Incidentally, the convex portion 400 may be configured by combining the hollow convex portions 4 shown in any one of the subsections (a) through (c) of FIG. 35 in order to eject the reaction gases and the separation gases from the corresponding ejection holes 33 of the corresponding hollow convex portions 4 without using the gas nozzles 31, 32, 41, 42 and the slits 400a.

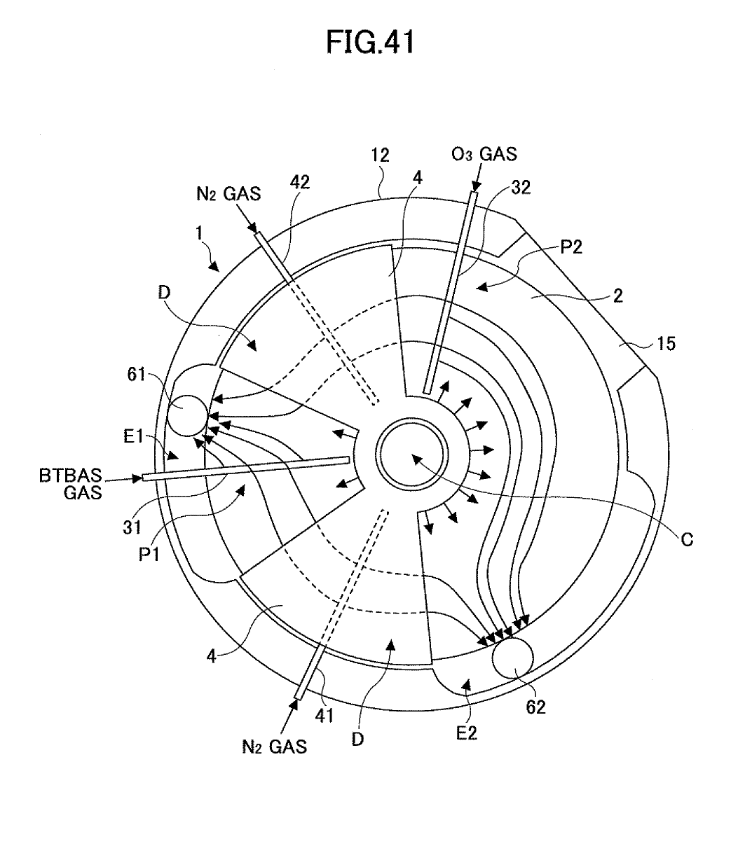

The process areas P1, P2 and the separation areas D may be arranged, for example, as shown in FIG. 41 in other embodiments. Referring to FIG. 41, the reaction gas nozzle 32 for supplying, for example, the O₃ gas is arranged upstream in the rotation direction of the susceptor 2 relative to the transfer opening 15, or between the separation gas nozzle 42 and the transfer opening 15. Even in such an arrangement, the gases ejected from the nozzles and the center area C flow substantially as shown by arrows in FIG. 41, and thus the reaction gases are impeded from being intermixed. Therefore, an appropriate ALD where the BTBAS gas is adsorbed on the upper surface of the wafer W and oxidized by the O₃ gas can be realized in such an arrangement.

Although the two kinds of reaction gases are used in the film deposition apparatuses according to the above embodiments, three or more kinds of reaction gases may be used in film deposition apparatuses according to other embodiments of the present invention. In this case, a first reaction gas nozzle, a separation gas nozzle, a second reaction gas nozzle, a separation gas nozzle, a third reaction gas nozzle and a separation gas nozzle may be located in this order at predetermined angular intervals, each nozzle extending along the radial direction of the susceptor 2. Additionally, the separation areas D including the corresponding separation gas nozzles are configured in the same manner as explained above.

In addition, not being limited to ALD of a silicon oxide film, the film deposition apparatuses may be used to carry out ALD of a silicon nitride film. As a nitriding gas in the case of ALD of silicon nitride, ammonia (NH₃), hydrazine (N₂H₂), and the like are used.

Moreover, as a source gas for the silicon oxide or nitride film deposition, dichlorosilane (DCS), hexadichlorosilane (HCD, tris(dimethylamino)silane (3DMAS), tetra ethyl ortho silicate (TEOS), and the like may be used rather than BTBAS.

Moreover, the film deposition apparatus according to an embodiment of the present invention may be used for MLD of an aluminum oxide (Al₂O₃) film using trymethylaluminum (TMA) and O₃ or oxygen plasma, a zirconium oxide (ZrO₂) film using tetrakis (ethylmethylamino) zirconium (TEMAZr) and O₃ or oxygen plasma, a hafnium oxide (HfO₂) film using tetrakis(ethylmethylamino)hafnium (TEMAHf) and O₃ or oxygen plasma, a strontium oxide (SrO) film using bis (tetra methyl heptandionate) strontium (Sr(THD)₂) and O₃ or oxygen plasma, a titanium oxide (TiO) film using (methyl-pentadionate)(bis-tetra-methyl-heptandionate) titanium (Ti(MPD)(THD)) and O₃ or oxygen plasma, and the like, rather than the silicon oxide film and the silicon nitride film.

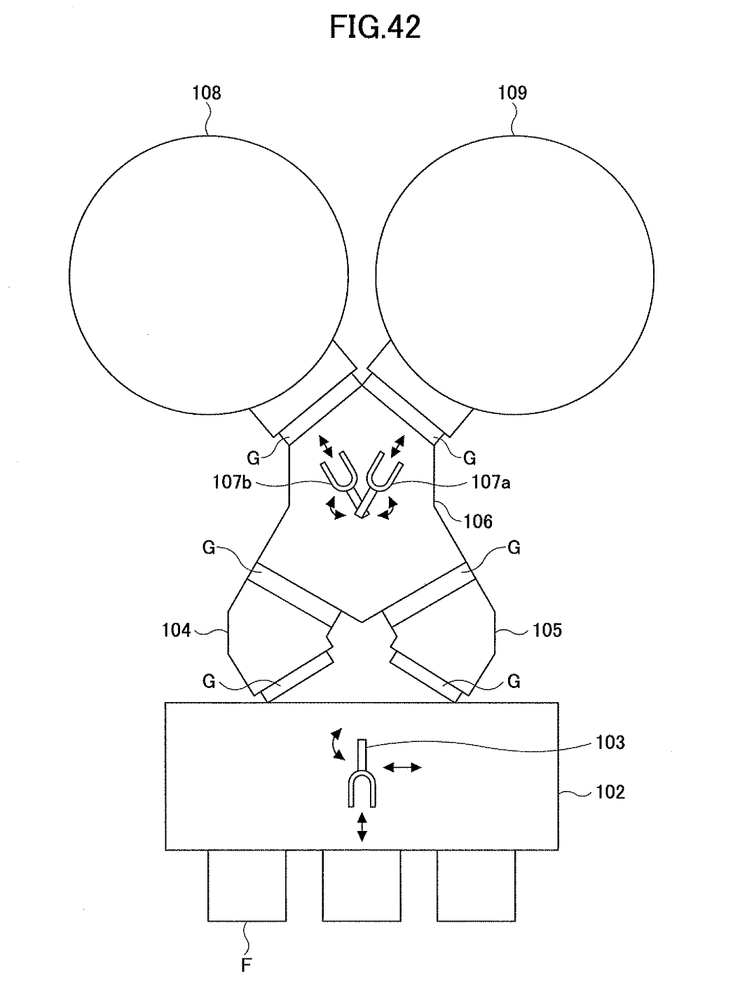

The film deposition apparatuses according to embodiments of the present invention may be integrated into a wafer process apparatus, an example of which is schematically illustrated in FIG. 42. The wafer process apparatus includes an atmospheric transfer chamber 102 in which a transfer arm 103 is provided, a load lock chamber (preparation chamber) 104 (105) whose atmosphere is changeable between vacuum and atmospheric pressure, a vacuum transfer chamber 106 in which two transfer arms 107a, 107b are provided, and film deposition apparatuses 108, 109 according to embodiments of the present invention. In addition, the wafer process apparatus includes cassette stages (not shown) on which a wafer cassette F such as a Front Opening Unified Pod (FOUP) is placed. The wafer cassette F is brought onto one of the cassette stages, and connected to a transfer in/out port provided between the cassette stage and the atmospheric transfer chamber 102. Then, a lid of the wafer cassette (FOUP) F is opened by an opening/closing mechanism (not shown) and the wafer is taken out from the wafer cassette F by the transfer arm 103. Next, the wafer is transferred to the load lock chamber 104 (105). After the load lock chamber 104 (105) is evacuated, the wafer in the load lock chamber 104 (105) is transferred further to one of the film deposition apparatuses 108, 109 through the vacuum transfer chamber 106 by the transfer arm 107a (107b). In the film deposition apparatus 108 (109), a film is deposited on the wafer in such a manner as described above. Because the wafer process apparatus has two film deposition apparatuses 108, 109 each of which can house five wafers at a time, the ALD (or MLD) mode deposition can be performed at high throughput.

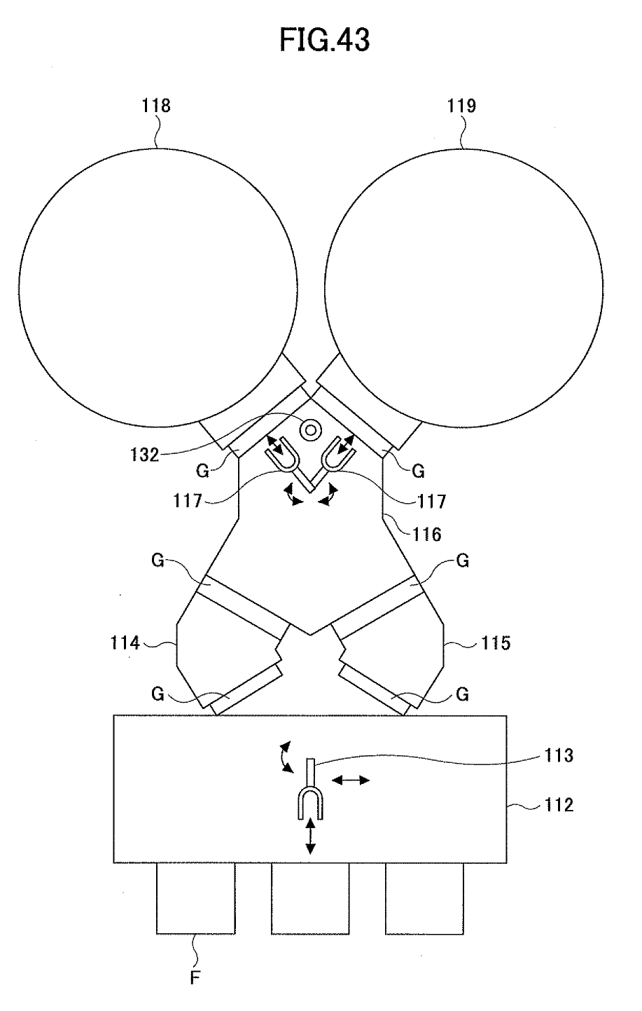

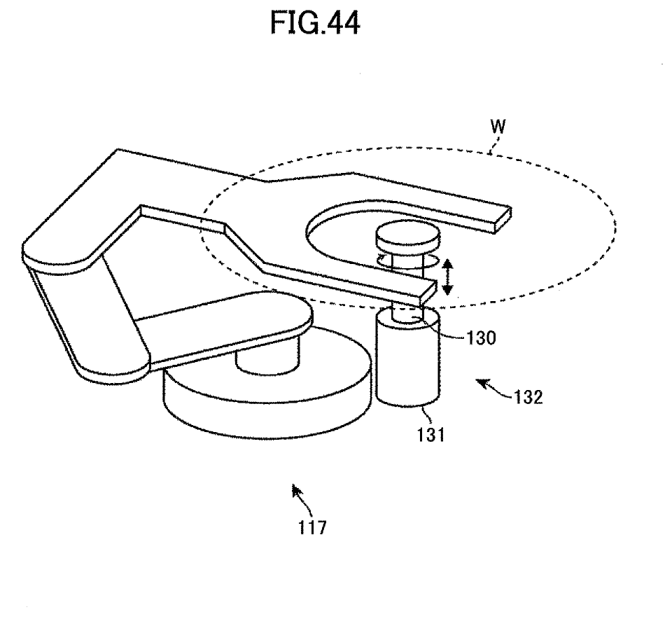

The wafers W may be rotated around their respective centers outside of the film deposition apparatus, while being rotated inside the film deposition apparatus in the above substrate process apparatus. Such an example is explained with reference to FIG. 43. In a vacuum transfer chamber 116 of the substrate process apparatus, there is provided a rotation mechanism 132 composed of an elevation shaft 130 that brings the wafer W upward from the lower surface of the wafer W held on a vacuum transfer arm 117 and rotates the wafer W, and a driving portion 131 that supports the elevation shaft 130 rotatably around a vertical axis and elevatably, as shown in FIG. 44. The rotation mechanism 132 is arranged in a position that allows two vacuum transfer arms 117, 117 to access the rotation mechanism 132, for example, in the middle of the vacuum transfer arms 117, 117 and adjacent to film deposition apparatus 118, 119 (see FIG. 43). The rotation mechanism 132 can rotate the wafer W around its center during the film deposition, and allow continuous film deposition on the wafer W. Incidentally, only one of the transfer arms 117, 117 is illustrated in FIG. 44.

In this substrate process apparatus, when the wafer W is rotated around its center, the inner pressure of a vacuum chamber (for example, the vacuum chamber 1 in FIG. 1) of the film deposition apparatus 118 or 119 is controlled to be substantially the same as the inner pressure of the vacuum transfer chamber 116 by a pressure controller (for example, the pressure controller 65 in FIG. 1). Next, the gate valve G is opened; the vacuum transfer arm 117 is brought into the vacuum chamber; and the wafer W is transferred onto the vacuum transfer arm 117 with the aid of lift pins (for example, the lift pins 16 in FIG. 24). Then, the wafer W is transferred out from the vacuum chamber to a position above the rotation mechanism 132, and received by the elevation shaft 130 by moving the elevation shaft 132 upward. Subsequently, the elevation shaft 130 is rotated by the driving portion 131, so that the wafer W is rotated, in the same manner as explained above. Next, the wafer W is transferred onto the vacuum transfer arm 117 by bringing the elevation shaft 130 downward, and then transferred into the vacuum chamber. After the above procedures are repeated for the remaining four wafers W by intermittently rotating the susceptor 2, the film deposition step is restarted. Even in this example, the thickness uniformity can be improved in the same manner as explained above.

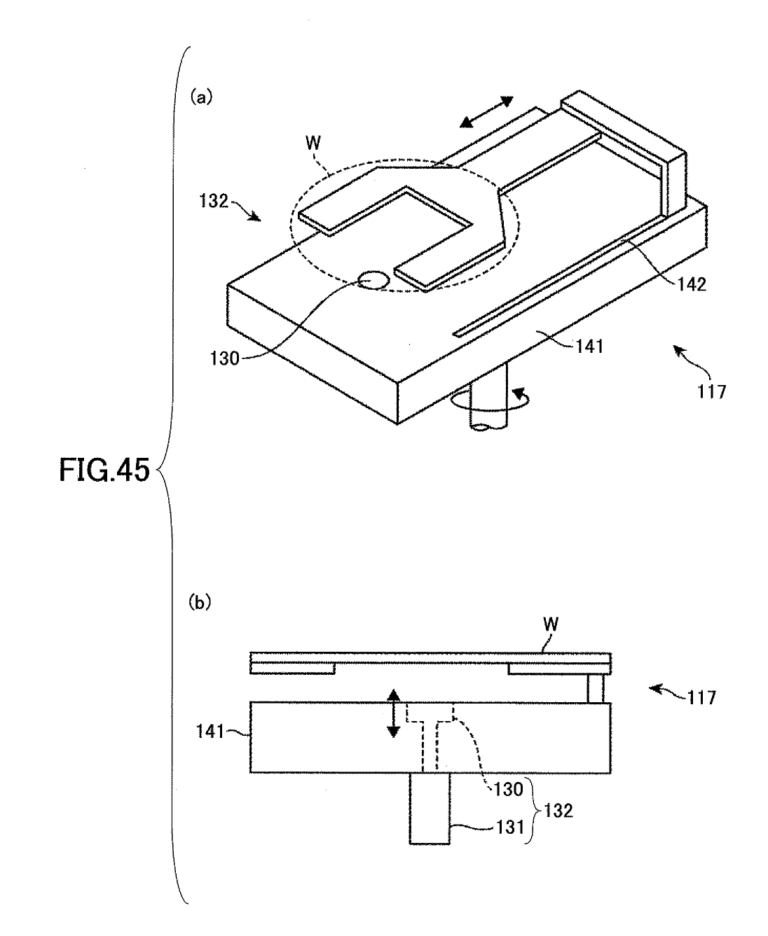

In addition, while the rotation mechanism 132 is arranged in the vacuum transfer chamber 116, the rotation mechanism 132 may be integrated into the vacuum transfer arms 117, 117. A subsection (a) of FIG. 45 illustrates such vacuum transfer arms 117, 117 with the rotation mechanism 132 integrated. As shown, the vacuum transfer arm 117 may be configured as a slide arm that can reciprocally move along a rail 142 formed on a supporting plate 141. In addition, the elevation shaft 130 of the rotation mechanism 132 is embedded into the supporting plate 141 from below as shown in a subsection (b) of FIG. 45. With this configuration, when the vacuum transfer arm 117 recedes back above the supporting plate 141 while holding the wafer W thereon, the driving portion 131 of the rotation mechanism 132 rotates the supporting plate 141 and the vacuum transfer arm 117, and thus the wafer W. Therefore, the same effect as explained above can be demonstrated by the vacuum transfer arms 117, 117 of FIG. 45. Incidentally, the vacuum transfer arms 117, 117 of FIG. 45 may be provided in an atmospheric chamber 112 of the substrate process apparatus illustrated in FIG. 43, in the place of an atmospheric transfer arm 113. With this, the wafer W may be rotated around its center in the atmospheric transfer chamber 112.

### Example

Next, results of simulation carried out in order to evaluate an improvement to be achieved by the film deposition method using the film deposition apparatus according to the embodiment of the present invention are explained.

(Simulation Conditions)

The simulation is carried out with the following conditions.
rotational speed of the susceptor 2: 120 rpm, 240 rpm
target thickness of the film: about 155 nm
the number of rotations of the wafer (around its center):

0 (for comparison purpose),

1 (a rotation angle of 180°),

8 (a rotation angle of 45°), and

4 (a rotation angle of 90°)

Incidentally, it is assumed that the wafer W is rotated by the same rotation angle (180°, 45°, or 90°) at every rotation. In addition, thicknesses of the film are obtained (or calculated) at 49 points evenly distributed across the wafer W, when the wafer W is rotated once, while the thicknesses are obtained at 8 points along a radius direction of the wafer W and 4 points along the radius direction the wafer W when the wafer W is rotated 8 times and 4 times, respectively.

(Simulation Results)

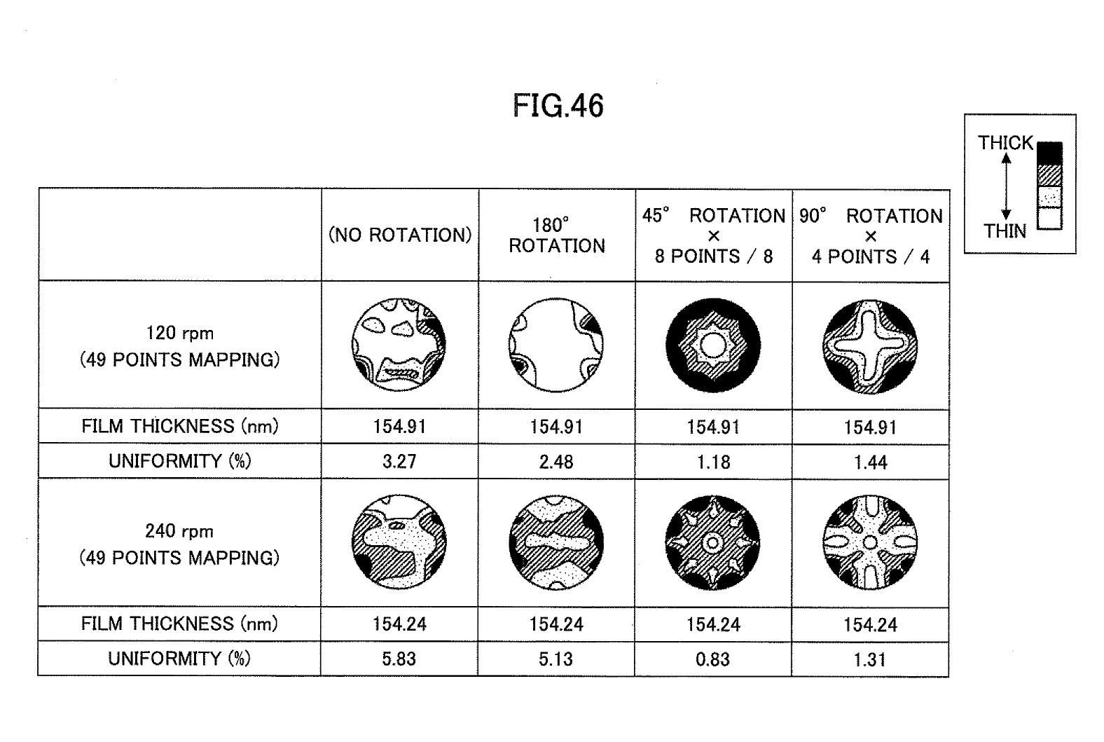

As shown in FIG. 46, even when the wafer W is rotated once, the thickness uniformity is improved compared to when the wafer W is not rotated. In addition, the greater numbers of rotations lead to better thickness uniformity. Moreover, when the wafer is rotated 8 times, thickness uniformity is greatly improved to 1% or below when the rotational speed of the susceptor 2 is 240 rpm.

What is claimed is:

1. A film deposition apparatus for depositing a film on a substrate in a chamber by carrying out a cycle of alternately supplying at least two kinds of reaction gases that react with each other on the substrate to produce a layer of a reaction product, the film deposition apparatus comprising:
a susceptor provided in the chamber;
plural reaction gas supplying portions that are provided opposing an upper surface of the susceptor and apart from one another in a circumferential direction of the susceptor, and supply corresponding reaction gases to an upper surface of the substrate;
a separation area including a separation gas supplying portion that supplies a separation gas, in order to separate atmospheres of plural process areas where the corresponding reaction gases are supplied from the corresponding reaction gas supplying portions, the separation area being provided between the plural process areas;
a first rotation mechanism that carries out relative rotation of the susceptor with respect to the reaction gas supplying portions and the separation gas supplying portion around a vertical axis;
substrate receiving portions formed in the susceptor along a rotation direction of the relative rotation carried out by the first rotation mechanism so that the substrate may be positioned in the plural process areas and the separation areas in turn due to the relative rotation carried out by the first rotation mechanism;
a second rotation mechanism that rotates the substrate around a vertical axis by a predetermined rotation angle; and
an evacuation portion that evacuates the chamber.

2. The film deposition apparatus of claim 1, further comprising a control portion that outputs a control signal to the first rotation mechanism and the second rotation mechanism so that the first rotation mechanism stops the relative rotation and the second rotation mechanism rotates the substrate during film deposition.

3. The film deposition apparatus of claim 2, wherein the substrate passes through the plural process areas and the separation area in turn due to rotation of the susceptor, and
wherein the second rotation mechanism is arranged below the susceptor and configured to push the substrate upward from below and rotate the substrate, thereby allowing the substrate to change in orientation.

4. The film deposition apparatus of claim 3, wherein the second rotation mechanism has a function of transferring the substrate between the susceptor and a transfer mechanism provided outside of the chamber.

5. The film deposition apparatus of claim 2, wherein the substrate passes through the plural process areas and the separation area in turn due to rotation of the susceptor, and
wherein the second rotation mechanism is provided above the susceptor and configured to hold the substrate from both sides of the substrate and rotate the substrate, thereby allowing the substrate to change in orientation.

6. The film deposition apparatus of claim 1, wherein the susceptor has a circular top view shape, and
wherein the plural gas supplying portions extend along a radius direction of the susceptor.

7. The film deposition apparatus of claim 1, wherein the separation area includes a ceiling surface that creates a thin space where the separation gas flows from the separation area toward the process areas between the susceptor and the ceiling surface, the ceiling surface being positioned on both sides of the separation gas supplying portion in relation to a direction of the relative rotation carried out by the first rotation mechanism.

8. The film deposition apparatus of claim 1, further comprising a center area that is located in a center portion of the chamber in order to separate atmospheres of the plural process areas, and that has an ejection hole that ejects a separation gas along the upper surface of the susceptor, the surface including the wafer receiving portion.

9. The film deposition apparatus of claim 1, wherein the susceptor includes a concave portion having a through-hole in a bottom portion thereof, and a plate that is detachably accommodated in the concave portion, and
wherein the second rotation mechanism includes an elevation/rotation portion that pushes the plate upward through the through-hole to rotate the plate.

10. The film deposition apparatus of claim 9, wherein the substrate receiving portion is provided in the plate.

11. The film deposition apparatus of claim 1, wherein the second rotation mechanism includes:
plural arms including at distal ends corresponding tip portions capable of supporting a lower edge portion of the substrate; and
a driving portion that may move the plural, arms in a vertical direction, in a direction so that the plural tip portions come closer to one another, and in an arc pattern,
wherein the susceptor includes concave portions that allow the tip portions to move thereinto in order that the tip portions may reach the lower edge portion of the substrate placed on the susceptor.

12. The film deposition apparatus of claim 9, further comprising a driving mechanism that may move the susceptor in a vertical direction,
wherein the elevation/rotation portion separates the plate from the susceptor due to a cooperative downward movement of the susceptor caused by the driving mechanism, and rotates the plate.

13. A film deposition apparatus for depositing a film on a substrate in a chamber by carrying out a cycle of alternately supplying at least two kinds of reaction gases that react with each other on the substrate to produce a layer of a reaction product, the film deposition apparatus comprising:
a susceptor that is rotatably provided in the chamber and includes in one surface of the susceptor a substrate receiving portion in which the substrate is placed;
a first reaction gas supplying portion configured to supply a first reaction gas to the one surface;
a second reaction gas supplying portion configured to supply a second reaction gas to the one surface, the second reaction gas supplying portion being separated from the first reaction gas supplying portion along a rotation direction of the susceptor;
a separation area positioned along the rotation direction between a first process area where the first reaction gas is supplied and a second process area where the second reaction gas is supplied;
a center area that is positioned in a center portion of the chamber in order to separate the first process area and the second process area and that includes a gas ejection hole through which a first separation gas is ejected along the one surface;
an evacuation hole configured to evacuate the chamber; and
a unit into which the substrate may be transferred from the chamber, wherein a rotational stage on which the substrate is placed is inside the unit;
wherein the separation area includes a separation gas supplying portion that supplies a second separation gas, and a ceiling surface that creates in relation to the one surface of the susceptor a thin space where the second separation gas may flow from the separation area to the process area side in relation to the rotation direction.

14. A film deposition method for depositing a film on a substrate in a chamber by carrying out a cycle of alternately supplying at least two kinds of reaction gases that react with each other on the substrate to produce a layer of a reaction product, the film deposition method comprising steps of:
placing the substrate in a substrate receiving portion of a susceptor provided in the chamber;
supplying the plural reaction gases to a susceptor surface where the wafer receiving portion is provided, from corresponding gas supplying portions provided to be separated from each other and to oppose the susceptor surface;
supplying from a separation gas supplying portion a first separation gas to a separation area provided between plural process areas along a circumferential direction of the susceptor, wherein the reaction gases are supplied from the corresponding gas supplying portions to the corresponding plural process areas, thereby reducing the plural reaction gases flowing into the separation area;
depositing a film by carrying out relative rotation of the susceptor with respect to the reaction gas supplying portions and the separation gas supplying portion using a first rotation mechanism, in order to allow the substrate to be positioned in turn in the plural process areas and the separation areas, thereby producing a layer of a reaction product; and
rotating the substrate around a center thereof using a second rotation mechanism by a predetermined rotation angle during the step of depositing the film.

15. The film deposition method of claim 14, further comprising a step of stopping the relative rotation caused by the first rotation mechanism prior to the step of rotating the substrate.

16. The film deposition method of claim 14, wherein the step of supplying the first separation gas includes a step of supplying the first separation gas from the separation area to the plural process areas through a thin space created by a ceiling surface on both sides of the first separation gas supplying portion in a direction of rotation caused by the first rotation mechanism.

17. The film deposition method of claim 14, wherein the step of supplying the first separation gas includes a step of evacuating the reaction gases along with a second separation gas ejected from a center area positioned in a center portion of the chamber and the first separation gas spreading toward the plural process areas, in order to separate atmospheres of the corresponding process areas.

18. The film deposition method of claim 14, wherein the step of rotating the substrate includes steps of:
bringing upward a plate detachably accommodated in a concave portion including a through-hole in a bottom portion of the concave portion, the concave portion being provided in the susceptor; and
rotating the plate around a center of the plate.

19. The film deposition method of claim 14, wherein the step of rotating the substrate includes steps of:
supporting a lower circumferential portion of the substrate to bring the substrate upward; and
rotating the substrate.

20. A computer readable storage medium storing a computer program for use in a film deposition apparatus for depositing a film on a substrate in a chamber by carrying out a cycle of alternately supplying at least two kinds of reaction gases that react with each other on the substrate to produce a layer of a reaction product, the computer program comprising a group of instructions for causing the film deposition apparatus to execute a film deposition method recited in claim 14.
